(19) United States
(12) Patent Application Publication
(10) Pub. No.: US 2018/0267404 A1
(43) Pub. Date: Sep. 20, 2018

(54) PATTERN FORMING METHOD AND METHOD FOR MANUFACTURING ELECTRONIC DEVICE

(71) Applicant: FUJIFILM Corporation, Tokyo (JP)

(72) Inventors: Akihiro KANEKO, Haibara-gun (JP); Tomotaka TSUCHIMURA, Haibara-gun (JP); Shuji HIRANO, Haibara-gun (JP); Hideaki TSUBAKI, Haibara-gun (JP); Wataru NIHASHI, Haibara-gun (JP)

(73) Assignee: FUJIFILM Corporation, Tokyo (JP)

(21) Appl. No.: 15/987,433

(22) Filed: May 23, 2018

Related U.S. Application Data
(63) Continuation of application No. PCT/JP2016/086528, filed on Dec. 8, 2016.

(30) Foreign Application Priority Data
Dec. 28, 2015 (JP) 2015-256183
Jul. 14, 2016 (JP) 2016-139275

(51) Int. Cl. G03F 7/038; G03F 7/16; G03F 7/20; G03F 7/38; G03F 7/32; G03F 7/40; C08F 212/14; C08F 220/16; C08F 220/28; G03F 7/039; G03F 7/004; H01L 21/027

(52) U.S. Cl. CPC G03F 7/038; C08F 2220/283; G03F 7/168; G03F 7/2004; G03F 7/38; G03F 7/32; G03F 7/40; C08F 212/145; C08F 220/16; C08F 220/28; C08F 212/14; G03F 7/039; G03F 7/0045; H01L 21/0274; G03F 7/16

(57) ABSTRACT

Provided are a pattern forming method for obtaining a pattern which is excellent in etching resistance and in which occurrence of pattern collapse can be suppressed, and a method for manufacturing an electronic device including the pattern forming method. The pattern forming method includes a step of forming a film using an actinic ray-sensitive or radiation-sensitive resin composition that contains a resin A having a repeating unit represented by General Formula (I) and a repeating unit represented by General Formula (BII), a step of exposing the film, and a step of developing the exposed film using a developer containing an organic solvent, to form a pattern.

### CROSS-REFERENCE TO RELATED APPLICATIONS

This application is a Continuation of PCT International Application No. PCT/JP2016/086528 filed on Dec. 8, 2016, which claims priority under 35 U.S.C. § 119(a) to Japanese Patent Application No. 2015-256183 filed on Dec. 28, 2015 and Japanese Patent Application No. 2016-139275 filed on Jul. 14, 2016. Each of the above applications is hereby expressly incorporated by reference, in its entirety, into the present application.

### BACKGROUND OF THE INVENTION

### 1. Field of the Invention

The present invention relates to a pattern forming method and a method for manufacturing an electronic device.

More specifically, the present invention relates to a pattern forming method which is used for a process for manufacturing a semiconductor such as an integrated circuit (IC), the manufacture of a circuit board for a liquid crystal, a thermal head, or the like, and other lithographic processes for photofabrication, and a method for manufacturing an electronic device including the pattern forming method.

### 2. Description of the Related Art

In processes for manufacturing semiconductor devices such as an integrated circuit (IC) and a large scale integrated circuit (LSI) in the related art, microfabrication by lithography using a photoresist composition has been carried out. In recent years, formation of an ultrafine pattern in a submicron region or quarter-micron region has been demanded in accordance with the realization of high integration for integrated circuits. With such a demand, a trend of wavelength shortening in the exposure wavelength from g-rays to i-rays, further to a KrF excimer laser light has been observed. Further, developments in lithography using an electron beam, X-rays, extreme ultraviolet rays (EUV light), or the like other than an excimer laser light have recently been progressing.

In such lithography, formation of a pattern is carried out using an actinic ray-sensitive or radiation-sensitive resin composition (also referred to as a photoresist composition or a chemically amplified resist composition) to form a film, then exposing the obtained film, and developing the exposed film using a developer containing an organic solvent (see, for example, JP5557550B).

### SUMMARY OF THE INVENTION

The present inventors used the actinic ray-sensitive or radiation-sensitive resin composition specifically disclosed in [Examples] of JP5557550B so as to form a pattern. As a result, it has been found that etching resistance was insufficient or pattern collapse occurred in some cases.

Therefore, an object of the present invention is to provide a pattern forming method for obtaining a pattern which is excellent in etching resistance and in which occurrence of pattern collapse can be suppressed, and a method for manufacturing an electronic device including the pattern forming method.

In order to achieve the above object, the present inventors have conducted extensive studies, and as a result, they have found that in a case where a resin contained in an actinic ray-sensitive or radiation-sensitive resin composition used has a combination of specific repeating units, desired effects are obtained.

More specifically, the present inventors have found that the above object can be achieved by the following constitution.

[1] A pattern forming method comprising: a step of forming a film using an actinic ray-sensitive or radiation-sensitive resin composition that contains a resin A having a repeating unit represented by General Formula (I) and a repeating unit represented by General Formula (BII); a step of exposing the film; and a step of developing the exposed film using a developer containing an organic solvent, to form a pattern.

[2] The pattern forming method according to [1], in which Ar₄ in General Formula (I) and Ar₆ in General Formula (BII) are each independently a phenylene group or a naphthylene group.

[3] The pattern forming method according to [1] or [2], in which X₄ in General Formula (I) and X₆ in General Formula (BII) are each independently a single bond.

[4] The pattern forming method according to any one of [1] to [3], in which a content of the repeating unit represented by General Formula (BII) is 10% by mol or more and 80% by mol or less, with respect to all the repeating units in the resin A.

[5] The pattern forming method according to any one of [1] to [4], in which a content of the repeating unit represented by General Formula (BII) is 25% by mol or more and 65% by mol or less, with respect to all the repeating units in the resin A.

[6] The pattern forming method according to any one of [1] to [5], in which a content of the repeating unit represented by General Formula (I) is 10% by mol or more and 80% by mol or less, with respect to all the repeating units in the resin A.

[7] The pattern forming method according to any one of [1] to [6], in which Y₂ in General Formula (BII) is a group represented by Formula (Y1).

[8] The pattern forming method according to [7], in which, in Formula (Y1), at least two of Rx₁, . . . , or Rx₃ are bonded to each other to form a ring.

[9] The pattern forming method according to any one of [1] to [8], in which the resin A further has a repeating unit having an aromatic ring group.

[10] The pattern forming method according to any one of [1] to [9], in which the resin A further has a repeating unit having a lactone group or a sultone group.

[11] The pattern forming method according to any one of [1] to [10], in which the actinic ray-sensitive or radiation-sensitive resin composition further contains a compound capable of generating an acid by actinic rays or radiation.

[12] The pattern forming method according to any one of [1] to [11], in which the developer contains at least one organic solvent selected from the group consisting of a ketone-based solvent and an ester-based solvent.

[13] The pattern forming method according to any one of [1] to 12, further comprising a step of washing the exposed film with a rinsing liquid after developing the exposed film using the developer, in which the rinsing liquid contains at least one organic solvent selected from the group consisting of a ketone-based solvent, an ether-based solvent, and a hydrocarbon-based solvent.

[14] A method for manufacturing an electronic device, comprising the pattern forming method according to any one of [1] to [13].

According to the present invention, it is possible to provide a pattern forming method for obtaining a pattern which is excellent in etching resistance and in which occurrence of pattern collapse can be suppressed, and a method for manufacturing an electronic device including the pattern forming method.

### DESCRIPTION OF THE PREFERRED EMBODIMENTS

Hereinafter, embodiments of the present invention will be described in detail.

In citations for a group (atomic group) in the present specification, a description not referring to substitution or non-substitution encompasses both a group having no substituent and a group having a substituent. For example, an “alkyl group” includes not only an alkyl group having no substituent (an unsubstituted alkyl group) but also an alkyl group having a substituent (a substituted alkyl group).

“Actinic ray” or “radiation” in the present specification means, for example, a bright line spectrum of a mercury lamp, far ultraviolet rays represented by an excimer laser, extreme ultraviolet rays (EUV light), X-rays, electron beams (EB), or the like. In addition, in the present invention, light means actinic ray or radiation.

Furthermore, unless otherwise specified, “exposure” or “exposing” in the present specification includes not only being subjected to exposure by a bright line spectrum of a mercury lamp, far ultraviolet rays represented by an excimer laser, extreme ultraviolet rays (EUV light), X-rays, or the like, but also lithography by particle rays such as electron beams and ion beams.

In the specification of the present application, “to” is used to include numerical values described before and after the preposition “to” as a lower limit value and an upper limit value.

In the present invention, the number-average molecular weight (Mn) and the weight-average molecular weight (Mw) are values expressed in terms of standard polystyrene and obtained from gel permeation chromatography (GPC) under the following conditions.

Apparatus: HLC-8320 GPC, manufactured by TOSOH Corporation

Column: TSK-GEL G3000PWXL, manufactured by TOSOH Corporation

Developing solvent: tetrahydrofuran (THF)

[Pattern Forming Method]

The pattern forming method of the present invention is a pattern forming method including a step of forming a film using an actinic ray-sensitive or radiation-sensitive resin composition (hereinafter also referred to as a “resist composition”) as described later, a step of exposing the film, and a step of developing the exposed film using a developer containing an organic solvent, to form a pattern.

According to the pattern forming method of the present invention, a pattern which is excellent in etching resistance and in which occurrence of pattern collapse can be suppressed is obtained.

The reason for this is speculated as follows. That is, it is considered that in a case where the resin A described later contained in the resist composition has a repeating unit having an aromatic ring group represented by General Formula (I) described later and a repeating unit having the same aromatic ring group represented by General Formula (BII) described later, a pattern formed using such resist composition has an improved etching resistance.

Further, it is considered that with the resin A being contained in the pattern, swelling with respect to the developer is suppressed, and as a result, occurrence of pattern collapse can be suppressed. The reason why the swelling is suppressed is uncertain. However, it is presumed that since both General Formula (I) and General Formula (BII) have an aromatic ring group, an interaction between the aromatic ring groups becomes strong so that permeation of the developer is suppressed. In addition, since etching resistance of the pattern is improved, a film thickness can be made thin and such thinning can also suppress occurrence of pattern collapse.

Hereinafter, each step of the pattern forming method of the present invention will be described.

[Film-Forming Step]

The film-forming step is a step of forming a film (hereinafter also referred to as a “resist film” or “actinic ray-sensitive or radiation-sensitive film”) using an actinic ray-sensitive or radiation-sensitive resin composition as described later, and can be, for example, carried out by the following method.

In order to form a resist film on a substrate using an actinic ray-sensitive or radiation-sensitive resin composition, each of components as described later is dissolved in a solvent to prepare an actinic ray-sensitive or radiation-sensitive resin composition, the resulting resin composition is filtered using a filter if necessary, and then coated on the substrate. The filter is, for example, a filter made of polytetrafluoroethylene, polyethylene, or nylon, having a pore size of 0.1 micron or less, preferably 0.05 micron or less, and more preferably 0.03 micron or less.

The actinic ray-sensitive or radiation-sensitive resin composition is coated on a substrate (for example, silicon-coated substrate and silicon dioxide-coated substrate) as used in the manufacture of integrated circuit elements by a suitable coating method such as a spinner. Thereafter, the resin composition is dried to form a resist film. If necessary, various base films (inorganic film, organic film, antireflection film) may be formed on an underlayer of the resist film.

As a drying method, a method of heating and drying is generally used. Heating can be carried out by means provided in a usual exposure machine or development machine, and may be carried out using a hot plate or the like.

A heating temperature is preferably 80° C. to 180° C., more preferably 80° C. to 150° C., still more preferably 80° C. to 140° C., particularly preferably 80° C. to 130° C. A heating time is preferably from 30 to 1,000 seconds, more preferably from 60 to 800 seconds, and still more preferably from 60 to 600 seconds.

The film thickness of the resist film is generally 200 nm or less, and preferably 100 nm or less.

For example, in order to resolve a 1:1 line-and-space pattern having a size of 30 nm or less, the thickness of the resist film to be formed is preferably 50 nm or less. In a case where the film thickness is 50 nm or less, pattern collapse is less likely to occur at the time of applying a development step as described later. Thus, superior resolution performance can be obtained.

The film thickness range is more preferably in a range of 15 nm to 45 nm. In a case where the film thickness is 15 nm or more, better etching resistance can be obtained. The film thickness range is still more preferably 15 nm to 40 nm.

In the pattern forming method of the present invention, an upper layer film (top coat film) may be formed on an upper layer of the resist film. The upper layer film can be formed using, for example, an upper layer film-forming composition containing a hydrophobic resin, an acid generator, a basic compound, or the like. The upper layer film and the upper layer film-forming composition are as described below.

[Exposure Step]

The exposure step is a step of exposing the resist film, and can be carried out, for example, by the following method.

The formed resist film is irradiated with actinic rays or radiation through a predetermined mask. In electron beam irradiation, lithography through no mask (direct lithography) is common.

The actinic rays or radiation is not particularly limited, and examples thereof include KrF excimer laser, ArF excimer laser, and extreme ultraviolet rays (EUV light), electron beam (EB). The exposure may be a liquid immersion exposure.

In the pattern forming method of the present invention using the resin (A) as described later, any of the actinic rays or radiation can be used.

[Baking (Post Exposure Bake (PEB))]

In the pattern forming method of the present invention, it is preferable to perform baking (heating) after exposure and before development. Baking promotes a reaction at the exposed portion and results in a better sensitivity and/or pattern shape.

The heating temperature is preferably from 80° C. to 150° C., more preferably from 80° C. to 140° C., and still more preferably from 80° C. to 130° C.

The heating time is preferably from 30 to 1,000 seconds, more preferably from 60 to 800 seconds, and still more preferably from 60 to 600 seconds.

Heating can be carried out by means provided in a usual exposure machine or development machine, and may be carried out using a hot plate or the like.

[Development Step]

The development step is a step of developing the exposed resist film using a developer containing an organic solvent to form a pattern. In the development step, an unexposed portion of the resist film is dissolved by the developer, and a so-called negative pattern is formed.

As a development method, for example, a method in which a substrate is immersed in a tank filled with a developer for a certain period of time (a dip method), a method in which development is performed by heaping a developer up onto the surface of a substrate by surface tension, and then allowing it to stand for a certain period of time (a puddle method), a method in which a developer is sprayed on the surface of a substrate (a spray method), and a method in which a developer is continuously discharged onto a substrate spun at a constant rate while scanning a developer discharging nozzle at a constant rate (a dynamic dispense method) can be applied.

Further, after the step of performing development, a step of stopping development may be carried out while performing replacement with another solvent.

The development time is not particularly limited as long as it is a time during which the resin at the unexposed portion is sufficiently dissolved, and is usually 10 to 300 seconds, and preferably 20 to 120 seconds.

A temperature of the developer is preferably 0° C. to 50° C. and more preferably 15° C. to 35° C.

As the developer used in the development step, it is preferable to use a developer (organic developer) as described later. In addition to development using the organic developer, development with an alkali developer may be carried out (so-called double development).

[Rinsing Step]

The pattern forming method of the present invention may further include a rinsing step after the development step. In the rinsing step, the wafer for which development has been carried out is preferably subjected to a washing (rinsing) treatment using a rinsing liquid as described later.

There are no particular limitations on a method for the washing treatment, and, for example, a method in which a rinsing liquid is continuously discharged onto a substrate spun at a constant rate (a rotary discharging method), a method in which a substrate is immersed in a tank filled with a rinsing liquid for a certain period of time (a dip method), a method in which a rinsing liquid is sprayed on the surface of a substrate (a spray method), or the like can be applied. Among these, a method in which a washing treatment is carried out using the rotary discharging method, and the substrate is rotated at a rotation speed of 2,000 rpm to 4,000 rpm after the washing, thereby removing the rinsing liquid from the substrate, is preferable.

The rinsing time is not particularly limited, and is usually from 10 seconds to 300 seconds, preferably from 10 seconds to 180 seconds, and more preferably from 20 seconds to 120 seconds.

A temperature of the rinsing liquid is preferably from 0° C. to 50° C., and more preferably from 15° C. to 35° C.

In addition, after the development treatment or the rinsing treatment, a treatment of removing the developer or rinsing liquid adhering on the pattern by a supercritical fluid can be carried out.

Furthermore, after the development treatment, the rinsing treatment, or the treatment with a supercritical fluid, a heat treatment can be performed to remove a solvent remaining in the pattern. The heating temperature is not particularly limited as long as a good resist pattern can be obtained, and is usually 40° C. to 160° C. The heating temperature is preferably 50° C. to 150° C., and more preferably 50° C. to 110° C. The heating time is not particularly limited as long as a good resist pattern can be obtained, and it is usually 15 to 300 seconds, and preferably 15 to 180 seconds.

[Developer and Rinsing Liquid]

It is preferable that the developer and the rinsing liquid used in the pattern forming method of the present invention contain an organic solvent and further contain an antioxidant and/or a surfactant.

Hereinafter, in the order of the developer and the rinsing liquid, components that are contained and can be contained therein will be described in detail.

The developer and the rinsing liquid may contain isomers (compounds having the same number of atoms and different structures) which are described below as examples. In addition, only one kind of the isomers may be contained or a plurality of kinds thereof may be contained.

<Developer>

The developer is used in the development step as described above and contains an organic solvent. Thus, the developer can also be referred to as an organic developer.

(Organic Solvent)

A vapor pressure at 20° C. of the organic solvent (vapor pressure as a whole in a case of a mixed solvent) is preferably 5 kPa or less, more preferably 3 kPa or less, and still more preferably 2 kPa or less.

By setting the vapor pressure of the organic solvent to 5 kPa or less, evaporation of the developer on a substrate or in a development cup is suppressed and wafer in-plane temperature uniformity is enhanced. As a result, wafer in-plane dimensional uniformity is improved.

As the organic solvent used in the developer, various organic solvents are widely used. For example, solvents such as an ester-based solvent, a ketone-based solvent, an alcohol-based solvent, an amide-based solvent, an ether-based solvent, and a hydrocarbon-based solvent can be used.

In the present invention, the ester-based solvent refers to a solvent having an ester group in the molecule, the ketone-based solvent refers to a solvent having a ketone group in the molecule, the alcohol-based solvent refers to a solvent having an alcoholic hydroxyl group in the molecule, the amide-based solvent refers to a solvent having an amide group in the molecule, and the ether-based solvent refers to a solvent having an ether bond in the molecule. Among these, a solvent having a plurality of functional groups described above in one molecule may also be present, but in this case, it is assumed that the solvent also corresponds to any solvent type containing the functional group which is contained in the solvent. For example, it is assumed that diethylene glycol monomethyl ether also corresponds to any of the alcohol-based solvent or the ether-based solvent, in the above classification.

In particular, a developer containing at least one solvent selected from a ketone-based solvent, an ester-based solvent, an alcohol-based solvent, or an ether-based solvent is preferable.

Examples of the ester-based solvent include methyl acetate, ethyl acetate, butyl acetate, isobutyl acetate, pentyl acetate, propyl acetate, isopropyl acetate, amyl acetate (pentyl acetate), isoamyl acetate (isopentyl acetate or 3-methylbutyl acetate), 2-methylbutyl acetate, 1-methylbutyl acetate, hexyl acetate, isohexyl acetate, heptyl acetate, octyl acetate, ethyl methoxyacetate, ethyl ethoxyacetate, propylene glycol monomethyl ether acetate (PGMEA; also known as 1-methoxy-2-acetoxypropane), ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, butyl propionate, pentyl propionate, hexyl propionate, heptyl propionate, butyl butanoate, isobutyl butanoate, pentyl butanoate, hexyl butanoate, isobutyl isobutanoate, propyl pentanoate, isopropyl pentanoate, butyl pentanoate, pentyl pentanoate, ethyl hexanoate, propyl hexanoate, butyl hexanoate, isobutyl hexanoate, methyl heptanoate, ethyl heptanoate, propyl heptanoate, cyclohexyl acetate, cycloheptyl acetate, 2-ethylhexyl acetate, cyclopentyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Among these, butyl acetate, amyl acetate, isoamyl acetate, 2-methylbutyl acetate, 1-methylbutyl acetate, hexyl acetate, pentyl propionate, hexyl propionate, heptyl propionate, and butyl butanoate are preferably used, and isoamyl acetate is more preferably used.

Examples of the ketone-based solvent include 1-octanone, 2-octanone, 1-nonanone, 2-nonanone, acetone, 2-heptanone, 4-heptanone, 1-hexanone, 2-hexanone, diisobutyl ketone, cyclohexanone, methyl cyclohexanone, phenyl acetone, methyl ethyl ketone, methyl isobutyl ketone, acetyl acetone, acetonyl acetone, ionone, diacetonyl alcohol, acetyl carbinol, acetophenone, methyl naphthyl ketone, isophorone, propylene carbonate, and γ-butyrolactone. Among these, 2-heptanone or diisobutyl ketone is preferred.

Examples of the alcohol-based solvent include an alcohol (monohydric alcohol) such as methanol, ethanol, 1-propanol, isopropanol, 1-butanol, 2-butanol, 3-methyl-1-butanol, tert-butyl alcohol, 1-pentanol, 2-pentanol, 1-hexanol, 1-heptanol, 1-octanol, 1-decanol, 2-hexanol, 2-heptanol, 2-octanol, 3-hexanol, 3-heptanol, 3-octanol, 4-octanol, 3-methyl-3-pentanol, cyclopentanol, 2,3-dimethyl-2-butanol, 3,3-dimethyl-2-butanol, 2-methyl-2-pentanol, 2-methyl-3-pentanol, 3-methyl-2-pentanol, 3-methyl-3-pentanol, 4-methyl-2-pentanol, 4-methyl-3-pentanol, cyclohexanol, 5-methyl-2-hexanol, 4-methyl-2-hexanol, 4,5-dimetyl-2-hexanol, 6-methyl-2-heptanol, 7-methyl-2-octanol, 8-methyl-2-nonanol, 9-methyl-2-decanol, and 3-methoxy-1-butanol; a glycol-based solvent such as ethylene glycol, diethylene glycol, and triethylene glycol; and a glycol ether-based solvent containing a hydroxyl group such as ethylene glycol monomethyl ether, propylene glycol monomethyl ether (PGME; also known as 1-methoxy-2-propanol), diethylene glycol monomethyl ether, triethylene glycol monoethyl ether, methoxymethyl butanol, ethylene glycol monoethyl ether, ethylene glycol monopropyl ether, ethylene glycol monobutyl ether, propylene glycol monoethyl ether, propylene glycol monopropyl ether, propylene glycol monobutyl ether, and propylene glycol monophenyl ether. Among these, the glycol ether-based solvent is preferably used.

Examples of the ether-based solvent include, in addition to the glycol ether-based solvent containing a hydroxyl group, a glycol ether-based solvent containing no hydroxyl group such as propylene glycol dimethyl ether, propylene glycol diethyl ether, diethylene glycol dimethyl ether, and diethylene glycol diethyl ether; an aromatic ether-based solvent such as anisole and phenetol; dioxane; tetrahydrofuran; tetrahydropyran; perfluoro-2-butyltetrahydrofuran; perfluorotetrahydrofuran; 1,4-dioxane; and isopropyl ether. Preferably, the glycol ether-based solvent or the aromatic ether-based solvent such as anisole is used.

Examples of the amide-based solvent which can be used include N-methyl-2-pyrrolidone, N,N-dimethylacetamide, N,N-dimethylformamide, hexamethylphosphoric triamide, and 1,3-dimethyl-2-imidazolidinone.

Examples of the hydrocarbon-based solvent include an aliphatic hydrocarbon-based solvent such as pentane, hexane, octane, nonane, decane, dodecane, undecane, hexadecane, 2,2,4-trimethylpentane, 2,2,3-trimethylhexane, perfluorohexane, and perfluoroheptane; and an aromatic hydrocarbon-based solvent such as toluene, xylene, ethylbenzene, propylbenzene, 1-methylpropylbenzene, 2-methylpropylbenzene, dimethylbenzene, di ethylbenzene, ethylmethylbenzene, trimethylbenzene, ethyldimethylbenzene, and dipropylbenzene.

Further, as the hydrocarbon-based solvent, an unsaturated hydrocarbon-based solvent can also be used, and examples thereof include an unsaturated hydrocarbon-based solvent such as octene, nonene, decene, undecene, dodecene, and hexadecene. The number of a double bond or triple bond possessed by the unsaturated hydrocarbon-based solvent is not particularly limited, and such bond may be at any position of the hydrocarbon chain. In addition, in a case where the unsaturated hydrocarbon-based solvent has a double bond, a cis-isomer and a trans-isomer may be mixed.

Furthermore, the aliphatic hydrocarbon-based solvent as the hydrocarbon-based solvent may be a mixture of compounds having the same carbon atoms and different structures. For example, in a case where decane is used as the aliphatic hydrocarbon-based solvent, 2-methylnonane, 2,2-dimethyloctane, 4-ethyloctane, isooctane, and the like, which are compounds having the same carbon atoms and different structures, may be contained in the aliphatic hydrocarbon-based solvent.

Further, only one kind of the compounds having the same carbon atoms and different structures may be contained or a plurality of kinds thereof may be contained as described above.

In a case where extreme ultraviolet rays (EUV light) and electron beams (EB) are used in the above-mentioned exposure step, the developer preferably uses an ester-based solvent having 7 or more carbon atoms (preferably 7 to 14 carbon atoms, more preferably 7 to 12 carbon atoms, and still more preferably 7 to 10 carbon atoms) and 2 or less heteroatoms from the viewpoint that swelling of the resist film can be suppressed.

The heteroatom of the ester-based solvent is an atom other than a carbon atom and a hydrogen atom, and examples thereof include an oxygen atom, a nitrogen atom, and a sulfur atom. The number of heteroatoms is preferably 2 or less.

Preferred examples of the ester-based solvent having 7 or more carbon atoms and 2 or less heteroatoms include amyl acetate, isoamyl acetate, 2-methylbutyl acetate, 1-methylbutyl acetate, hexyl acetate, pentyl propionate, hexyl propionate, heptyl propionate, and butyl butanoate, and isoamyl acetate is more preferably used.

In a case where extreme ultraviolet rays (EUV light) and electron beams (EB) are used in the above-mentioned exposure step, the developer may use a mixed solvent of the ester-based solvent and the hydrocarbon-based solvent, or a mixed solvent of the ketone-based solvent and the hydrocarbon-based solvent, instead of the above-mentioned ester-based solvent having 7 or more carbon atoms and 2 or less heteroatoms. Also, this case is effective for suppression of the swelling of the resist film.

In a case of using the ester-based solvent and the hydrocarbon-based solvent in combination, isoamyl acetate is preferably used as the ester-based solvent. Further, from the viewpoint of adjusting the solubility of the resist film, a saturated hydrocarbon-based solvent (for example, octane, nonane, decane, dodecane, undecane, and hexadecane) is preferably used as the hydrocarbon-based solvent.

In a case of using the ketone-based solvent and the hydrocarbon-based solvent in combination, 2-heptanone or diisobutyl ketone is preferably used as the ketone-based solvent. Further, from the viewpoint of adjusting the solubility of the resist film, a saturated hydrocarbon-based solvent (for example, octane, nonane, decane, dodecane, undecane, and hexadecane) is preferably used as the hydrocarbon-based solvent.

Further, in a case of using the ester-based solvent and the hydrocarbon-based solvent in combination or in a case of using the ketone-based solvent and the hydrocarbon-based solvent in combination, an unsaturated hydrocarbon-based solvent can also be used as the hydrocarbon-based solvent, and examples thereof include an unsaturated hydrocarbon-based solvent such as octene, nonene, decene, undecene, dodecene, and hexadecene. The number of a double bond or triple bond possessed by the unsaturated hydrocarbon-based solvent is not particularly limited, and such bond may be at any position of the hydrocarbon chain.

In addition, in a case where the unsaturated hydrocarbon-based solvent has a double bond, a cis-isomer and a trans-isomer may be mixed.

In a case of using the above-mentioned mixed solvent, since the content of the hydrocarbon-based solvent depends on a solvent solubility of the resist film, it is not particularly limited. Thus, the required amount of the hydrocarbon-based solvent may be determined by an appropriate adjustment.

A plurality of the above-mentioned organic solvents may be mixed, or the organic solvent may be used by mixing it with a solvent other than those mentioned above and/or with water. However, in order to sufficiently bring out the effects of the present invention, a moisture content in the entire developer is preferably less than 10% by mass, and more preferably water is substantially not contained.

The concentration of the organic solvent (a total thereof in a case where a plurality of kinds thereof are mixed) in the developer is preferably 50% by mass or more, more preferably from 50% to 100% by mass, still more preferably from 85% to 90% by mass or more, and particularly preferably from 95% to 100% by mass. Most preferably, the developer is substantially composed only of the organic solvent. In a case of being substantially composed only of the organic solvent, such case includes a case where trace amounts of a surfactant, an antioxidant, a stabilizer, an anti-foaming agent, and the like are contained.

Suitable examples of the organic solvent used as the developer include the ester-based solvent.

As the ester-based solvent, it is more preferable to use a solvent represented by General Formula (S1) as described later or a solvent represented by General Formula (S2) as described later; it is still more preferable to use the solvent represented by General Formula (S1); it is particularly preferable to use alkyl acetate; and it is most preferable to use butyl acetate, amyl acetate (pentyl acetate), and isoamyl acetate (isopentyl acetate).

R—C(═O)—O—R′ (S1)

In General Formula (S1), R and R′ each independently represent a hydrogen atom, an alkyl group, a cycloalkyl group, an alkoxyl group, an alkoxycarbonyl group, a carboxyl group, a hydroxyl group, a cyano group, or a halogen atom. R and R′ may be bonded to each other to form a ring.

The number of carbon atoms of the alkyl group, alkoxyl group, or alkoxycarbonyl group for R and R′ is preferably in a range of 1 to 15, and the number of carbon atoms of the cycloalkyl group is preferably 3 to 15.

R and R′ are preferably a hydrogen atom or an alkyl group. The alkyl group, cycloalkyl group, alkoxyl group, or alkoxycarbonyl group for R and R′, and the ring formed by the bonding of R and R′ to each other may be substituted with a hydroxyl group, a group containing a carbonyl group (for example, an acyl group, an aldehyde group, and an alkoxycarbonyl), a cyano group, or the like.

Examples of the solvent represented by General Formula (S1) include methyl acetate, butyl acetate, ethyl acetate, isopropyl acetate, amyl acetate, isoamyl acetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, and ethyl 2-hydroxypropionate.

Among these, R and R′ are preferably an unsubstituted alkyl group.

The solvent represented by General Formula (S1) is preferably an alkyl acetate; more preferably butyl acetate, amyl acetate (pentyl acetate), or isoamyl acetate (isopentyl acetate); and still more preferably isoamyl acetate.

The solvent represented by General Formula (S1) may be used in combination with one or more other organic solvents. The combination solvent in this case is not particularly limited as long as it can be mixed with the solvent represented by General Formula (S1) without separation. The solvents represented by General Formula (S1) may be used in combination, and the solvent represented by General Formula (S1) may be mixed with other solvent selected from an ester-based solvent, a ketone-based solvent, an alcohol-based solvent, an amide-based solvent, an ether-based solvent, and a hydrocarbon-based solvent. One or more kinds of the combination solvents can be used, but in order to obtain stable performance, it is preferable to use only one kind thereof. In a case of being used in a mixture with one kind of the combination solvents, a mixing ratio of the solvent represented by General Formula (S1) and the combination solvent is, in a mass ratio, usually 20:80 to 99:1, preferably 50:50 to 97:3, more preferably from 60:40 to 95:5, and still more preferably from 60:40 to 90:10.

As the organic solvent used as the developer, a glycol ether-based solvent can be used. As the glycol ether-based solvent, the solvent represented by General Formula (S2) may be used.

R″—C(═O)—O—R′″—O—R″″ (S2)

In General Formula (S2),

R″ and R″″ each independently represent a hydrogen atom, an alkyl group, a cycloalkyl group, an alkoxyl group, an alkoxycarbonyl group, a carboxyl group, a hydroxyl group, a cyano group, or a halogen atom. R″ and R″″ may be bonded to each other to form a ring.

R″ and R″″ are preferably a hydrogen atom or an alkyl group. The number of carbon atoms of the alkyl group, alkoxyl group, or alkoxycarbonyl group for R″ and R″″ is preferably in a range of 1 to 15, and the number of carbon atoms of the cycloalkyl group is preferably 3 to 15.

R′″ represents an alkylene group or a cycloalkylene group. R′″ is preferably an alkylene group. The number of carbon atoms of the alkylene group for R′″ is preferably in a range of 1 to 10. The number of carbon atoms of the cycloalkylene group for R′″ is preferably in a range of 3 to 10.

The alkyl group, cycloalkyl group, alkoxyl group, or alkoxycarbonyl group in R″ and R″″, the alkylene group or cycloalkylene group in R′″, and the ring formed by the bonding of R″ and R″″ to each other may be substituted with a hydroxyl group, a group containing a carbonyl group (for example, an acyl group, an aldehyde group, and an alkoxycarbonyl), a cyano group, or the like.

In General Formula (S2), the alkylene group for R′″ may have an ether bond in the alkylene chain.

Examples of the solvent represented by General Formula (S2) include propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monophenyl ether acetate, diethylene glycol monobutyl ether acetate, diethylene glycol monoethyl ether acetate, propylene glycol monoethyl ether acetate, propylene glycol monopropyl ether acetate, methyl-3-methoxy propionate, ethyl-3-methoxypropionate, ethyl-3-ethoxypropionate, propyl-3-methoxypropionate, ethyl methoxyacetate, ethyl ethoxyacetate, 2-methoxybutyl acetate, 3-methoxybutyl acetate, 4-methoxybutyl acetate, 3-methyl-3-methoxybutyl acetate, 3-ethyl-3-methoxybutyl acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, and 4-methyl-4-methoxy pentyl acetate, and propylene glycol monomethyl ether acetate is preferable.

Among these, R″ and R″″ are an unsubstituted alkyl group, and R′″ is preferably an unsubstituted alkylene group; and R″ and R″″ are more preferably any one of a methyl group and an ethyl group, and still more preferably a methyl group.

The solvent represented by General Formula (S2) may be used in combination with one or more other organic solvents. The combination solvent in this case is not particularly limited as long as it can be mixed with the solvent represented by General Formula (S2) without separation. The solvents represented by General Formula (S2) may be used in combination, and the solvent represented by General Formula (S2) may be mixed with other solvent selected from an ester-based solvent, a ketone-based solvent, an alcohol-based solvent, an amide-based solvent, an ether-based solvent, and a hydrocarbon-based solvent. One or more kinds of the combination solvents can be used, but in order to obtain stable performance, it is preferable to use only one kind thereof. In a case of being used in a mixture with one kind of the combination solvents, a mixing ratio of the solvent represented by General Formula (S2) and the combination solvent is, in a mass ratio, usually 20:80 to 99:1, preferably 50:50 to 97:3, more preferably from 60:40 to 95:5, and still more preferably from 60:40 to 90:10.

Further, as the organic solvent used as the developer, an ether-based solvent can also be suitably used.

Examples of the ether-based solvent that can be used include the above-mentioned ether-based solvents. Among these, an ether-based solvent containing one or more aromatic rings is preferable, a solvent represented by General Formula (S3) is more preferable, and anisole is still more preferable.

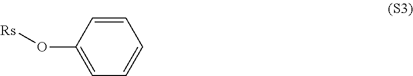

In General Formula (S3),

Rₛ represents an alkyl group. The alkyl group is preferably an alkyl group having 1 to 4 carbon atoms, more preferably a methyl group or an ethyl group, and still more preferably a methyl group.

In one embodiment, the developer preferably contains at least one organic solvent selected from the group consisting of a ketone-based solvent and an ester-based solvent, and more preferably contains a ketone-based solvent. In a case where the ketone-based solvent is used, as described above, the hydrocarbon-based solvent can be used in combination.

As the organic solvent contained in the developer in the present invention, an organic solvent used for an actinic ray-sensitive or radiation-sensitive resin composition as described later can be used.

(Surfactant)

The developer preferably contains a surfactant. Thus, a wettability to the resist film is improved, and the development proceeds more effectively.

As the surfactant, the same surfactant as used in the actinic ray-sensitive or radiation-sensitive resin composition as described later can be used.

The content of the surfactant is usually from 0.001% to 5% by mass, preferably from 0.005% to 2% by mass, and more preferably from 0.01% to 0.5% by mass, with respect to the total mass of the developer.

(Antioxidant)

The developer preferably contains an antioxidant. Thus, generation of an oxidizing agent over time can be suppressed, and the content of the oxidizing agent can be further reduced.

As the antioxidant, a known antioxidant can be used. In a case of being used for semiconductor applications, an amine-based antioxidant or a phenolic antioxidant is preferably used.

As examples of the amine-based antioxidant, reference can be made to a naphthylamine-based antioxidant, a phenylenediamine-based antioxidant, a diphenylamine-based antioxidant, and a phenothiazine-based antioxidant described in paragraph [0038] of JP2013-124266A, the contents of which are incorporated herein.

As examples of the phenolic antioxidant, reference can be made to a phenolic antioxidant described in paragraph [0038] of JP2013-124266A, the contents of which are incorporated herein.

The content of the antioxidant is not particularly limited, and is preferably 0.0001% to 1% by mass, more preferably 0.0001% to 0.1% by mass, and still more preferably 0.0001% to 0.01% by mass, with respect to the total mass of the developer. In a case where the content thereof is 0.0001% by mass or more, superior antioxidative effects can be obtained, and in a case where the content thereof is 1% by mass or less, development residue tends to be suppressed.

(Basic Compound)

The developer of the present invention preferably contains a basic compound. Specific examples of the basic compound include compounds exemplified as a basic compound (E) that can be contained in the actinic ray-sensitive or radiation-sensitive resin composition as described later.

As examples of the basic compound that can be contained in the developer of the present invention, reference can be made to compounds represented by Formula (1) described in paragraphs [0009] and [0031] to [0050] of JP2013-011858A, the contents of which are incorporated herein.

Among the above-mentioned nitrogen-containing compounds, nitrogen-containing compounds having an SP value of 18 or less are preferably used from the viewpoint of suppression of development defects. This is because the nitrogen-containing compounds having an SP value of 18 or less have good affinity with the rinsing liquid used in the above-mentioned rinsing step and can suppress occurrence of development defects such as precipitation.

The SP value of the nitrogen-containing compounds used in the present invention is calculated using the Fedors method described in “Properties of Polymers, Second Edition, published in 1976”. The equation for calculation used and the parameter for each of substituents are shown below.

SP value (Fedors method)=[(sum of cohesive energy for each of substituents)/(sum of volume for each of substituents)]^{0.5}

TABLE 1

| | Cohesive | | | Cohesive | |
|---|---|---|---|---|---|
| Sub- | energy | Volume | | energy | Volume |
| stituent | (J/mol) | (cm³/mol) | Substituent | (J/mol) | (cm³/mol) |
| CH₃ | 4,710 | 33.5 | CN | 25,530 | 24 |
| CH₂ | 4,940 | 16.1 | OH | 29,800 | 10 |
| CH | 3,430 | −1 | CHO | 21,350 | 22.3 |
| C | 1,470 | −19.2 | COOH | 27,630 | 28.5 |
| CH₂═ | 4,310 | 28.5 | —O— | 3,350 | 3.8 |
| ═CH— | 4,310 | 13.5 | CO | 17,370 | 10.8 |
| ═C< | 4,310 | −5.5 | COO | 18,000 | 18 |
| Ph | 31,940 | 71.4 | 5-Membered | 1,050 | 16 |
| | | | or higher ring | | |
| NH₂ | 12,560 | 19.2 | | | |
| NH | 8,370 | 4.5 | | | |
| N< | 4,190 | −9 | | | |

Excerpt of substituent constants for Fedors method (Properties of Polymers, Second Edition, p.p. 138 to 140)

(Cyclo)alkylamine compounds and nitrogen-containing aliphatic heterocyclic compounds satisfying the above-mentioned condition (SP value) are preferable, and 1-aminodecane, di-n-octylamine, tri-n-octylamine, or tetramethylethylenediamine is more preferable. The SP values and the like of these nitrogen-containing aliphatic heterocyclic compounds are shown in the following table.

TABLE 2

| | | | | | | SP |
|---|---|---|---|---|---|---|
| | CH₃ | CH₂ | NH₂ | NH | N | value |
| 1-Aminodecane | 1 | 9 | 1 | | | 17.7 |
| Di-n-octylamine | 2 | 14 | | 1 | | 17.1 |
| Tri-n-octylamine | 3 | 21 | | | 1 | 16.9 |
| Tetramethylethylene diamine | 4 | 2 | | | 2 | 15.8 |

The content of the basic compound (preferably a nitrogen-containing compound) in the developer is not particularly limited, and is preferably 10% by mass or less and more preferably from 0.5% to 5% by mass with respect to the total amount of the developer, from the viewpoint that superior effects of the present invention are achieved.

In the present invention, only one kind of the nitrogen-containing compounds may be used, or two or more kinds thereof having different chemical structures may be used in combination.

<Rinsing Liquid>

The rinsing liquid is used in the above-mentioned rinsing step and contains an organic solvent. Thus, it can also be referred to as an organic rinsing liquid.

A vapor pressure at 20° C. of the rinsing liquid (vapor pressure as a whole in a case of a mixed solvent) is preferably 0.05 kPa to 5 kPa, more preferably 0.1 kPa to 5 kPa, and still more preferably 0.12 kPa to 3 kPa. By setting the vapor pressure of the rinsing liquid to 0.05 kPa to 5 kPa, wafer in-plane temperature uniformity is enhanced and swelling due to permeation of the rinsing liquid is suppressed. As a result, wafer in-plane dimensional uniformity is improved.

(Organic Solvent)

As the organic solvent contained in the rinsing liquid of the present invention, various organic solvents are used, and at least one organic solvent organic selected from the group consisting of a hydrocarbon-based solvent, a ketone-based solvent, an ester-based solvent, an alcohol-based solvent, an amide-based solvent, and an ether-based solvent is preferably used.

Specific examples of these organic solvents are the same as the organic solvents described for the developer.

In a case where extreme ultraviolet rays (EUV light) and electron beams (EB) are used in the above-mentioned exposure step, as the organic solvent contained in the rinsing liquid, a hydrocarbon-based solvent is preferably used, and an aliphatic hydrocarbon-based solvent is more preferably used among the above-mentioned organic solvents. As the aliphatic hydrocarbon-based solvent used in the rinsing liquid, from the viewpoint of further improving effects thereof, an aliphatic hydrocarbon-based solvent having 5 or more carbon atoms (for example, pentane, hexane, octane, decane, undecane, dodecane, and hexadecane) is preferable, an aliphatic hydrocarbon-based solvent having 8 or more carbon atoms is more preferable, and an aliphatic hydrocarbon-based solvent having 10 or more carbon atoms is still more preferable.

Moreover, the upper limit value in the number of carbon atoms of the aliphatic hydrocarbon-based solvent is not particularly limited, and examples thereof include values of 16 or less, preferably values of 14 or less, and more preferably values of 12 or less.

Among the above-mentioned aliphatic hydrocarbon-based solvents, decane, undecane, or dodecane is preferable, and undecane is more preferable.

Further, as the hydrocarbon-based solvent contained in the rinsing liquid, an unsaturated hydrocarbon-based solvent can also be used, and examples thereof include an unsaturated hydrocarbon-based solvent such as octene, nonene, decene, undecene, dodecene, and hexadecene. The number of a double bond or triple bond possessed by the unsaturated hydrocarbon-based solvent is not particularly limited, and such bond may be at any position of the hydrocarbon chain. In addition, in a case where the unsaturated hydrocarbon-based solvent has a double bond, a cis-isomer and a trans-isomer may be mixed.

By using the hydrocarbon-based solvent (particularly an aliphatic hydrocarbon-based solvent) as the organic solvent contained in the rinsing liquid as above, an effect, in which the developer that has been slightly soaked into the resist film after the development is washed away, the swelling is further suppressed, and the pattern collapse is suppressed, is further exhibited.

Further, as the organic solvent contained in the rinsing liquid, a mixed solvent of the ester-based solvent and the hydrocarbon-based solvent, or a mixed solvent of the ketone-based solvent and the hydrocarbon-based solvent may be used. In a case of using the mixed solvent as described above, it is preferable to use a hydrocarbon-based solvent as a main component.

In a case where the ester-based solvent and the hydrocarbon-based solvent are used in combination, it is preferable to use butyl acetate or isoamyl acetate as the ester-based solvent. In addition, as the hydrocarbon-based solvent, it is preferable to use a saturated hydrocarbon-based solvent (for example, decane, dodecane, undecane, and hexadecane) from the viewpoint that the above effects are further exhibited.

In a case where the ketone-based solvent and the hydrocarbon-based solvent are used in combination, it is preferable to use 2-heptanone as the ketone-based solvent. In addition, as the hydrocarbon-based solvent, it is preferable to use a saturated hydrocarbon-based solvent (for example, decane, dodecane, undecane, and hexadecane) from the viewpoint that the above effects are further exhibited.

Further, in a case where the ester-based solvent and the hydrocarbon-based solvent are used in combination or in a case where the ketone-based solvent and the hydrocarbon-based solvent are used in combination, an unsaturated hydrocarbon-based solvent can also be used as the hydrocarbon-based solvent, and examples thereof include an unsaturated hydrocarbon-based solvent such as octene, nonene, decene, undecene, dodecene, and hexadecene. The number of a double bond or triple bond possessed by the unsaturated hydrocarbon-based solvent is not particularly limited, and such bond may be at any position of the hydrocarbon chain.

In addition, in a case where the unsaturated hydrocarbon-based solvent has a double bond, a cis-isomer and a trans-isomer may be mixed.

Furthermore, as the organic solvent contained in the rinsing liquid, an embodiment, in which at least one selected from the group consisting of the ester-based solvent and the ketone-based solvent is used, may be adopted from the viewpoint that it is particularly effective for reduction of residues after development.

In a case where the rinsing liquid contains at least one selected from the group consisting of the ester-based solvent and the ketone-based solvent, it is preferable that at least one solvent selected from the group consisting of butyl acetate, isopentyl acetate (isoamyl acetate), n-pentyl acetate, ethyl 3-ethoxypropionate (EEP, ethyl-3-ethoxypropionate), and 2-heptanone is preferably contained as a main component, and it is more preferable that at least one solvent selected from the group consisting of butyl acetate and 2-heptanone is contained as a main component.

Further, in a case where the rinsing liquid contains at least one selected from the group consisting of the ester-based solvent and the ketone-based solvent, it is preferable that a solvent selected from the group consisting of the ester-based solvent, the glycol ether-based solvent, the ketone-based solvent, and the alcohol-based solvent is contained as a minor component. Among these, a solvent selected from the group consisting of propylene glycol monomethyl ether acetate (PGMEA), propylene glycol monomethyl ether (PGME), ethyl acetate, ethyl lactate, methyl 3-methoxypropionate, cyclohexanone, methyl ethyl ketone, γ-butyrolactone, propanol, 3-methoxy-1-butanol, N-methylpyrrolidone, and propylene carbonate is more preferable.

Among these, in a case where the ester-based solvent is used as the organic solvent, it is preferable to use two or more ester-based solvents from the viewpoint that the above effects are further exhibited. Specific examples of this case include a case where an ester-based solvent (preferably, butyl acetate) is used as a main component and another ester-based solvent (preferably, propylene glycol monomethyl ether acetate (PGMEA)) having a chemical structure different from the ester-based solvent as the main component is used as a minor component.

Further, in a case where the ester-based solvent is used as the organic solvent, the glycol ether-based solvent may be used in addition to (one kind or two or more kinds of) the ester-based solvent from the viewpoint that the above effects are further exhibited. Specific examples of this case include a case where an ester-based solvent (preferably, butyl acetate) is used as a main component and a glycol ether-based solvent (preferably, propylene glycol monomethyl ether (PGME)) is used as a minor component.

In a case where the ketone-based solvent is used as the organic solvent, the ester-based solvent and/or the glycol ether-based solvent may be used in addition to (one kind or two or more kinds of) the ketone-based solvent from the viewpoint that the above effects are further exhibited. Specific examples of this case include a case where a ketone-based solvent (preferably, 2-heptanone) is used as a main component and an ester-based solvent (preferably, propylene glycol monomethyl ether acetate (PGMEA)) and/or a glycol ether-based solvent (preferably, propylene glycol monomethyl ether (PGME)) is used as a minor component.

Here, the above-mentioned “main component” means that the content with respect to the total mass of the organic solvent is 50% to 100% by mass, preferably 70% to 100% by mass, more preferably 80% to 100% by mass, still more preferably 90% to 100% by mass, and particularly preferably 95% to 100% by mass.

Further, in a case of containing a minor component, the content of the minor component is preferably 0.1% to 20% by mass, more preferably 0.5% to 10% by mass, and still more preferably 1% to 5% by mass, with respect to the total mass (100% by mass) of the main component.

As the rinsing liquid, the ether-based solvent can also be suitably used.

Examples of the ether-based solvent include, in addition to a glycol ether-based solvent containing a hydroxyl group, a glycol ether-based solvent containing no hydroxyl group such as dipropylene glycol dimethyl ether, dipropylene glycol diethyl ether, diethylene glycol dimethyl ether, and diethylene glycol diethyl ether; an aromatic ether-based solvent such as anisole and phenetole; a cyclic aliphatic ether-based solvent such as dioxane, tetrahydrofuran, tetrahydropyran, perfluoro-2-butyl tetrahydrofuran, perfluorotetrahydrofuran, 1,4-dioxane, cyclopentyl isopropyl ether, cyclopentyl sec-butyl ether, cyclopentyl tert-butyl ether, cyclohexyl isopropyl ether, cyclohexyl sec-butyl ether, and cyclohexyl tert-butyl ether; an acyclic aliphatic ether-based solvent having a linear alkyl group such as di-n-propyl ether, di-n-butyl ether, di-n-pentyl ether, and di-n-hexyl ether; and an acyclic aliphatic ether-based solvent having a branched alkyl group such as diisohexyl ether, methyl isopentyl ether, ethyl isopentyl ether, propyl isopentyl ether, diisoamyl ether (diisopentyl ether), methyl isobutyl ether, ethyl isobutyl ether, propyl isobutyl ether, diisobutyl ether, diisopropyl ether, ethyl isopropyl ether, methyl isopropyl ether, and diisohexyl ether. Among these, from the viewpoint of wafer in-plane uniformity, an acyclic aliphatic ether-based solvent having 8 to 12 carbon atoms is preferably used, and an acyclic aliphatic ether-based solvent having 8 to 12 carbon atoms and having a branched alkyl group is more preferable. Diisobutyl ether, diisoamyl ether (diisopentyl ether), or diisohexyl ether is still more preferable.

In one embodiment, the rinsing liquid preferably contains at least one organic solvent selected from the group consisting of the ketone-based solvent, the ether-based solvent, and the hydrocarbon-based solvent.

A plurality of the organic solvents may be mixed, or the organic solvent may be used by mixing it with an organic solvent other than those mentioned above. The solvent may be mixed with water, but a moisture content in the rinsing liquid is usually 60% by mass or less, preferably 30% by mass or less, more preferably 10% by mass or less, and still more preferably 5% by mass or less. By setting the moisture content to 60% by mass or less, good rinsing characteristics can be obtained.

(Surfactant)

The rinsing liquid preferably contains a surfactant. Thus, a wettability to the resist film is improved, and washing effects tend to be further improved.

As the surfactant, the same surfactant as used in the actinic ray-sensitive or radiation-sensitive resin composition as described later can be used.

The content of the surfactant is usually 0.001% to 5% by mass, preferably 0.005% to 2% by mass, and more preferably 0.01% to 0.5% by mass, with respect to the total mass of the rinsing liquid.

(Antioxidant)

The rinsing liquid preferably contains an antioxidant. Thus, generation of an oxidizing agent over time can be suppressed, and the content of the oxidizing agent can be further reduced. Specific examples and contents of the antioxidant are the same as those described above for the developer.

An electrically conductive compound may be added to the developer and the rinsing liquid in order to prevent the failure of chemical liquid pipes and/or various parts (filters, O-rings, tubes, and the like) associated with electrostatic charge and subsequently occurring electrostatic discharge.

Since the developer and the rinsing liquid contain a highly polar organic solvent having a specific dielectric constant of 6.0 or more, they themselves have an effect of suppressing the electrostatic charge. However, due to combination with the electrically conductive compound, it is possible to further suppress the electrostatic charge.

The electrically conductive compound is not particularly limited, and examples thereof include methanol. The addition amount thereof is not particularly limited, but is preferably 10% by mass or less, and more preferably 5% by mass or less, from the viewpoint of maintaining preferred development characteristics. For the members of the chemical liquid pipes, various pipes coated with SUS, or with polyethylene, polypropylene, or fluorine resins (polytetrafluoroethylene resin, perfluoroalkoxy resin, and the like) which has been subjected to an antistatic treatment can be used. Similarly, with respect to the filters and the O-rings, polyethylene, polypropylene, or fluorine resins (polytetrafluoroethylene resin, perfluoroalkoxy resin, and the like) which has been subjected to an antistatic treatment can be used.

[Actinic Ray-Sensitive or Radiation-Sensitive Resin Composition (Resist Composition)]

Next, the actinic ray-sensitive or radiation-sensitive resin composition used in the pattern forming method of the present invention will be described in detail.

[(A) Resin]

The actinic ray-sensitive or radiation-sensitive resin composition contains a resin A (hereinafter also referred to as “resin (A)”). The resin (A) is a resin having at least a repeating unit represented by General Formula (I) as described later and a repeating unit represented by General Formula (BII) as described later.

<Repeating Unit Represented by General Formula (I)>

The resin (A) has a repeating unit represented by General Formula (I).

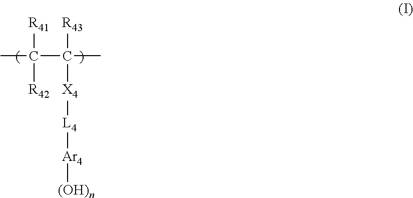

In General Formula (I),

R₄₁, R₄₂, and R₄₃ each independently represent a hydrogen atom, an alkyl group, a cycloalkyl group, a halogen atom, a cyano group, or an alkoxycarbonyl group, where R₄₂ may be bonded to Ar₄ to form a ring, and R₄₂ in such a case represents a single bond or an alkylene group,

X₄ represents a single bond, —COO—, or —CONR₆₄—, and R₆₄ represents a hydrogen atom or an alkyl group,

L₄ represents a single bond or an alkylene group,

Ar₄ represents an (n+1)-valent aromatic ring group, and in a case of being bonded to R₄₂ to form a ring, it represents an (n+2)-valent aromatic ring group, and

n represents an integer of 1 or more.

Examples of the alkyl group of R₄₁, R₄₂, or R₄₃ in General Formula (I) preferably include an alkyl group having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group, more preferably include an alkyl group having 8 or less carbon atoms, and still more preferably include an alkyl group having 3 or less carbon atoms, each of which may have a substituent.

The cycloalkyl group of R₄₁, R₄₂, or R₄₃ in General Formula (I) may be either monocyclic or polycyclic. Preferred examples thereof include a monocyclic cycloalkyl group having 3 to 8 carbon atoms, such as a cyclopropyl group, a cyclopentyl group, and a cyclohexyl group, each of which may have a substituent.

Examples of the halogen atom of R₄₁, R₄₂, or R₄₃ in General Formula (I) include a fluorine atom, a chlorine atom, a bromine atom, and an iodine atom, with the fluorine atom being preferable.

The alkyl group included in the alkoxycarbonyl group of R₄₁, R₄₂, or R₄₃ in General Formula (I) is preferably the same as the alkyl group in R₄₁, R₄₂, or R₄₃.

In a case where R₄₂ in General Formula (I) represents an alkylene group, examples thereof preferably include an alkylene group having 1 to 8 carbon atoms such as a methylene group, an ethylene group, a propylene group, a butylene group, a hexylene group, and an octylene group. An alkylene group having 1 to 4 carbon atoms is more preferable, and an alkylene group having 1 to 2 carbon atoms is still more preferable.

R₄₁, R₄₂, and R₄₃ are preferably a hydrogen atom or an alkyl group, and more preferably a hydrogen atom or a methyl group.

Examples of the alkyl group represented by R₆₄ of X₄ in General Formula (I) include the same alkyl group as the above-mentioned alkyl group. X₄ is preferably a single bond.

Examples of the alkylene group represented by L₄ in General Formula (I) include the same alkylene group as the above-mentioned alkylene group.

Preferred examples of the substituent in each of the groups include an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, and a nitro group, and the substituent preferably has 8 or less carbon atoms.

Ar₄ represents an (n+1)-valent aromatic ring group. A divalent aromatic ring group in a case where n is 1 may have a substituent, and preferred examples thereof include an arylene group having 6 to 18 carbon atoms, such as a phenylene group, a tolylene group, a naphthylene group, and an anthracenylene group, or an aromatic ring group including a heterocycle, such as thiophene, furan, pyrrole, benzothiophene, benzofuran, benzopyrrole, triazine, imidazole, benzimidazole, triazole, thiadiazole, and thiazole.

Among these, Ar₄ is preferably a phenylene group or a naphthylene group.

Specific suitable examples of the (n+1)-valent aromatic ring group in a case where n is an integer of 2 or more include groups formed by removing any (n−1) hydrogen atoms from the specific examples of the divalent aromatic ring groups.

The (n+1)-valent aromatic ring group may further have a substituent.

Examples of the substituent which can be contained in the alkyl group, the cycloalkyl group, the alkoxycarbonyl group, the alkylene group, and the (n+1)-valent aromatic ring group include the alkyl groups mentioned above for R₄₁, R₄₂, or R₄₃ in General Formula (I), alkoxy groups such as a methoxy group, an ethoxy group, a hydroxyethoxy group, a propoxy group, a hydroxypropoxy group, and a butoxy group; and aryl groups such as a phenyl group.

Preferred examples of the alkyl group of R₆₄ in —CONR₆₄— represented by X₄ (R₆₄ represents a hydrogen atom or an alkyl group) include an alkyl group having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group, and more preferred examples of the alkyl group include an alkyl group having 8 or less carbon atoms, each of which may have a substituent.

X₄ is preferably a single bond, —COO—, or —CONH—, and more preferably a single bond or —COO—.

Preferred examples of the alkyl group in L₄ include an alkylene group having 1 to 8 carbon atoms, such as a methylene group, an ethylene group, a propylene group, a butylene group, a hexylene group, and an octylene group, each of which may have a substituent.

As Ar₄, an aromatic ring group having 6 to 18 carbon atoms, which may have a substituent, is more preferable, and a benzene ring group, a naphthalene ring group, or a biphenylene ring group is more preferable.

The repeating unit represented by General Formula (I) preferably includes a hydroxystyrene structure or a hydroxynaphthalene structure. That is, Ar₄ is preferably a benzene ring group or a naphthalene ring group.

n represents an integer of 1 or more, preferably represents an integer of 1 to 5, and more preferably represents an integer of 1 to 3.

Preferred examples of the repeating unit represented by General Formula (I) include a repeating unit represented by General Formula (p1).

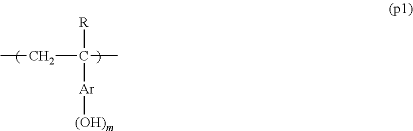

R in General Formula (p1) represents a hydrogen atom, a halogen atom, or a linear or branched alkyl group having 1 to 4 carbon atoms. A plurality of R's may be the same as or different from each other. R in General Formula (p1) is particularly preferably a hydrogen atom.

Ar in General Formula (p1) represents an aromatic ring, and examples thereof include an aromatic hydrocarbon ring having 6 to 18 carbon atoms, which may have a substituent, such as a benzene ring, a naphthalene ring, an anthracene ring, a fluorene ring, and a phenanthrene ring, or an aromatic ring heterocycle including a heterocycle, such as for example, thiophene ring, furan ring, pyrrole ring, a benzothiophene ring, a benzofuran ring, a benzopyrrole ring, a triazine ring, imidazole ring, a benzimidazole ring, a triazole ring, a thiadiazole ring, and a thiazole ring. Among those, the benzene ring or the naphthalene ring is preferable.

m in General Formula (p1) represents an integer of 1 to 5, and is preferably 1 to 3.

Specific examples of the repeating unit represented by General Formula (I) are shown below, but the present invention is not limited thereto. In the formula, a represents an integer of 1 to 5.

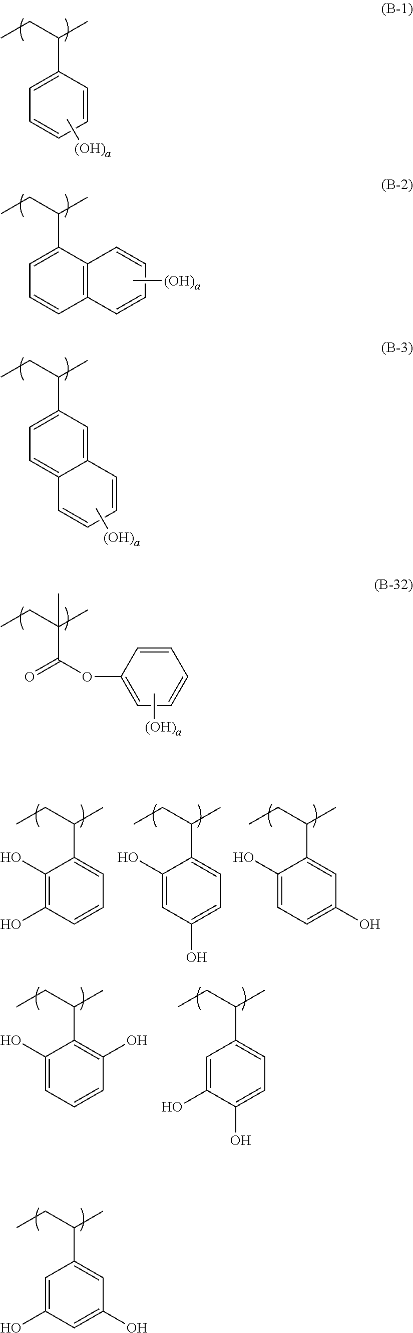

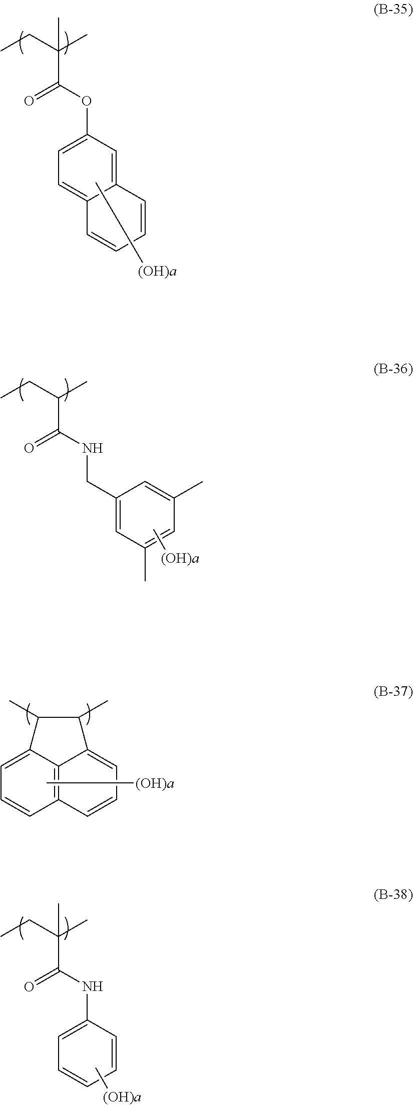

In the resin (A), one kind of the repeating units represented by General Formula (I) may be present or two or more kinds thereof may be present.

The content of the repeating unit represented by General Formula (I) is preferably 10% by mol or more, more preferably 20% by mol or more, and still more preferably 25% by mol or more, with respect to all the repeating units in the resin (A), because sensitivity to electron beams or extreme ultraviolet rays becomes good and occurrence of pattern collapse is also further suppressed, thereby resulting in superior etching resistance.

The upper limit of the content of the repeating unit represented by General Formula (I) is not particularly limited, and is, for example, 80% by mol or less, preferably 70% by mol or less, and more preferably 60% by mol or less, with respect to all the repeating units in the resin (A).

<Repeating Unit Represented by General Formula (BII)>

The resin (A) has a repeating unit represented by General Formula (BII).

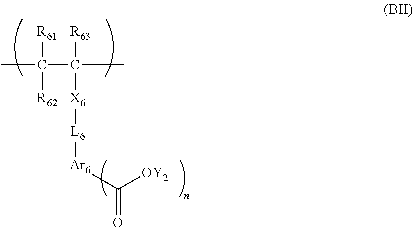

In General Formula (BII),

R₆₁, R₆₂, and R₆₃ each independently represent a hydrogen atom, an alkyl group, a cycloalkyl group, a halogen atom, a cyano group, or an alkoxycarbonyl group, where R₆₂ may be bonded to Ar₆ to form a ring, and R₆₂ in such a case represents a single bond or an alkylene group.

X₆ represents a single bond, —COO—, or —CONR₆₄—. R₆₄ represents a hydrogen atom or an alkyl group.

L₆ represents a single bond or an alkylene group.

Ar₆ represents an (n+1)-valent aromatic ring group, and in a case where Ar₆ is bonded with R₆₂ to form a ring, it represents an (n+2)-valent aromatic ring group.

Y₂, in a case where n=1, represents a group capable of leaving by the action of an acid, and in a case where n≥2, Y2's each independently represent a hydrogen atom or a group capable of leaving by the action of an acid, where at least one of Y₂'s represents a group capable of leaving by the action of an acid.

n represents an integer of 1 or more.

Preferred examples of the alkyl group of R₆₁, R₆₂, and R₆₃ in General Formula (BII) include an alkyl group having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group, more preferred examples of the alkyl group include an alkyl group having 8 or less carbon atoms, and still more preferred examples of the alkyl group include an alkyl group having 3 or less carbon atoms, each of which may have a substituent.

Examples of the cycloalkyl group of R₆₁, R₆₂, and R₆₃ in General Formula (BII) include a monocyclic cycloalkyl group having 3 to 8 carbon atoms such as a cyclopropyl group, a cyclopentyl group, and a cyclohexyl group.

Examples of the halogen atom of R₆₁, R₆₂, or R₆₃ in General Formula (BII) include a fluorine atom, a chlorine atom, a bromine atom, and an iodine atom, with the fluorine atom being preferable.

Examples of the alkyl group contained in the alkoxycarbonyl group of R₆₁, R₆₂, and R₆₃ in General Formula (BII) include the same alkyl group as the above-mentioned alkyl group.

In a case where R₆₂ in General Formula (BII) represents an alkylene group, the alkylene group is preferably an alkylene group having 1 to 8 carbon atoms, such as a methylene group, an ethylene group, a propylene group, a butylene group, a hexylene group, and an octylene group. An alkylene group having 1 to 4 carbon atoms is more preferable, and an alkylene group having 1 to 2 carbon atoms is still more preferable.

R₆₁, R₆₂, and R₆₃ are preferably a hydrogen atom or an alkyl group, and more preferably a hydrogen atom or a methyl group.

Examples of the alkyl group represented by R₆₄ of X₆ in General Formula (BII) include the same alkyl group as the above-mentioned alkyl group. X₆ is preferably a single bond.

Examples of the alkylene group represented by L₆ in General Formula (BII) include the same alkylene group as the above-mentioned alkylene group.

Ar₆ represents an (n+1)-valent aromatic ring group. A divalent aromatic ring group in a case where n is 1 may have a substituent, and preferred examples thereof include an arylene group having 6 to 18 carbon atoms, such as a phenylene group, a tolylene group, a naphthylene group, and an anthracenylene group, or an aromatic ring group including a heterocycle, such as thiophene, furan, pyrrole, benzothiophene, benzofuran, benzopyrrole, triazine, imidazole, benzimidazole, triazole, thiadiazole, and thiazole.

Among these, Ar₄ is preferably a phenylene group or a naphthylene group.

n represents an integer of 1 or more, preferably represents an integer of 1 to 4, and more preferably represents an integer of 1 to 3.

Specific suitable examples of the (n+1)-valent aromatic ring group in a case where n is an integer of 2 or more include groups formed by removing any (n−1) hydrogen atoms from the specific examples of the divalent aromatic ring groups.

Each of the groups may have a substituent, and examples of the substituent include an alkyl group (having 1 to 4 carbon atoms), a halogen atom, a hydroxyl group, an alkoxy group (having 1 to 4 carbon atoms), a carboxyl group, and an alkoxycarbonyl group (having 2 to 6 carbon atoms), with those having 8 or less carbon atoms being preferable.

The group capable of leaving by the action of an acid as Y₂ is preferably Formula (Y1), (Y3), or (Y4).

—C(Rx₁)(Rx₂)(Rx₃) Formula (Y1):

—C(R₃₆)(R₃₇)(OR₃₈) Formula (Y3):

—C(Rn)(H)(Ar) Formula (Y4):

In Formula (Y1), Rx₁ to Rx₃ each independently represent a (linear or branched) alkyl group or a (monocyclic or polycyclic) cycloalkyl group. Here, in a case where all of Rx₁ to Rx₃ are (linear or branched) alkyl groups, it is preferable that at least two of Rx₁, . . . , or Rx₃ are methyl groups.

Two of Rx₁ to Rx₃ may be bonded to each other to form a cycle (monocycle or polycycle).

As the alkyl group of Rx₁ to Rx₃, an alkyl group having 1 to 4 carbon atoms, such as a methyl group, an ethyl group, an n-propyl group, an isopropyl group, an n-butyl group, an isobutyl group, and a t-butyl group is preferable.

As the cycloalkyl group of Rx₁ to Rx₃, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable.

As the cycloalkyl group formed by the bonding of two of Rx₁ to Rx₃ to each other, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable, and a monocyclic cycloalkyl group having 5 or 6 carbon atoms is more preferable.

In the cycloalkyl group formed by the bonding of two of Rx₁ to Rx₃ to each other, for example, one of the methylene groups constituting the ring may be substituted with a heteroatom such as an oxygen atom, or with a group having a heteroatom, such as a carbonyl group.

An embodiment of the repeating unit represented by General Formula (Y1), for example, in which Rx₁ is a methyl group or an ethyl group, and Rx₂ and Rx₃ are bonded to each other to form the above-mentioned cycloalkyl group, is preferable.

In Formula (Y3), R₃₆ to R₃₈ each independently represent a hydrogen atom or a monovalent organic group. R₃₇ and R₃₈ may be bonded to each other to form a ring. Examples of the monovalent organic group include an alkyl group, a cycloalkyl group, an aryl group, an aralkyl group, and an alkenyl group. R₃₆ is also preferably a hydrogen atom.

As a preferred Formula (Y3), a structure represented by General Formula (Y3-1) is more preferable.

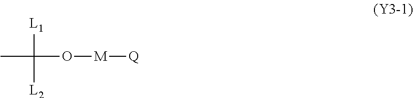

Here, L₁ and L₂ each independently represent a hydrogen atom, an alkyl group, a cycloalkyl group, an aryl group, or a group obtained by combining an alkylene group and an aryl group.

M represents a single bond or a divalent linking group.

Q represents an alkyl group, a cycloalkyl group which may include a heteroatom, an aryl group which may include a heteroatom, an amino group, an ammonium group, a mercapto group, a cyano group, or an aldehyde group.

It is preferable that at least one of L₁ or L₂ is a hydrogen atom, and at least one of L₁ or L₂ is an alkyl group, a cycloalkyl group, an aryl group, or a group obtained by combining an alkylene group and an aryl group.

At least two of Q, M, or L₁ may be bonded to each other to form a ring (preferably a 5- or 6-membered ring).

For the improvement of pattern collapse performance, L₂ is preferably a secondary or tertiary alkyl group, and more preferably a tertiary alkyl group. Examples of the secondary alkyl group include an isopropyl group, a cyclohexyl group, and a norbornyl group, and examples of the tertiary alkyl group include a tert-butyl group and adamantane. In these embodiments, since Tg and/or activation energy is high, suppression of fogging can be achieved, in addition to secured film hardness.

In Formula (Y4), Ar represents an aromatic ring group. Rn represents an alkyl group, a cycloalkyl group, or an aryl group. Rn and Ar may be bonded to each other to form a non-aromatic ring. Ar is preferably an aryl group.

The repeating unit represented by General Formula (BII) is preferably a repeating unit represented by General Formula (BIII).

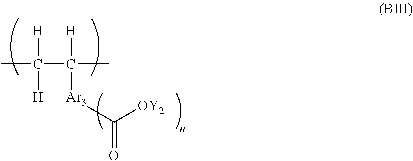

In General Formula (BIII)

Ar₃ represents an aromatic ring group.

Y₂, in a case where n=1, represents a group capable of leaving by the action of an acid, and in a case where n≥2, Y₂'s each independently represent a hydrogen atom or a group capable of leaving by the action of an acid, where at least one of Y₂'s represents a group capable of leaving by the action of an acid. The group capable of capable of leaving by the action of an acid as Y₂ is preferably one of Formula (Y1), (Y3), or (Y4) and more preferably Formula (Y1).

n represents an integer of 1 or more, and n is preferably 1 to 4 and more preferably 1 or 2.

The aromatic ring group represented by Ar₃ is preferably a benzene ring group or a naphthalene ring group, and more preferably a benzene ring group.

At least one of Rx₁, . . . , or Rx₃ in Formula (Y1) is preferably a methyl group or an ethyl group, and the others are preferably a linear or branched alkyl group having 1 to 6 carbon atoms or a cyclic alkyl group having 4 to 8 carbon atoms. In addition, it is more preferable that two of Rx₁ to Rx₃ are bonded to each other to form a cycloalkyl group.

In a case where Rx₂ and Rx₃ are bonded to each other to form a cycloalkyl group, activation energy is moderately lowered, and acid diffusion length is shortened, leading to an increase in exposure latitude and/or improvement in resolution. In addition, as the total number of carbon atoms of Rx₁ to Rx₃ is smaller, the outgassing performance is advantageous.

Due to good pattern collapse performance and excellent outgassing performance, a case where Y₂ in General Formulae (BII) and (BIII) is Formula (Y1) is preferable as compared with a case where Y₂ is Formula (Y3) or (Y4), and due to superior pattern collapse performance, it is more preferable that at least two of Rx₁, . . . , or Rx₃ in Formula (Y1) are bonded to each other to form a ring.

Further, due to excellent outgassing performance, in Formula (Y1), a case where at least two of Rx₁, . . . , or Rx₃ are bonded to each other to form a ring is preferable as compared with a case where any one of Rx₁ to Rx₃ is a cycloalkyl group.

In Formula (Y1), in a case where two of Rx₁ to Rx₃ are bonded to each other to form a ring, the ring thus formed is preferably a cycloalkyl group, more preferably a cyclopentyl group or a cyclohexyl group, and still more preferably a cyclopentyl group. At this time, one of Rx₁ to Rx₃ which does not form a ring is preferably a methyl group or an ethyl group, and more preferably a methyl group.

Specific examples of the repeating unit represented by General Formula (BII) are shown below, but the present invention is not limited thereto.

In the specific examples, Rx represents a hydrogen atom, CH₃, CF₃, or CH₂OH. Rxa and Rxb each represent an alkyl group having 1 to 4 carbon atoms. Z represents a substituent containing a polar group, and in a case where Z's are present in plural numbers, they are each independent. p represents 0 or a positive integer. Examples of the substituent containing a polar group, represented by Z, include a linear or branched alkyl group, and a cycloalkyl group, each having a hydroxyl group, a cyano group, an amino group, an alkylamido group, or a sulfonamido group, and preferably an alkyl group having a hydroxyl group. As the branched alkyl group, an isopropyl group is preferable.

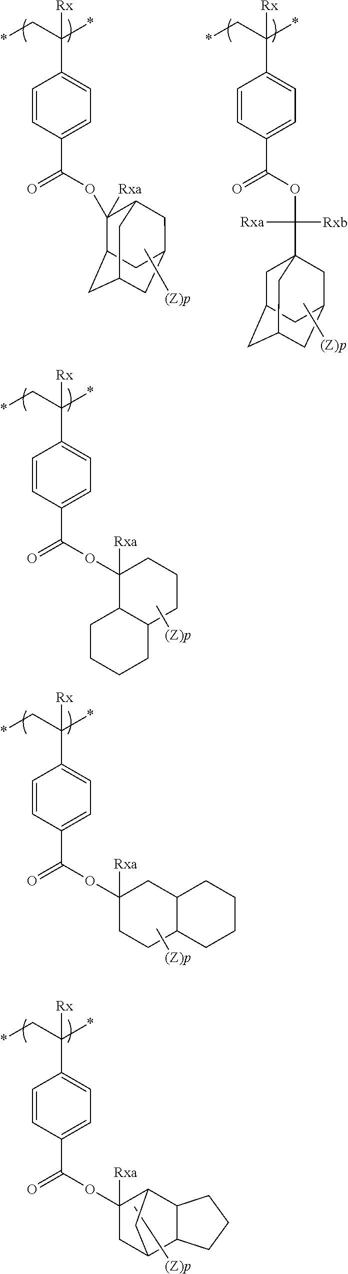

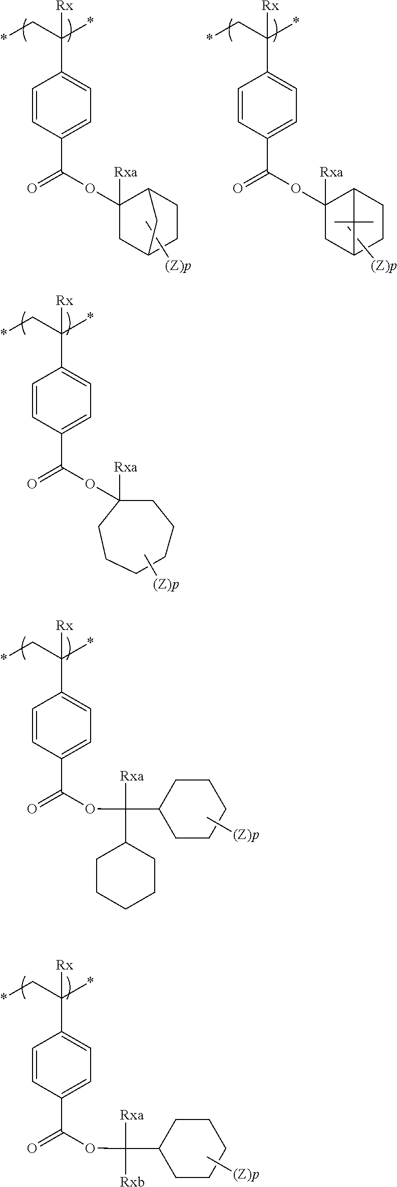

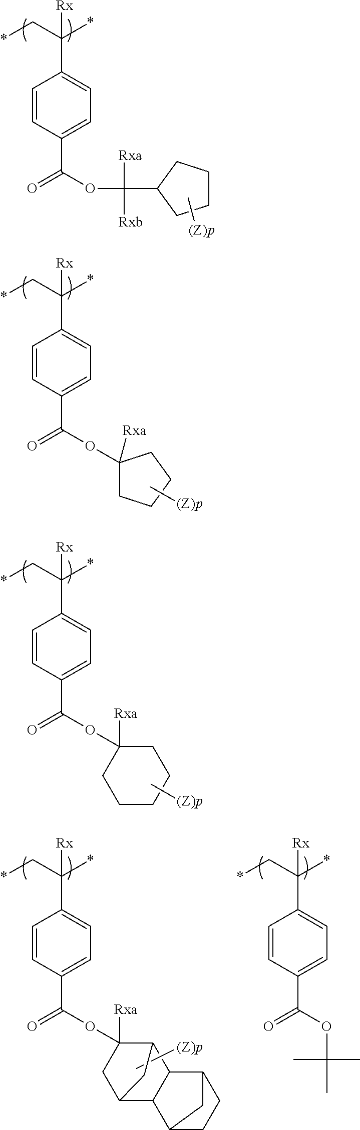

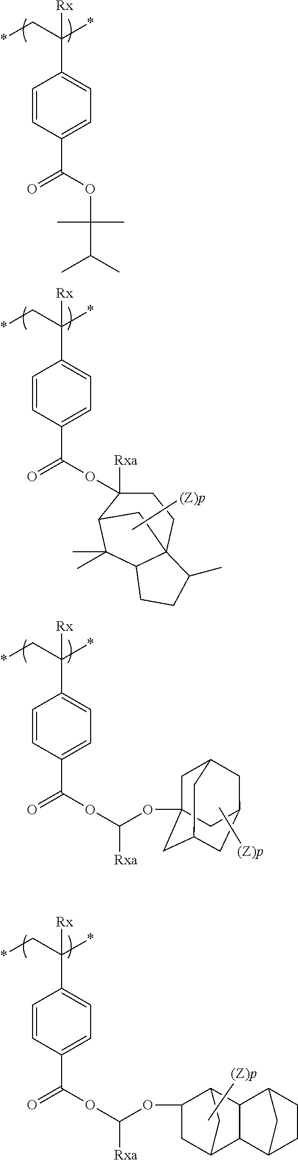

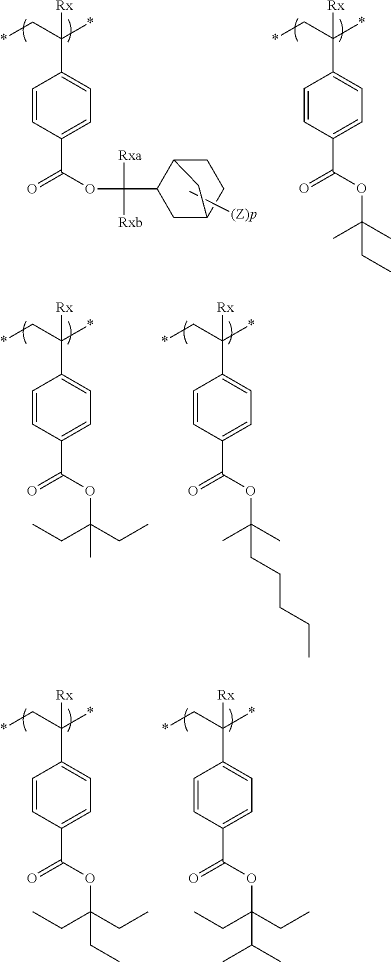

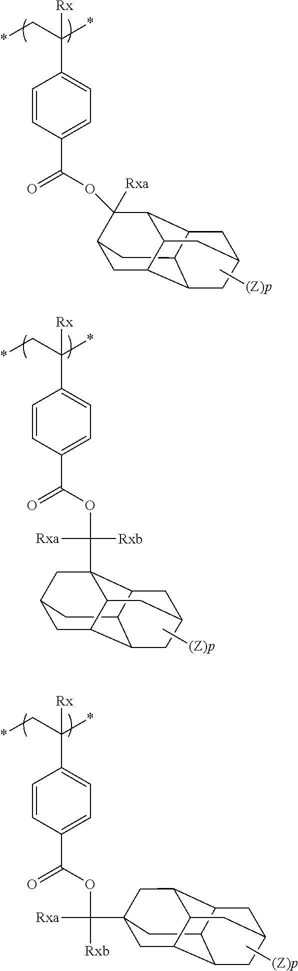

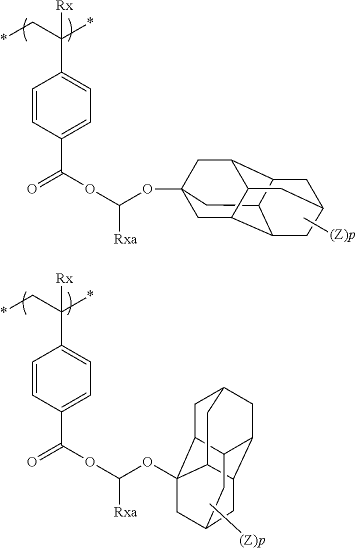

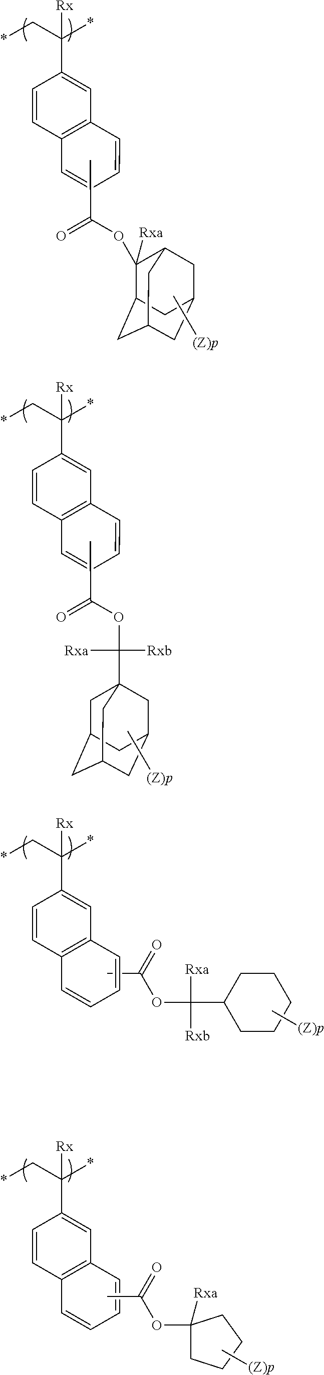

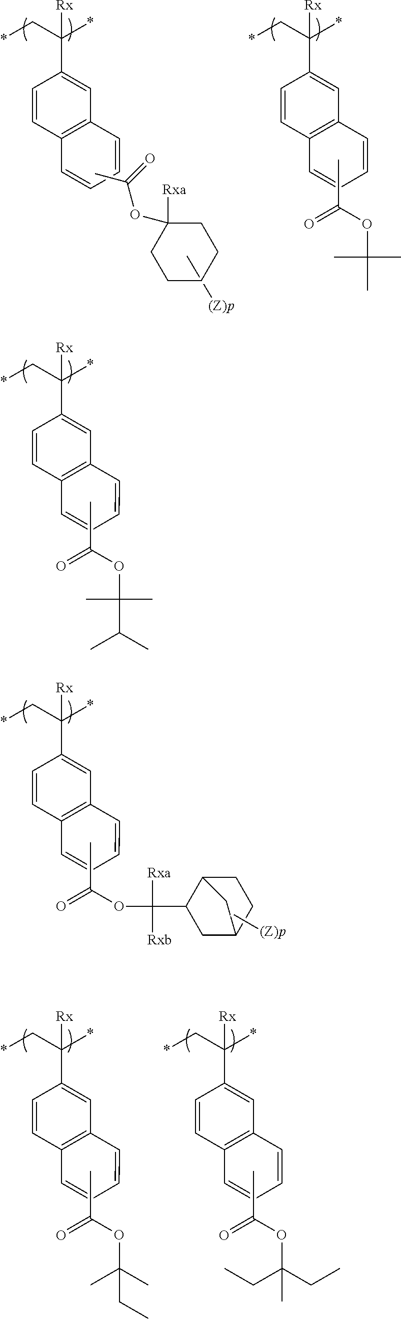

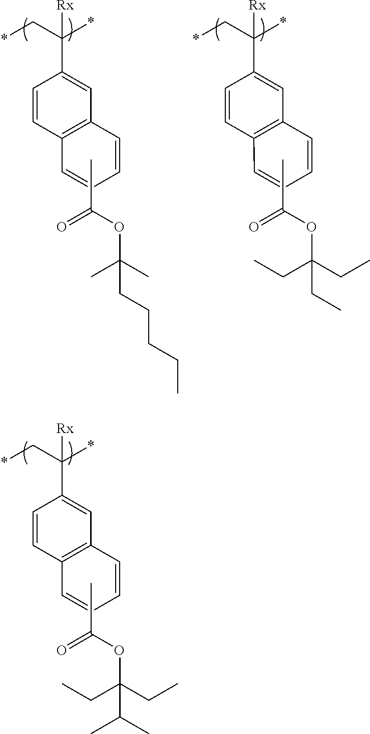

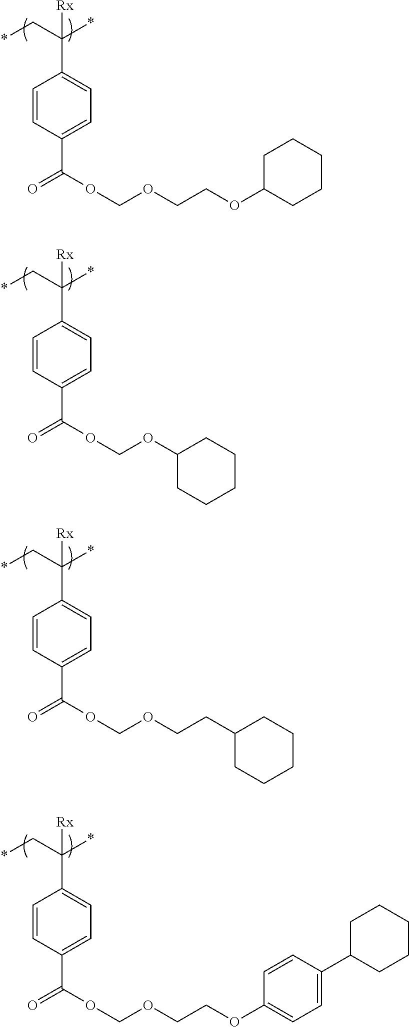

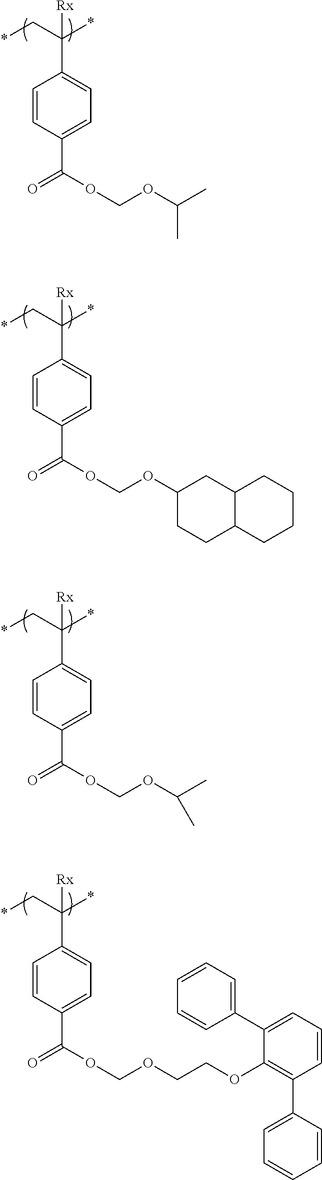

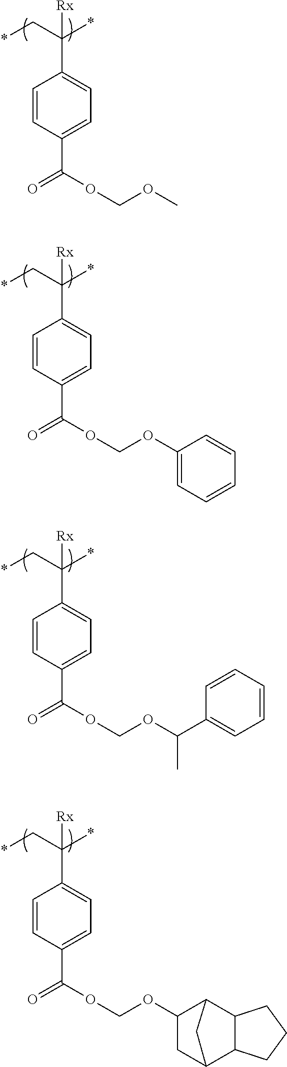

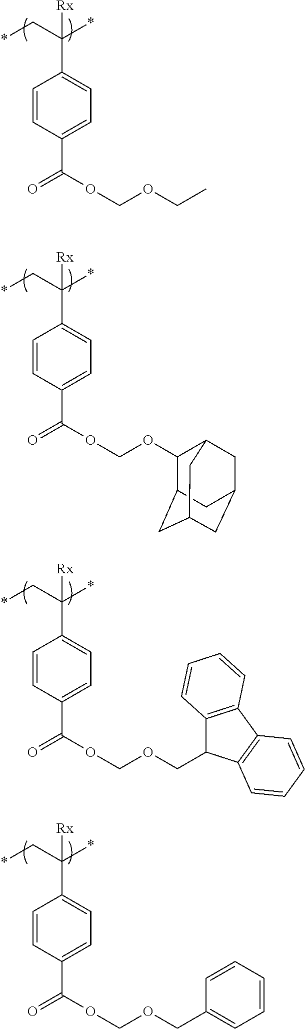

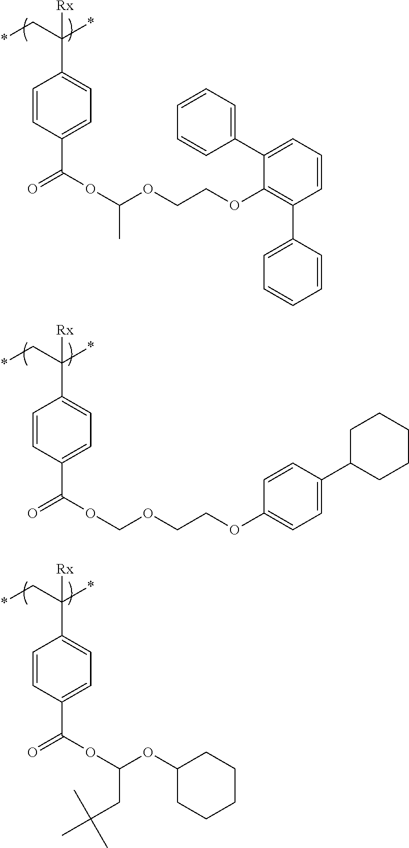

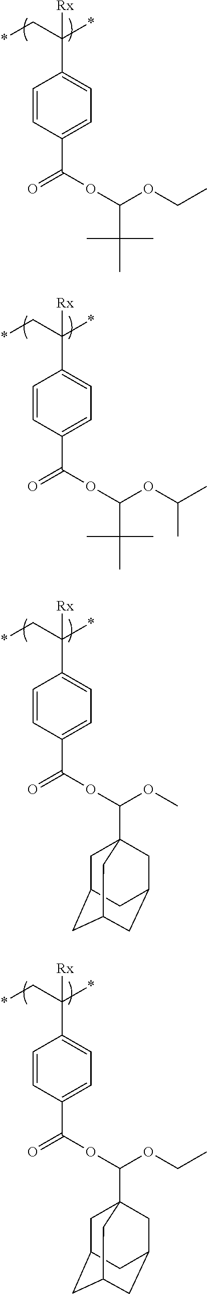

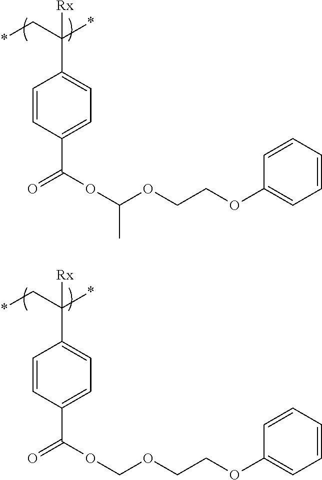

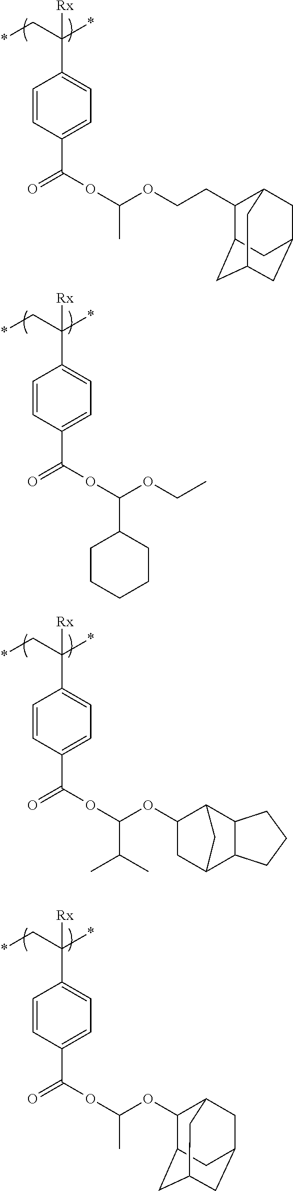

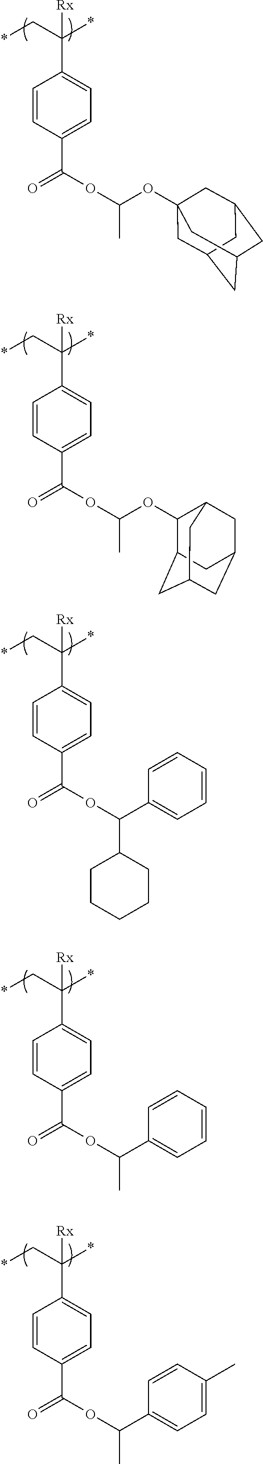

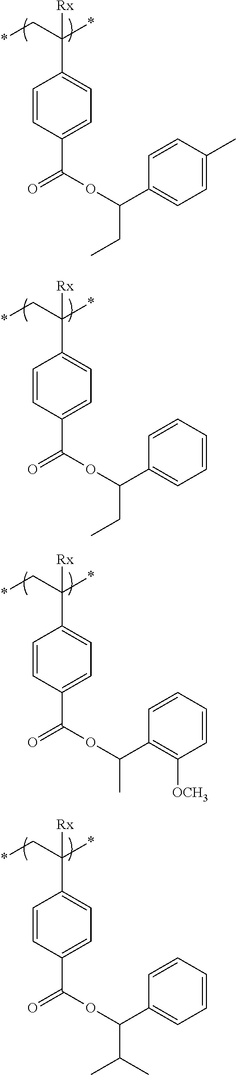

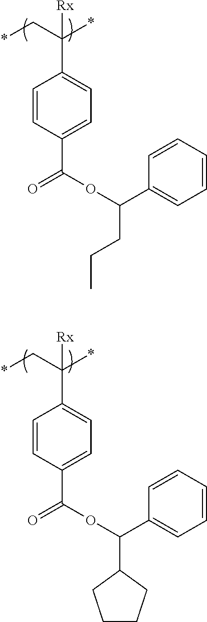

The repeating unit represented by General Formula (BII) may be used singly or in combination of two or more kinds thereof.

The content of the repeating unit (a total thereof in a case where a plurality of kinds thereof are contained) represented by General Formula (BII) in the resin (A) is preferably from 10% by mol to 80% by mol, more preferably from 20% by mol to 70% by mol, and still more preferably from 25% by mol to 65% by mol, with respect to all the repeating units in the resin (A).

<Repeating Unit (c) Having Structure in which Polar Group is Protected with Leaving Group Capable of Decomposing by Action of Acid to Leave>

In a preferred embodiment, the resin (A) has a repeating unit other than the repeating unit represented by General Formula (BII) which is a repeating unit (c) having a structure in which a polar group is protected with a leaving group capable of decomposing by the action of an acid to leave.

Examples of the polar group in the repeating unit (c) having a structure in which a polar group is protected with a leaving group capable of decomposing by the action of an acid to leave (acid-decomposable group) include a carboxyl group, an alcoholic hydroxyl group, a phenolic hydroxyl group, and a sulfonic acid group. Among these, the polar group is preferably a carboxyl group, an alcoholic hydroxyl group, or a phenolic hydroxyl group, and more preferably a carboxyl group or a phenolic hydroxyl group.

Furthermore, in a case where the resin (A) has a repeating unit having an acid-decomposable group, the solubility in an alkali developer is enhanced by the action of an acid, and thus, the solubility in an organic solvent decreases.

Examples of the leaving group capable of decomposing by the action of an acid to leave include groups represented by Formulae (Y1) to (Y4).

—C(Rx₁)(Rx₂)(Rx₃) Formula (Y1):

—C(═O)OC(Rx₁)(Rx₂)(Rx₃) Formula (Y2):

—C(R₃₆)(R₃₇)(OR₃₈) Formula (Y3):

—C(Rn)(H)(Ar) Formula (Y4):

In these formulae, Formulae (Y1), (Y3), and (Y4) have the same definitions as Formulae (Y1), (Y3), and (Y4) as Y2 in the repeating unit represented by General Formula (BII).

Further, Rx₁ to Rx₃ in Formula (Y2) have the same definitions as Rx₁ to Rx₃ in Formula (Y1).

As the repeating unit (c), a repeating unit represented by General Formula (AI) or (AII) is preferable.

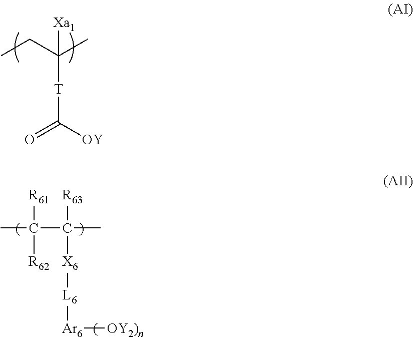

In General Formula (AI),

Xa₁ represents a hydrogen atom or an alkyl group.

T represents a single bond or a divalent linking group.

Y represents a group capable of leaving by the action of an acid. Y is preferably any one of the above-mentioned Formulae (Y1) to (Y4).

The alkyl group represented by Xa₁ is preferably an alkyl group having 1 to 4 carbon atoms, more preferably a methyl group or an ethyl group, and still more preferably a methyl group. Xa₁ is preferably a hydrogen atom or a methyl group.

Examples of the divalent linking group represented by T include an alkylene group having 1 to 8 carbon atoms, with an alkylene group having 1 to 4 carbon atoms being preferable. T is preferably a single bond.

R₆₁ to R₆₃, X₆, L₆, Ar₆, Y₂, and n in General Formula (AII) have the same definitions as R₆₁ to R₆₃, X₆, L₆, Ar₆, Y₂, and n in General Formula (BII).

Y₂ in General Formula (AII) is preferably any one of the above-mentioned Formulae (Y1) to (Y4).

The repeating unit (c) may be used singly or in combination of two or more kinds thereof.

The content of the repeating unit (c) (a total thereof in a case where a plurality of kinds thereof are contained) in the resin (A) is preferably from 5% by mol to 60% by mol, and more preferably from 10% by mol to 50% by mol, with respect to all the repeating units in the resin (A).

In a case where the resin (A) further has the repeating unit (c) having a structure in which the polar group is protected with a leaving group capable of decomposing by the action of an acid to leave, a total of the repeating unit (c) and the repeating unit represented by General Formula (BII) is preferably 10% by mol to 80% by mol, more preferably 20% by mol to 70% by mol, and still more preferably 25% by mol to 65% by mol, with respect to all the repeating units in the resin (A).

In this case, the repeating unit (c) is preferably 5% by mol to 75% by mol, more preferably 5% by mol to 60% by mol, and still more preferably 10% by mol to 50% by mol, with respect to all the repeating units in the resin (A), and the repeating unit represented by General Formula (BII) is preferably 10% by mol to 75% by mol, more preferably 15% by mol to 65% by mol, and still more preferably 15% by mol to 60% by mol, with respect to all the repeating units in the resin (A).

<Repeating Unit Having Lactone Group or Sultone Group>

The resin (A) preferably contains a repeating unit having a lactone group or a sultone (cyclic sulfonic acid ester) group. As the lactone group or sultone group, any group can be used as long as it contains a lactone structure or sultone structure, and is preferably a group having a 5- to 7-membered ring lactone structure or sultone structure, with those having a 5- to 7-membered ring lactone structure or sultone structure to which another ring structure is fused so as to form a bicyclo structure or Spiro structure being preferable.

The resin (A) still more preferably has a repeating unit having a group having a lactone structure represented by any one of General Formulae (LC1-1) to (LC1-17), or a sultone structure represented by any one of General Formulae (SL1-1) to (SL1-3). Further, the group having a lactone structure or a sultone structure may be directly bonded to the main chain. A preferred lactone structure or sultone structure is a group represented by General Formula (LC1-1), (LC1-4), (LC1-5), (LC1-6), (LC1-13), or (LC1-14).

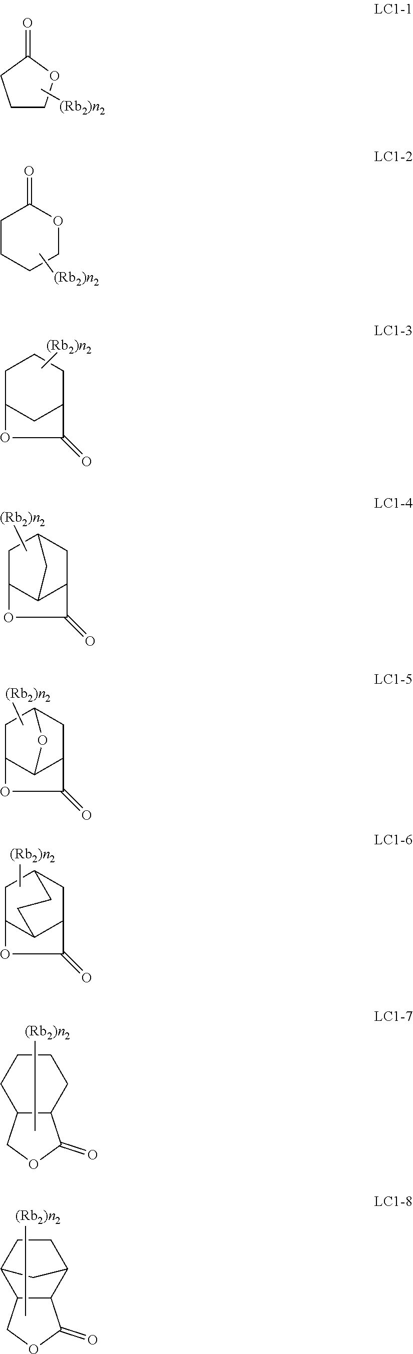

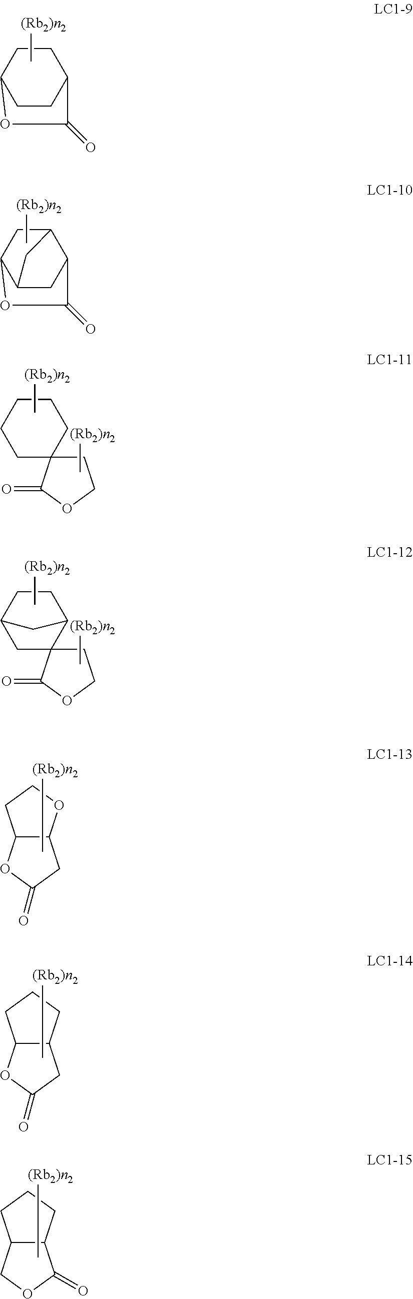

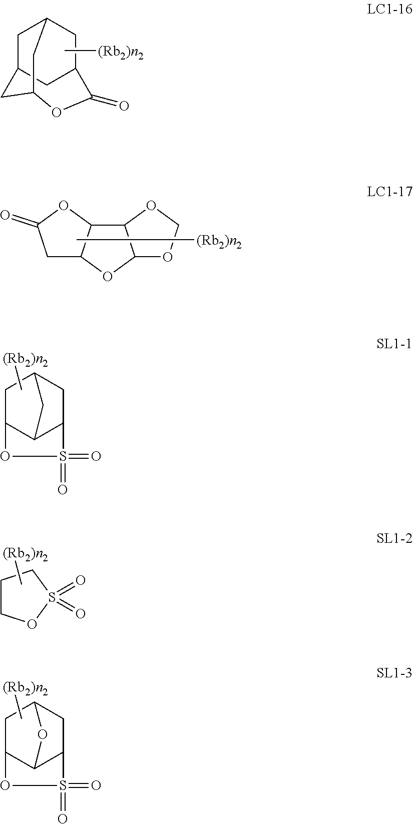

The lactone structure moiety or the sultone structure moiety may or may not have a substituent (Rb₂). Preferred examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 1 to 8 carbon atoms, a carboxyl group, a halogen atom, a hydroxyl group, a cyano group, and an acid-decomposable group. n₂ represents an integer of 0 to 4. In a case where n₂ is 2 or more, Rb₂'s which are present in plural numbers may be the same as or different from each other, and further, Rb₂'s which are present in plural numbers may be bonded to each other to form a ring.

Examples of the repeating unit having a group having a lactone structure represented by any one of General Formulae (LC1-1) to (LC1-17) or a sultone structure represented by any one of General Formulae (SL1-1) to (SL1-3) include a repeating unit represented by General Formula (AI).

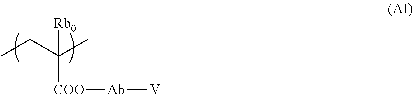

In General Formula (AI), Rb₀ represents a hydrogen atom, a halogen atom, or an alkyl group having 1 to 4 carbon atoms.

Preferred examples of the substituent which the alkyl group of Rb₀ may have include a hydroxyl group and a halogen atom.

Examples of the halogen atom of Rb₀ include a fluorine atom, a chlorine atom, a bromine atom, and an iodine atom. Rb₀ is preferably a hydrogen atom or a methyl group.

Ab represents a single bond, an alkylene group, a divalent linking group having a monocyclic or polycyclic alicyclic hydrocarbon structure, an ether group, an ester group, a carbonyl group, a carboxyl group, or a divalent group formed by combination thereof. Ab is preferably a single bond or a linking group represented by -Ab₁-CO₂—. Ab₁ is a linear or branched alkylene group or a monocyclic or polycyclic cycloalkylene group, and preferably a methylene group, an ethylene group, a cyclohexylene group, an adamantylene group, or a norbornylene group.

V represents a group represented by any one of General Formulae (LC1-1) to (LC1-17), and (SL1-1) to (SL1-3).

As the repeating unit having a lactone group or a sultone group, an optical isomer thereof is usually present, and any optical isomer may be used. Further, one kind of optical isomer may be used singly or a plurality of optical isomers may be mixed and used. In a case of mainly using one kind of optical isomer, the optical purity (ee) thereof is preferably 90% or more, and more preferably 95% or more.

Specific examples of the repeating unit having a lactone group or a sultone group are shown below, but the present invention is not limited thereto.

(In the formulae, Rx is CH₃, CH₂OH, or CF₃)

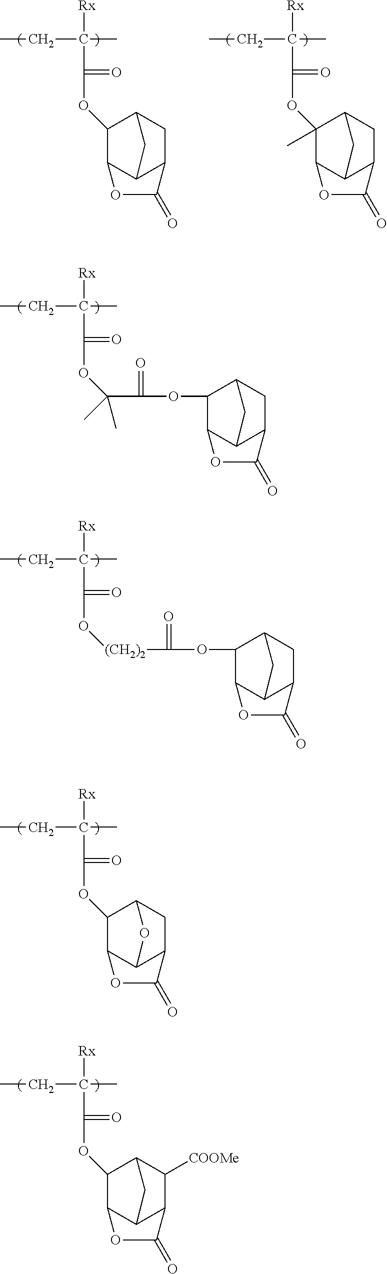

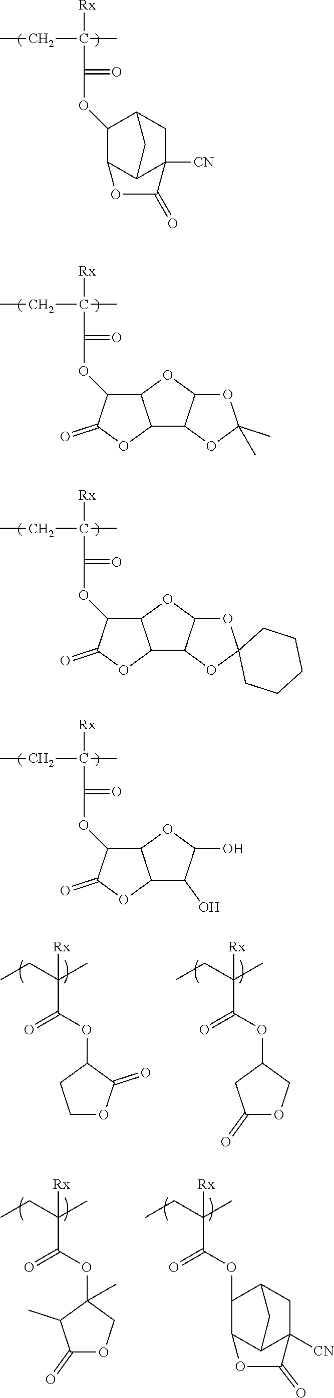

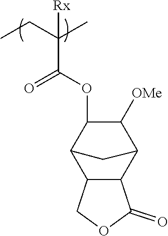

The content of the repeating unit having a lactone group or sultone group is preferably from 1% to 30% by mol, more preferably from 5% to 25% by mol, still more preferably from 5% to 20% by mol, based on all the repeating units in the resin (A) %.

<Repeating Unit Having Aromatic Ring Group>

The resin (A) may further have a repeating unit having an aromatic ring group which is different from the repeating unit represented by General Formula (I) and the repeating unit represented by General Formula (BII). Examples of such a repeating unit having an aromatic ring group include a repeating unit represented by General Formula (VII).

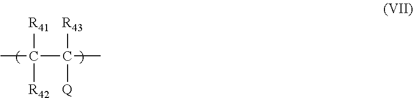

In the formula, R₄₁, R₄₂, and R₄₃ each independently represent a hydrogen atom, an alkyl group, a monovalent aliphatic hydrocarbon ring group, a halogen atom, a cyano group, or an alkoxycarbonyl group. R₄₂ may be bonded to Q to form a ring (preferably a 5- or 6-membered ring), and R₄₂ in such a case represents an alkylene group.

Q represents a group containing an aromatic ring group.

General Formula (VII) will be described in more detail.

Examples of the alkyl group of R₄₁, R₄₂, or R₄₃ in General Formula (VII) preferably include an alkyl group having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group, more preferably include an alkyl group having 8 or less carbon atoms, and particularly preferably include an alkyl group having 3 or less carbon atoms, each of which may have a substituent.

Examples of the monovalent aliphatic hydrocarbon ring group of R₄₁, R₄₂, and R₄₃ in Formula (VII) include a monovalent aliphatic hydrocarbon ring group which may be monocyclic or polycyclic. Preferred examples thereof include a monocyclic monovalent aliphatic hydrocarbon ring group having 3 to 8 carbon atoms such as a cyclopropyl group, a cyclopentyl group, and a cyclohexyl group, each of which may have a substituent.

Examples of the halogen atom of R₄₁, R₄₂, or R₄₃ in Formula (VII) include a fluorine atom, a chlorine atom, a bromine atom, and an iodine atom, with the fluorine atom being preferable.

Examples of the alkyl group contained in the alkoxycarbonyl group of R₄₁, R₄₂, and R₄₃ in Formula (VII) include the same alkyl group as the above-mentioned alkyl group.

Further, in a case where R₄₂ represents an alkylene group, the alkylene group is preferably an alkylene group having 1 to 8 carbon atoms, such as a methylene group, an ethylene group, a propylene group, a butylene group, a hexylene group, and an octylene group. An alkylene group having 1 to 4 carbon atoms is more preferable, and an alkylene group having 1 to 2 carbon atoms is particularly preferable.

As R₄₁ and R₄₃ in Formula (VII), a hydrogen atom, an alkyl group, or a halogen atom is more preferable, and a hydrogen atom, a methyl group, an ethyl group, a trifluoromethyl group (—CF₃), a hydroxymethyl group (—CH₂—OH), a chloromethyl group (—CH₂—Cl), or a fluorine atom (—F) is particularly preferable. As R₄₂, a hydrogen atom, an alkyl group, a halogen atom, or an alkylene group (which is bonded to Q to form a ring) is more preferable, and a hydrogen atom, a methyl group, an ethyl group, a trifluoromethyl group (—CF₃), a hydroxymethyl group (—CH₂—OH), a chloromethyl group (—CH₂—Cl), a fluorine atom (—F), a methylene group (which is bonded to Q to form a ring), or an ethylene group (which is bonded to Q to form a ring) is particularly preferable.

In General Formula (VII), Q is preferably a substituted or unsubstituted aromatic group having 1 to 20 carbon atoms. Examples of the aromatic group represented by Q include the following.

A phenyl group, a naphthyl group, an anthranyl group, a phenanthryl group, a fluorenyl group, a triphenylenyl group, a naphthacenyl group, a biphenyl group, a pyrrolinyl group, a furanyl group, a thiophenyl group, an imidazolyl group, an oxazolyl group, a thiazolyl group, a pyridyl group, a pyrazinyl group, a pyrimidyl group, a pyridazyl group, an indolizyl group, a benzofuranyl group, a benzothiophenyl group, an isobenzofuranyl group, a quinolizyl group, a quinolinyl group, a phthalazyl group, a naphthyridyl group, a quinoxalyl group, a quinoxazolyl group, an isoquinolinyl group, a carbazolyl group, an acridyl group, a phenanthrolyl group, a thianthrenyl group, a chromenyl group, a xanthenyl group, a phenoxathiinyl group, a phenothiazyl group, and a phenazyl group. Among these, an aromatic hydrocarbon ring is preferable; a phenyl group, a naphthyl group, an anthranyl group, a carbazolyl group, or a phenanthryl group is more preferable; and a phenyl group, a naphthyl group, or a carbazolyl group is still more preferable.

In a case where Q in General Formula (VII) has a substituent, the substituent is preferably an alkyl or alkoxy group having 1 to 20 carbon atoms.

In one embodiment of General Formula (VII), R₄₁, R₄₂, and R₄₃ are preferably a hydrogen atom.

The repeating unit having an aromatic ring group may be used singly or in combination of two or more kinds thereof.

The content of the repeating unit having an aromatic ring group in the resin (A) is contained preferably in a range of 5% to 90% by mol, more preferably in a range of 10% to 80% by mol, and still more preferably in a range of 20% to 70% by mol, with respect to all the repeating units.

<Other Repeating Units>

The resin (A) may have other repeating units than the above-mentioned repeating unit. Other repeating units are not particularly limited, and examples thereof include a repeating unit containing an organic group having a polar group, in particular, a repeating unit having an alicyclic hydrocarbon structure substituted with a polar group. Thus, substrate adhesiveness and developer affinity are improved.

As the alicyclic hydrocarbon structure substituted with a polar group, an adamantyl group, a diamantyl group, or a norbornane group is preferable. As the polar group, a hydroxyl group or a cyano group is preferable. Specific examples of the repeating unit having a polar group are shown below, but the present invention is not limited thereto.

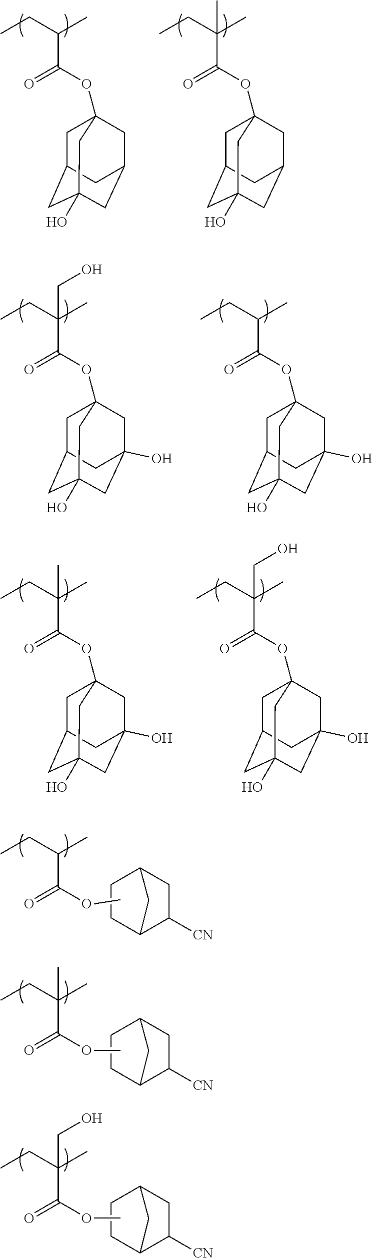

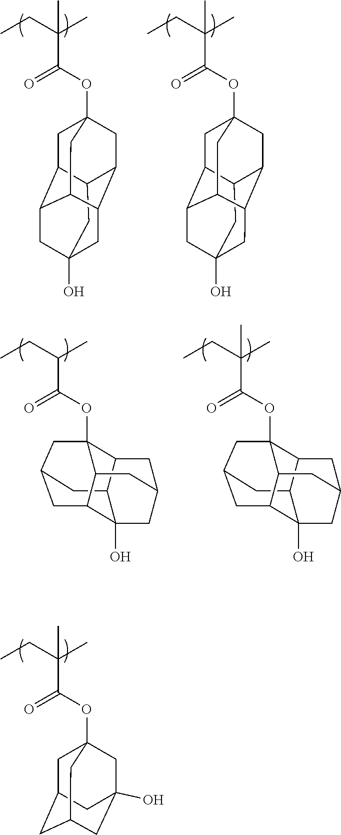

In a case where the resin (A) has a repeating unit containing an organic group having a polar group, the content of the repeating unit containing an organic group having a polar group is preferably 1% to 30% by mol, more preferably 5% to 25% by mol, and still more preferably 5% to 20% by mol, with respect to all the repeating units in the resin (A).

The resin (A) can be synthesized in accordance with an ordinary method (for example, radical polymerization). Examples of the general synthesis method include a batch polymerization method in which polymerization is carried out by dissolving monomer species and an initiator in a solvent and heating the solution, a dropwise addition polymerization method in which a solution of monomer species and an initiator is added dropwise to a heated solvent for 1 to 10 hours, with the dropwise addition polymerization method being preferable.

Examples of the reaction solvent include ethers such as tetrahydrofuran, 1,4-dioxane, and diisopropyl ether; ketones such as methyl ethyl ketone and methyl isobutyl ketone; ester solvents such as ethyl acetate; amide solvents such as dimethyl formamide and dimethyl acetamide; and a solvent in which the actinic ray-sensitive or radiation-sensitive resin composition of the present invention is dissolved, such as propylene glycol monomethyl ether acetate, propylene glycol monomethyl ether, and cyclohexanone. It is more preferable to perform polymerization using the same solvent as the solvent used in the actinic ray-sensitive or radiation-sensitive resin composition of the present invention. Thus, generation of the particles during storage can be suppressed.

It is preferable that the polymerization reaction is carried out in an inert gas atmosphere such as nitrogen or argon. As a polymerization initiator, commercially available radical initiators (an azo-based initiator, a peroxide, or the like) are used to initiate the polymerization. As the radical initiator, an azo-based initiator is preferable, and the azo-based initiator having an ester group, a cyano group, or a carboxyl group is more preferable. Preferred examples of the initiator include azobisisobutyronitrile, azobisdimethylvaleronitrile, and dimethyl 2,2′-azobis(2-methyl propionate). The initiator is added additionally or added in portionwise, as desired, and after the reaction is completed, a desired polymer is recovered by pouring the reaction mixture into a solvent, and using a method such as powder or solid recovery. The reaction concentration is 5% to 50% by mass, and preferably 10% to 30% by mass.

The reaction temperature is usually 10° C. to 150° C., preferably 30° C. to 120° C., and more preferably 60° C. to 100° C.

For purification, for example, ordinary methods can be applied, such as a liquid-liquid extraction method of applying water washing or combining appropriate solvents to remove residual monomers and oligomer components; a purification method in a solution state, such as ultrafiltration of extracting and removing only polymers having a molecular weight not more than a specific value; a re-precipitation method of adding dropwise the resin solution in a poor solvent to solidify the resin in the poor solvent and thereby remove residual monomers and the like; and a purification method in a solid state, such as washing of a resin slurry with a poor solvent after filtration of the slurry.

The weight-average molecular weight of the resin (A) is preferably 1,000 to 200,000, more preferably 3,000 to 20,000, and still more preferably 5,000 to 15,000 as a value in terms of polystyrene by means of a GPC method. By setting the weight-average molecular weight to 1,000 to 200,000, it is possible to prevent the deterioration of heat resistance and dry-etching resistance, and also prevent the deterioration of developability or the deterioration of film-forming properties due to increased viscosity.

A dispersity (molecular weight distribution) of the resin (A) is in a range of usually 1 to 5, preferably 1 to 3, more preferably 1.2 to 3.0, and still more preferably 1.2 to 2.0. As the dispersity is smaller, the resolution and the resist shape are better, the side wall of the resist pattern is smooth, and the roughness is excellent.

It is preferable that the resin (A) does not contain a repeating unit having a group capable of generating an acid upon irradiation with actinic rays or radiation (photoacid-generating group) as the other repeating unit.

[(B) Compound Capable of Generating Acid with Actinic Rays or Radiation (Photoacid Generator)]

The actinic ray-sensitive or radiation-sensitive resin composition preferably contains a compound capable of generating an acid with actinic rays or radiation (also referred to as a “photoacid generator <<PAG>>”).

The photoacid generator may be in a form of a low molecular compound or in a form of being introduced into a part of a polymer. Further, a combination of the form of a low molecular compound and the form of being introduced into a part of a polymer may also be used.

In a case where the photoacid generator is in the form of a low molecular compound, the molecular weight thereof is preferably 3,000 or less, more preferably 2,000 or less, and still more preferably 1,000 or less.

In a case where the photoacid generator is in the form of being introduced into a part of a polymer, it may be introduced into a part of the resin (A) or into a resin other than the resin (A).

In the present invention, the photoacid generator is preferably in the form of a low molecular compound.

Although the photoacid generator is not particularly limited as long as it is a known photoacid generator, the photoacid generator is preferably a compound capable of generating an organic acid, for example, at least one of sulfonic acid, bis(alkylsulfonyl)imide, or tris(alkylsulfonyl)methide, upon irradiation with actinic rays or radiation, preferably electron beams or extreme ultraviolet rays.

More preferred examples of the photoacid generator include a compound represented by General Formula (ZI), (ZII), or (ZIII).

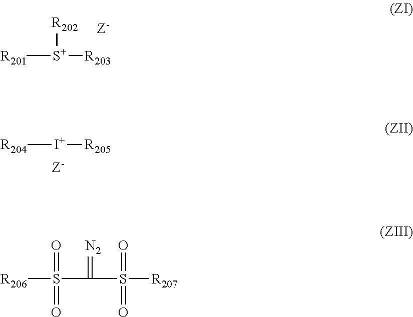

In General Formula (ZI),

R₂₀₁, R₂₀₂, and R₂₀₃ each independently represent an organic group.

The number of carbon atoms of the organic group as R₂₀₁, R₂₀₂, and R₂₀₃ is generally 1 to 30, and preferably 1 to 20.

Furthermore, two of R₂₀₁ to R₂₀₃ may be bonded to each other to form a ring structure, and the ring may include an oxygen atom, a sulfur atom, an ester bond, an amide bond, or a carbonyl group, and examples of the group formed by the bonding of two of R₂₀₁ to R₂₀₃ to each other include an alkylene group (for example, a butylene group and a pentylene group).

Z⁻ represents a non-nucleophilic anion (anion having an extremely low ability of causing a nucleophilic reaction).

Examples of the non-nucleophilic anion include a sulfonate anion (such as an aliphatic sulfonate anion, an aromatic sulfonate anion, and a camphor sulfonate anion), a carboxylate anion (such as an aliphatic carboxylate anion, an aromatic carboxylate anion, and an aralkyl carboxylate anion), a sulfonylimide anion, a bis(alkylsulfonyl)imide anion, and a tris(alkylsulfonyl)methide anion.

The aliphatic moiety in the aliphatic sulfonate anion and the aliphatic carboxylate anion may be an alkyl group or a cycloalkyl group, and preferred examples thereof include a linear or branched alkyl group having 1 to 30 carbon atoms and a cycloalkyl group having 3 to 30 carbon atoms.

Preferred examples of the aromatic group in the aromatic sulfonate anion and aromatic carboxylate anion include an aryl group having 6 to 14 carbon atoms, such as a phenyl group, a tolyl group, and a naphthyl group.

The alkyl group, the cycloalkyl group, and the aryl group mentioned above may have a substituent. Specific examples of the substituent include a nitro group, a halogen atom such as fluorine atom, a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 1 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), and a cycloalkylalkyloxyalkyloxy group (preferably having 8 to 20 carbon atoms).

The aryl group or the ring structure which is contained in each group may further have an alkyl group (preferably having 1 to 15 carbon atoms) as a substituent.

Preferred examples of the aralkyl group in the aralkyl carboxylate anion include an aralkyl group having 7 to 12 carbon atoms, such as a benzyl group, a phenethyl group, a naphthylmethyl group, a naphthylethyl group, and a naphthylbutyl group.

Examples of the sulfonylimide anion include a saccharin anion.

The alkyl group in the bis(alkylsulfonyl)imide anion and the tris(alkylsulfonyl)methide anion is preferably an alkyl group having 1 to 5 carbon atoms. Examples of the substituent of this alkyl group include a halogen atom, a halogen atom-substituted alkyl group, an alkoxy group, an alkylthio group, an alkyloxysulfonyl group, an aryloxysulfonyl group, and a cycloalkylaryloxysulfonyl group, with the fluorine atom and the fluorine atom-substituted alkyl group being preferable.

In addition, the alkyl groups in the bis(alkylsulfonyl)imide anion may be bonded to each other to form a ring structure. Thus, the acid strength is increased.

Other examples of the non-nucleophilic anion include fluorinated phosphorus (for example, PF₆⁻), fluorinated boron (for example, BF₄⁻), and fluorinated antimony (for example, SbF₆⁻).

The non-nucleophilic anion is preferably an aliphatic sulfonate anion substituted with a fluorine atom at least at the α-position of the sulfonic acid, an aromatic sulfonate anion substituted with a fluorine atom or a fluorine atom-containing group, a bis(alkylsulfonyl)imide anion in which the alkyl group is substituted with a fluorine atom, or a tris(alkylsulfonyl)methide anion in which the alkyl group is substituted with a fluorine atom. The non-nucleophilic anion is more preferably a perfluoroaliphatic sulfonate anion (still more preferably having 4 to 8 carbon atoms) or a fluorine atom-containing benzenesulfonate anion, and still more preferably a nonafluorobutanesulfonate anion, a perfluorooctanesulfonate anion, a pentafluorobenzenesulfonate anion, or a 3,5-bis(trifluoromethyl)benzenesulfonate anion.

From the viewpoint of the acid strength, the pKa of the acid generated is preferably −1 or less so as to improve the sensitivity.

Further, as a preferred embodiment of the non-nucleophilic anion, reference can be made to an anion represented by General Formula (AN1) and described in paragraphs [0243] to [0251] of JP2015-172767A, the contents of which are incorporated herein.

General Formula (AN1) is as follows.

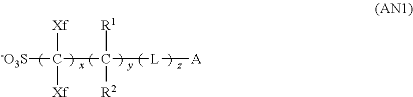

In the formula,

Xf's each independently represent a fluorine atom or an alkyl group substituted with at least one fluorine atom.

R¹ and R² each independently represent a hydrogen atom, a fluorine atom or an alkyl group, and R¹'s or R²'s in a case where a plurality of R¹'s or R²'s are present may be the same as or different from each other.

L represents a divalent linking group, and L's in a case where a plurality of L's are present may be the same as or different from each other.

A represents a cyclic organic group.

x represents an integer of 1 to 20, y represents an integer of 0 to 10, and z represents an integer of 0 to 10.

In General Formula (ANI), preferred examples of a combination of partial structures other than A include SO₃⁻—CF₂—CH₂—OCO—, SO₃⁻—CF₂—CHF—CH₂—OCO—, SO₃⁻—CF₂—COO—, SO₃⁻—CF₂—CF₂—CH₂—, SO₃⁻—CF₂—CH(CF₃)—OCO—.

In General Formula (ZI), examples of the organic group of R₂₀₁, R₂₀₂, and R₂₀₃ include an aryl group, an alkyl group, and a cycloalkyl group.

It is preferable that at least one of three members R₂₀₁, R₂₀₂, or R₂₀₃ is an aryl group, and it is more preferable that all of these three members are an aryl group. The aryl group may be a heteroaryl group such as indole residue and pyrrole residue, other than a phenyl group, a naphthyl group and the like. The alkyl group and the cycloalkyl group of R₂₀₁ to R₂₀₃ may be preferably a linear or branched alkyl group having 1 to 10 carbon atoms and a cycloalkyl group having 3 to 10 carbon atoms. More preferred examples of the alkyl group include a methyl group, an ethyl group, an n-propyl group, an i-propyl group, and an n-butyl group. More preferred examples of the cycloalkyl group include a cyclopropyl group, a cyclobutyl group, a cyclopentyl group, a cyclohexyl group, and a cycloheptyl group. These groups may further have a substituent, and examples of the substituent include, but are not limited to, a nitro group, a halogen atom such as fluorine atom, a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), and an alkoxycarbonyloxy group (preferably having 2 to 7 carbon atoms).

Next, General Formulae (ZII) and (ZIII) will be described.

In General Formulae (ZII) and (ZIII), R₂₀₄ to R₂₀₇ each independently represent an aryl group, an alkyl group, or a cycloalkyl group.

The aryl group of R₂₀₄ to R₂₀₇ is preferably a phenyl group or a naphthyl group, more preferably a phenyl group. The aryl group of R₂₀₄ to R₂₀₇ may be an aryl group having a heterocyclic structure having an oxygen atom, a nitrogen atom, a sulfur atom, or the like. Examples of the skeleton of the aryl group having a heterocyclic structure include pyrrole, furan, thiophene, indole, benzofuran, and benzothiophene.

The alkyl group and the cycloalkyl group in R₂₀₄ to R₂₀₇ are preferably a linear or branched alkyl group having 1 to 10 carbon atoms (for example, methyl group, ethyl group, propyl group, butyl group, and pentyl group) and a cycloalkyl group having 3 to 10 carbon atoms (cyclopentyl group, cyclohexyl group, or norbonyl group).

The aryl group, the alkyl group, and the cycloalkyl group of R₂₀₄ to R₂₀₇ may have a substituent. Examples of the substituent which may be included in the aryl group, the alkyl group, or cycloalkyl group of R₂₀₄ to R₂₀₇ include an alkyl group (for example, having 1 to 15 carbon atoms), a cycloalkyl group (for example, having 3 to 15 carbon atoms), an aryl group (for example, having 6 to 15 carbon atoms), an alkoxy group (for example, having 1 to 15 carbon atoms), a halogen atom, a hydroxyl group, and a phenylthio group.

Further, in General Formula (ZII), Z⁻ represents a non-nucleophilic anion. Specifically, it is the same as the one described as Z⁻ in General Formula (ZI), and a preferred form thereof is also the same.

Specific examples of General Formulae (ZI) to (ZIII) are shown below, but the present invention is not limited thereto.

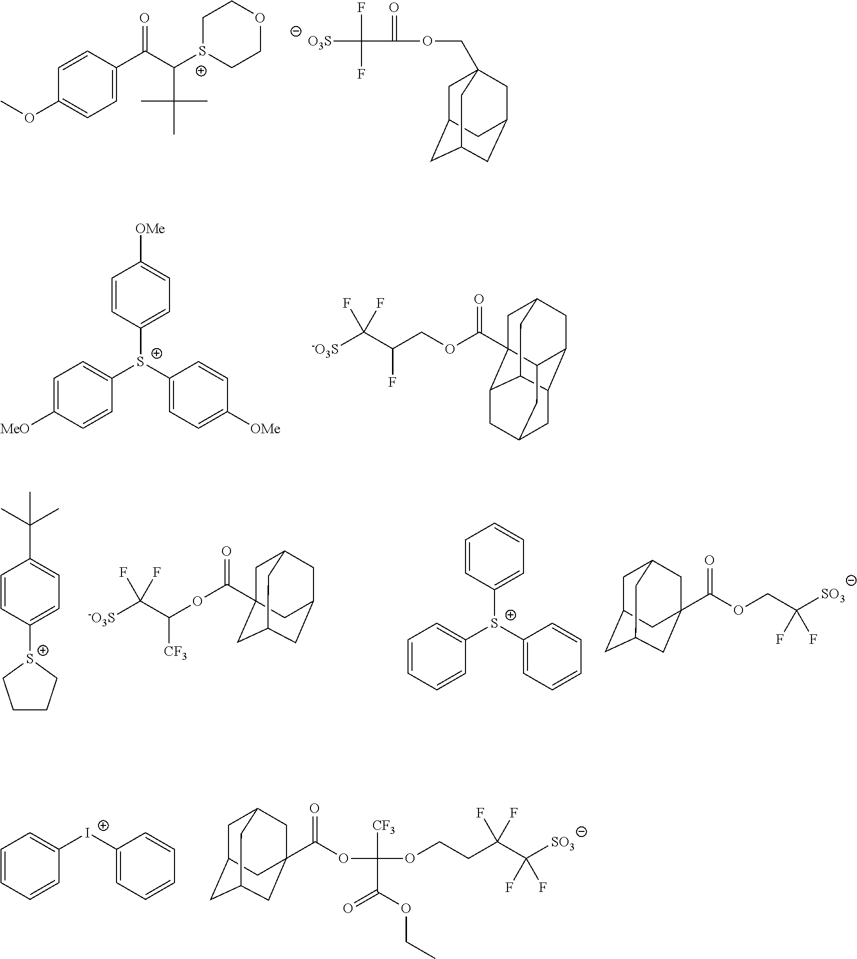

The number of fluorine atoms contained in the photoacid generator is appropriately adjusted for the purpose of adjusting cross-sectional shape of a pattern. By adjusting the fluorine atoms, it is possible to control uneven distribution on a surface of the photoacid generator in the resist film.

As the number of the fluorine atoms contained in the photoacid generator is higher, the photoacid generator is more unevenly distributed on the surface of the resist film.

In the present invention, from the viewpoint of suppressing an acid generated by exposure from diffusing to the unexposed portion, and thus, improving the resolution, the photoacid generator is a compound capable of generating an acid in a size with a volume of 130 Å³ or more (more preferably a sulfonic acid), more preferably a compound capable of generating an acid in a size with a volume of 190 Å³ or more (more preferably a sulfonic acid), still more preferably a compound capable of generating an acid in a size with a volume of 270 Å³ or more (more preferably sulfonic acid), and particularly preferably a compound capable of generating an acid in a size with a volume of 400 Å³ or more (more preferably sulfonic acid), upon irradiation with electron beams or extreme ultraviolet rays. However, from the viewpoint of the sensitivity and/or the solubility in the coating solvent, the volume is preferably 2,000 Å³ or less, and more preferably 1,500 Å³ or less. The value of the volume was determined using “WinMOPAC” manufactured by Fujitsu Limited. That is, first, the chemical structure of the acid in each compound is input, next, using this structure as an initial structure, the most stable steric conformation of each acid is determined by molecular force field calculation according to an MM3 method, and then, molecular orbital calculation using a PM3 method is performed with respect to the most stable steric conformation, whereby the “accessible volume” of each acid can be calculated.

1 angstrom (Å) is 0.1 nanometer (nm).

With regard to the photoacid generator, reference can be made to paragraphs [0368] to [0377] of JP2014-41328A, and paragraphs [0240] to [0262] of JP2013-228681A ([0339] of the corresponding US2015/004533A), the contents of which are incorporated herein. Further, specific preferred examples thereof include the following compounds, but are not limited thereto.

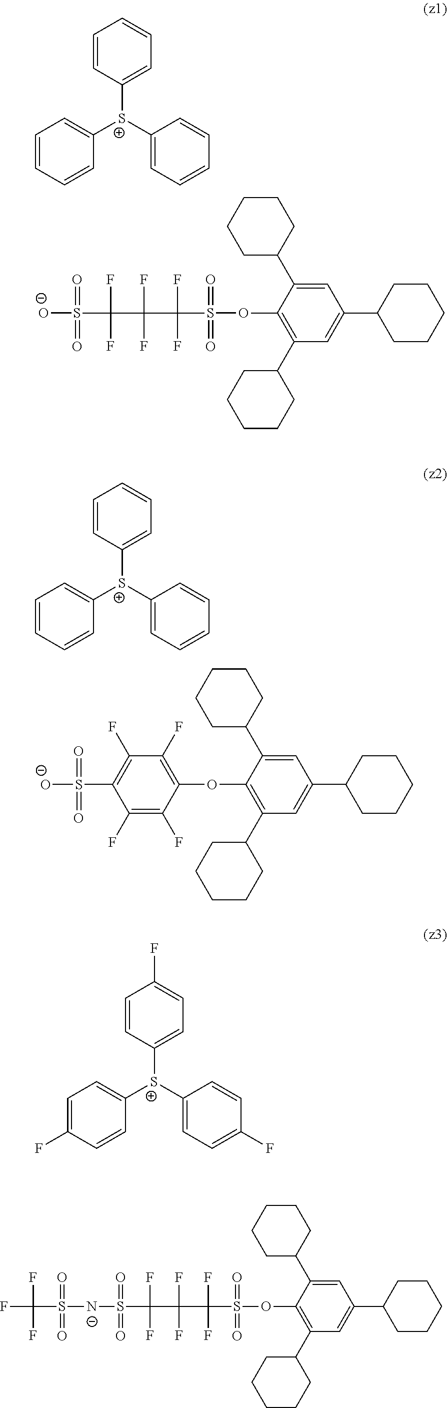 [SMILES: c1ccc([S+](c2ccccc2)c2ccccc2)cc1 ; O=S(=O)([O-])C(F)(F)C(F)(F)C(F)(F)S(=O)(=O)Oc1c(C2CCCCC2)cc(C2CCCCC2)cc1C1CCCCC1 ; c1ccc([S+](c2ccccc2)c2ccccc2)cc1 ; O=S(=O)([O-])c1c(F)c(F)c(Oc2c(C3CCCCC3)cc(C3CCCCC3)cc2C2CCCCC2)c(F)c1F ; Fc1ccc([S+](c2ccc(F)cc2)c2ccc(F)cc2)cc1 ; O=S(=O)([N-]S(=O)(=O)C(F)(F)C(F)(F)C(F)(F)S(=O)(=O)Oc1c(C2CCCCC2)cc(C2CCCCC2)cc1C1CCCCC1)C(F)(F)F]

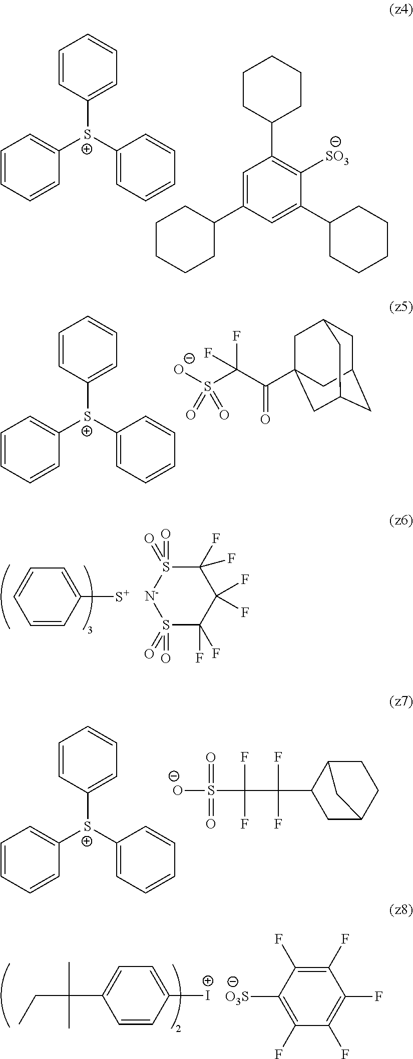

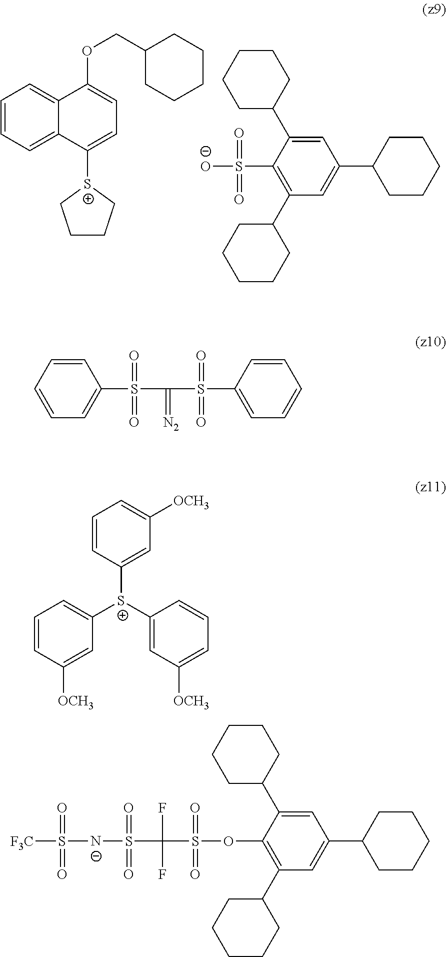

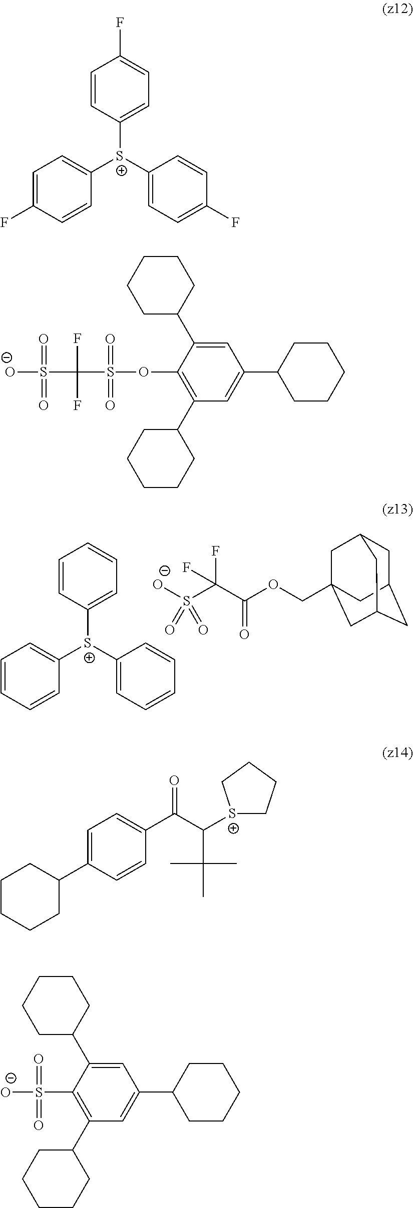 [SMILES: Fc1ccc([S+](c2ccc(F)cc2)c2ccc(F)cc2)cc1 ; O=S(=O)([O-])C(F)(F)S(=O)(=O)Oc1c(C2CCCCC2)cc(C2CCCCC2)cc1C1CCCCC1 ; c1ccc([S+](c2ccccc2)c2ccccc2)cc1 ; O=C(OCC12CC3CC(CC(C3)C1)C2)C(F)(F)S(=O)(=O)[O-] ; CC(C)(C)C(C(=O)c1ccc(C2CCCCC2)cc1)[S+]1CCCC1 ; O=S(=O)([O-])c1c(C2CCCCC2)cc(C2CCCCC2)cc1C1CCCCC1]

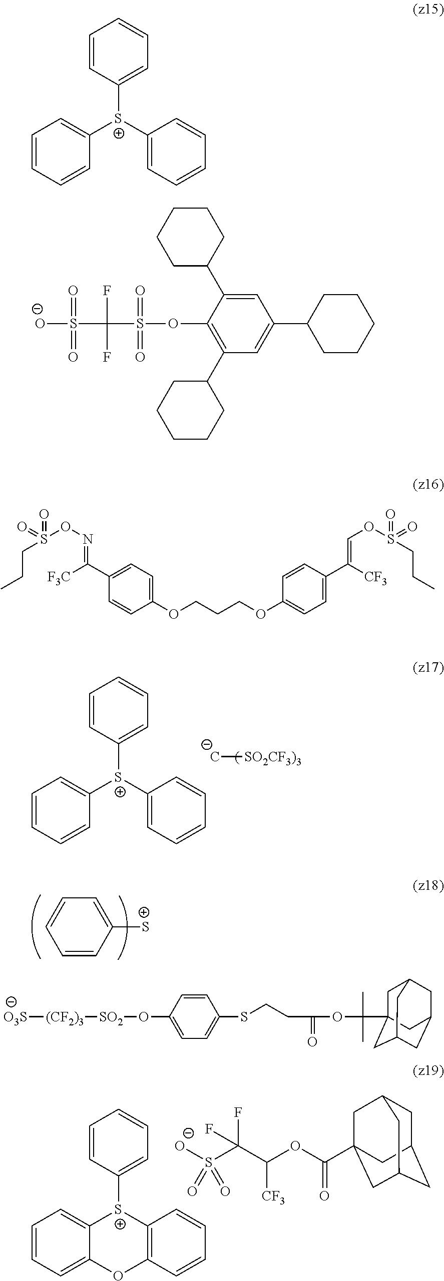

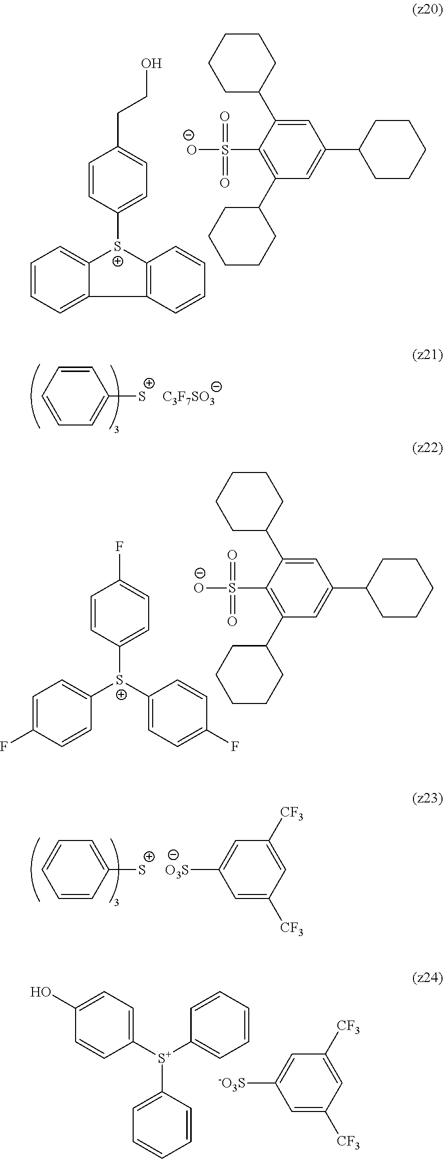

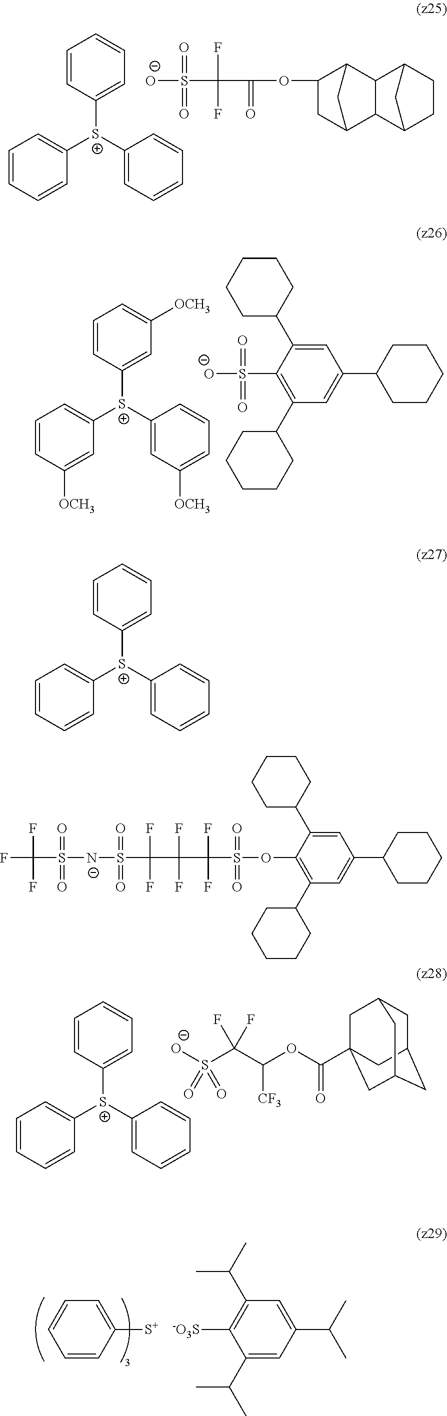

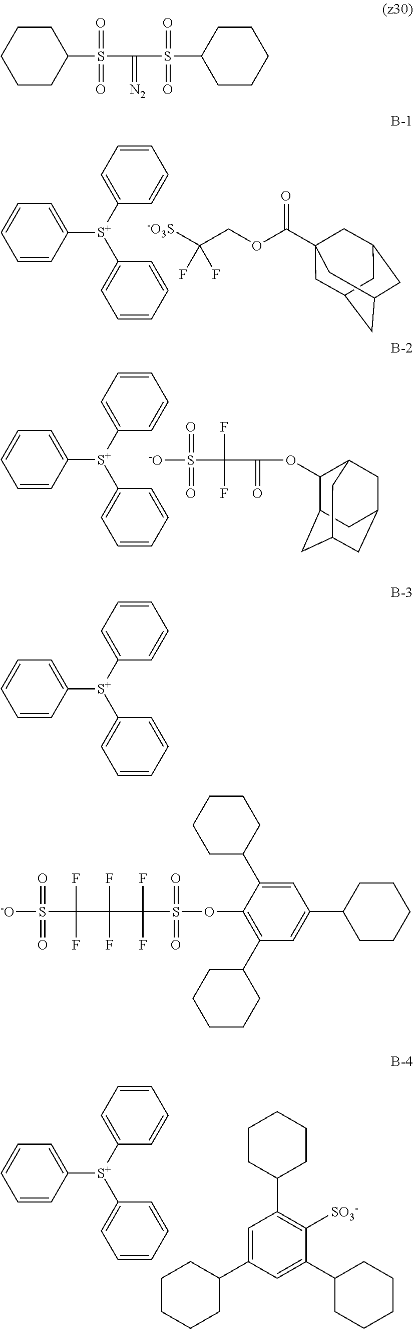

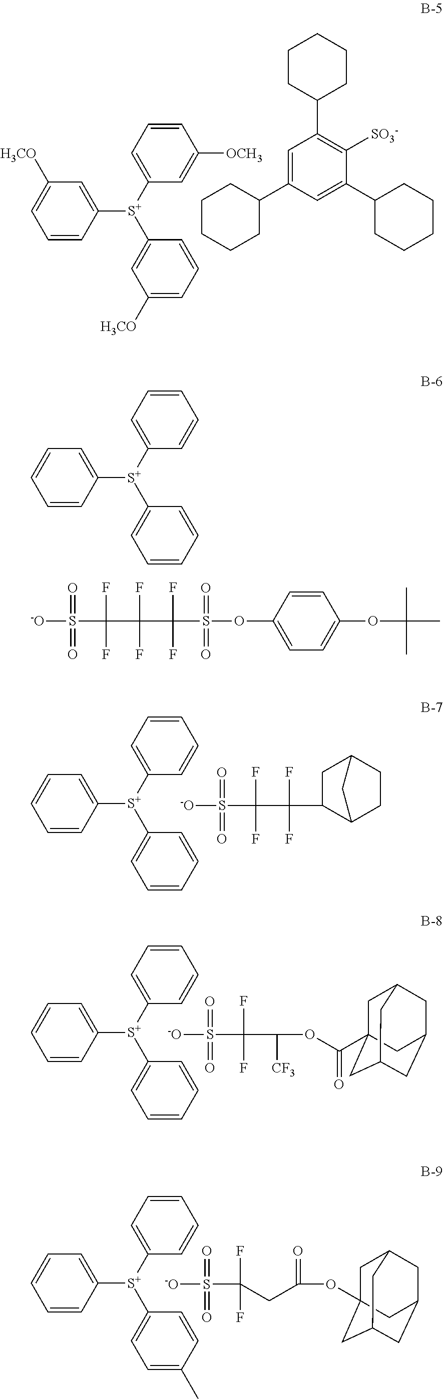

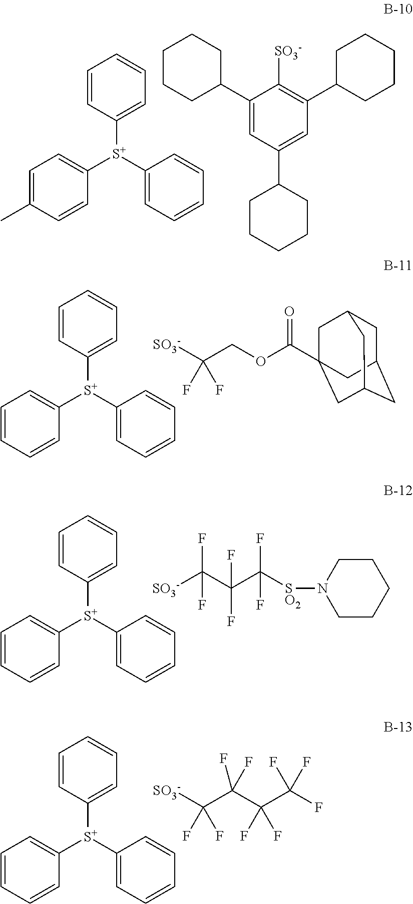

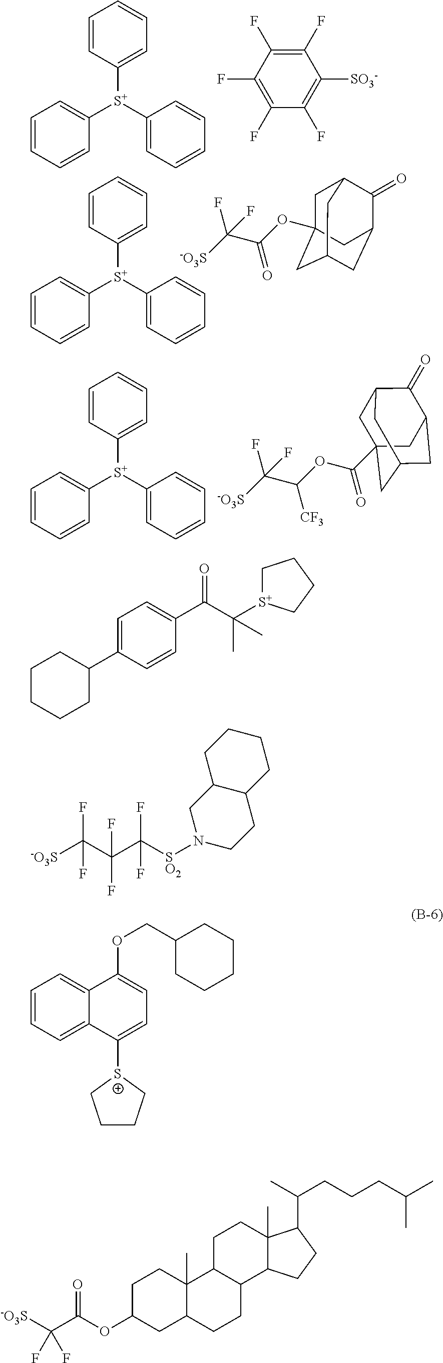

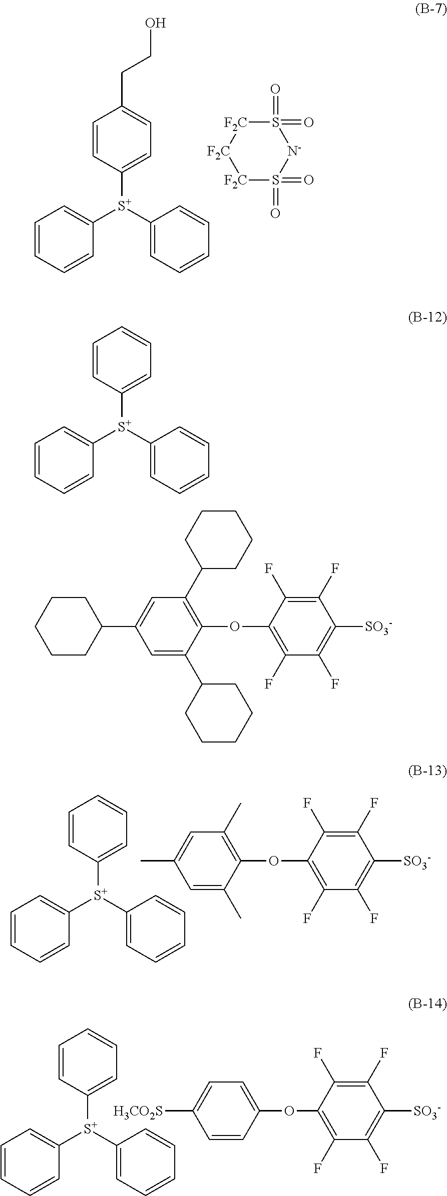

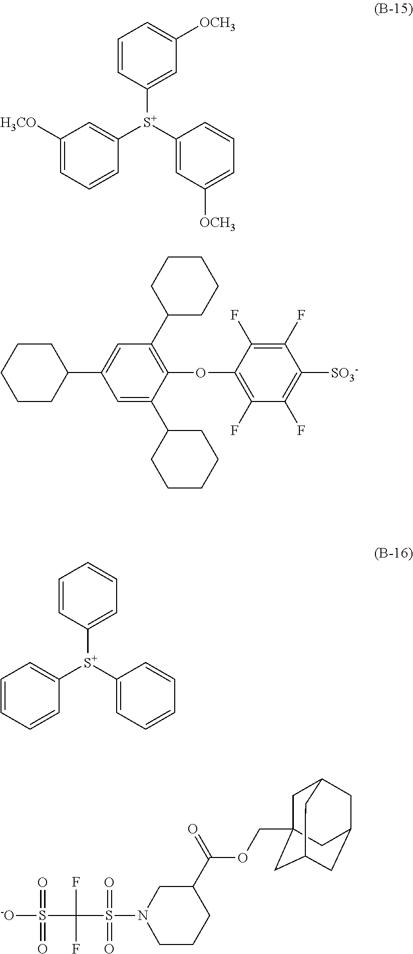

The photoacid generators may be used singly or in combination of two or more kinds thereof.

The content of the photoacid generator in the actinic ray-sensitive or radiation-sensitive resin composition is preferably 0.1% to 50% by mass, more preferably 5% to 50% by mass, and still more preferably 8% to 40% by mass, based on the total solid content of the composition. In particular, in order to satisfy both high sensitivity and high resolution upon exposure using electron beams or extreme ultraviolet rays, the content of the photoacid generator is preferably high, more preferably 10% to 40% by mass, and most preferably 10% to 35% by mass.

[(C) Solvent]

In a case where the actinic ray-sensitive or radiation-sensitive resin composition is prepared by dissolving each of the above-mentioned components, a solvent can be used. Examples of usable solvents include organic solvents such as alkylene glycol monoalkyl ether carboxylate, alkylene glycol monoalkyl ether, alkyl ester lactate, alkyl alkoxypropionate, a cyclic lactone having 4 to 10 carbon atoms, a monoketone compound having 4 to 10 carbon atoms which may contain a ring, alkylene carbonate, alkyl alkoxyacetate, and alkyl pyruvate.

Preferred examples of the alkylene glycol monoalkyl ether carboxylate include propylene glycol monomethyl ether acetate, propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate, and ethylene glycol monoethyl ether acetate.

Preferable examples of the alkylene glycol monoalkyl ether include propylene glycol monomethyl ether, propylene glycol monoethyl ether, propylene glycol monopropyl ether, propylene glycol monobutyl ether, ethylene glycol monomethyl ether, and ethylene glycol monoethyl ether.

Preferred examples of the alkyl ester lactate include methyl lactate, ethyl lactate, propyl lactate, and butyl lactate.

Preferred examples of the alkyl alkoxypropionate include ethyl 3-ethoxypropionate, methyl 3-methoxypropionate, methyl 3-ethoxypropionate, and ethyl 3-methoxypropionate.

Preferred examples of the cyclic lactone having 4 to 10 carbon atoms include β-propiolactone, β-butyrolactone, γ-butyrolactone, α-methyl-γ-butyrolactone, β-methyl-γ-butyrolactone, γ-valerolactone, γ-caprolactone, γ-octanoic lactone, and α-hydroxy-γ-butyrolactone.

Preferred examples of the monoketone compound having 4 to 10 carbon atoms which may contain a ring include 2-butanone, 3-methylbutanone, pinacolone, 2-pentanone, 3-pentanone, 3-methyl-2-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexene-2-one, 3-penten-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone, and 3-methylcycloheptanone.

Preferable examples of the alkylene carbonate include propylene carbonate, vinylene carbonate, ethylene carbonate, and butylene carbonate.

Preferred examples of the alkyl alkoxyacetate include 2-methoxyethyl acetate, 2-ethoxyethyl acetate, 2-(2-ethoxyethoxy)ethyl acetate, 3-methoxy-3-methylbutyl acetate, and 1-methoxy-2-propyl acetate.

Preferable examples of the alkyl pyruvate include methyl pyruvate, ethyl pyruvate, and propyl pyruvate.

The solvent that can be preferably used is a solvent having a boiling point of 130° C. or more at ordinary temperature and pressure. Specific examples thereof include cyclopentanone, γ-butyrolactone, cyclohexanone, ethyl lactate, ethylene glycol monoethyl ether acetate, propylene glycol monomethyl ether acetate, ethyl 3-ethoxypropionate, ethyl pyruvate, 2-ethoxyethyl acetate, 2-(2-ethoxyethoxy)ethyl acetate, and propylene carbonate.

In the present invention, the above solvents may be used be used singly or in combination of two or more kinds thereof.

In the present invention, a mixed solvent obtained by mixing a solvent containing a hydroxyl group in its structure and a solvent containing no hydroxyl group may be used as an organic solvent.

Examples of the solvent containing a hydroxyl group include ethylene glycol, ethylene glycol monomethyl ether, ethylene glycol monoethyl ether, propylene glycol, propylene glycol monomethyl ether, propylene glycol monoethyl ether, and ethyl lactate. Among these, propylene glycol monomethyl ether and ethyl lactate are particularly preferable.

Examples of the solvent containing no hydroxyl group include propylene glycol monomethyl ether acetate, ethyl ethoxypropionate, 2-heptanone, γ-butyrolactone, cyclohexanone, butyl acetate, N-methylpyrrolidone, N,N-dimethylacetamide, and dimethylsulfoxide. Among these, propylene glycol monomethyl ether acetate, ethyl ethoxypropionate, 2-heptanone, γ-butyrolactone, cyclohexanone, or butyl acetate is particularly preferable, and propylene glycol monomethyl ether acetate, ethyl ethoxypropionate, or 2-heptanone is most preferable.

The mixing ratio (mass) of the solvent containing a hydroxyl group and the solvent containing no hydroxyl group is preferably 1/99 to 99/1, more preferably 10/90 to 90/10, and still more preferably 20/80 to 60/40. A mixed solvent containing 50% by mass or more of the solvent containing no hydroxyl group is particularly preferable from the viewpoint of coating uniformity.

The solvent is preferably a mixed solvent of two or more kinds of solvents containing propylene glycol monomethyl ether acetate.

As the solvent, for example, the solvents described in paragraphs 0013 to 0029 of JP2014-219664A can also be used.

The solvent may contain isomers (compounds having the same number of atoms and different structures) which are described above as examples. In addition, only one kind of the isomers may be contained or a plurality of kinds thereof may be contained.

[(E) Basic Compound]

The actinic ray-sensitive or radiation-sensitive resin composition preferably contains a basic compound (E) in order to reduce a change in performance over time from exposure to heating.

Preferred examples of the basic compound include compounds having structures represented by Formulae (A) to (E).

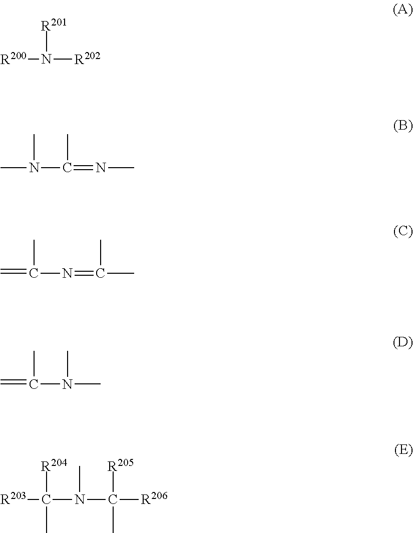

In General Formulae (A) to (E), R²⁰⁰, R²⁰¹, and R²⁰² may be the same as or different from each other, and each represent a hydrogen atom, an alkyl group (preferably having 1 to 20 carbon atoms), a cycloalkyl group (preferably having 3 to 20 carbon atoms), or an aryl group (preferably having 6 to 20 carbon atoms), in which R²⁰¹ and R²⁰² may be bonded to each other to form a ring.

With respect to the alkyl group, as the alkyl group having a substituent, an aminoalkyl group having 1 to 20 carbon atoms, a hydroxyalkyl group having 1 to 20 carbon atoms, or a cyanoalkyl group having 1 to 20 carbon atoms is preferable.

R²⁰³, R²⁰⁴, R²⁰⁵, and R²⁰⁶ may be the same as or different from each other, and each represent an alkyl group having 1 to 20 carbon atoms.

The alkyl group in General Formulae (A) to (E) is more preferably unsubstituted.

Preferred examples of the compound include guanidine, aminopyrrolidine, pyrazole, pyrazoline, piperazine, aminomorpholine, aminoalkylmorpholine and piperidine. More preferred examples of the compound include a compound having an imidazole structure, a diazabicyclo structure, an onium hydroxide structure, an onium carboxylate structure, a trialkylamine structure, an aniline structure, or a pyridine structure; an alkylamine derivative having a hydroxyl group and/or an ether bond; and an aniline derivative having a hydroxyl group and/or an ether bond.

Examples of the compound having an imidazole structure include imidazole, 2,4,5-triphenylimidazole, and benzimidazole. Examples of the compound having a diazabicyclo structure include 1,4-diazabicyclo[2,2,2]octane, 1,5-diazabicyclo[4,3,0]non-5-ene, and 1,8-diazabicyclo[5,4,0]undec-7-ene. Examples of the compound having an onium hydroxide structure include triarylsulfonium hydroxide, phenacylsulfonium hydroxide, and sulfonium hydroxide having a 2-oxoalkyl group, specifically triphenylsulfonium hydroxide, tris(t-butylphenyl)sulfonium hydroxide, bis(t-butylphenyl)iodonium hydroxide, phenacylthiophenium hydroxide, and 2-oxopropylthiophenium hydroxide. The compound having an onium carboxylate structure is one in which the anion moiety of the compound having an onium hydroxide structure has been converted into a carboxylate, and examples thereof include acetate, adamantane-1-carboxylate, and perfluoroalkyl carboxylate. Examples of the compound having a trialkylamine structure include tri(n-butyl)amine and tri(n-octyl)amine. Examples of the compound having an aniline structure include 2,6-diisopropylaniline, N,N-dimethylaniline, N,N-dibutylaniline, and N,N-dihexylaniline. Examples of the alkylamine derivative having a hydroxyl group and/or an ether bond include ethanolamine, diethanolamine, triethanolamine, and tris(methoxyethoxyethyl)amine. Examples of the aniline derivative having a hydroxyl group and/or an ether bond include N,N-bis(hydroxyethyl)aniline.

Preferred examples of the basic compound further include an amine compound having a phenoxy group and an ammonium salt compound having a phenoxy group.

As the amine compound, a primary, secondary, or tertiary amine compound can be used, and an amine compound in which at least one alkyl group is bonded to a nitrogen atom is preferable. The amine compound is more preferably a tertiary amine compound. In the amine compound, as long as at least one alkyl group (preferably having 1 to 20 carbon atoms) is bonded to a nitrogen atom, a cycloalkyl group (preferably having 3 to 20 carbon atoms) or an aryl group (preferably having 6 to 12 carbon atoms) may be bonded to the nitrogen atom, in addition to the alkyl group.

Further, the amine compound preferably has an oxygen atom in the alkyl chain to form an oxyalkylene group. The number of the oxyalkylene groups within the molecule is 1 or more, preferably 3 to 9, and more preferably 4 to 6. Among the oxyalkylene groups, an oxyethylene group (—CH₂CH₂O—) or an oxypropylene group (—CH(CH₃)CH₂O— or —CH₂CH₂CH₂O—) is preferable, and an oxyethylene group is more preferable.

As the ammonium salt compound, primary, secondary, tertiary, or quaternary ammonium salt compounds can be used, and an ammonium salt compound having at least one alkyl group bonded to a nitrogen atom thereof is preferable. In the ammonium salt compounds, as long as at least one alkyl group (preferably having 1 to 20 carbon atoms) is bonded to a nitrogen atom thereof, a cycloalkyl group (preferably having 3 to 20 carbon atoms) or an aryl group (preferably having 6 to 12 carbon atoms) may be bonded to the nitrogen atom, in addition to the alkyl group.

The ammonium salt compound preferably has an oxygen atom in the alkyl chain to form an oxyalkylene group. The number of oxyalkylene groups within the molecule is 1 or more, preferably 3 to 9, and more preferably 4 to 6. Among the oxyalkylene groups, an oxyethylene group (—CH₂CH₂O—) or an oxypropylene group (—CH(CH₃)CH₂O— or —CH₂CH₂CH₂O—) is preferable, and an oxyethylene group is more preferable.

Examples of the anion of the ammonium salt compound include halogen atoms, sulfonate, borate, and phosphate, and among these, halogen atoms and sulfonate are preferable. As the halogen atom, chloride, bromide, or iodide is particularly preferable, and as the sulfonate, an organic sulfonate having 1 to 20 carbon atoms is particularly preferable. Examples of the organic sulfonate include aryl sulfonate and alkyl sulfonate having 1 to 20 carbon atoms. The alkyl group of the alkyl sulfonate may have a substituent. Examples of the substituent include fluorine, chlorine, bromine, an alkoxy group, an acyl group, and an aryl group. Specific examples of the alkyl sulfonates include methane sulfonate, ethane sulfonate, butane sulfonate, hexane sulfonate, octane sulfonate, benzyl sulfonate, trifluoromethane sulfonate, pentafluoroethane sulfonate, and nonafluorobutane sulfonate. Examples of the aryl group of the aryl sulfonate include a benzene ring, a naphthalene ring, and an anthracene ring. The benzene ring, the naphthalene ring, or the anthracene ring may have a substituent, and as the substituent, a linear or branched alkyl group having 1 to 6 carbon atoms or a cycloalkyl group having 3 to 6 carbon atoms is preferable. Specific examples of the linear or branched alkyl group and the cycloalkyl group include methyl, ethyl, n-propyl, isopropyl, n-butyl, i-butyl, t-butyl, n-hexyl, and cyclohexyl. Other examples of the substituent include an alkoxy group having 1 to 6 carbon atoms, a halogen atom, cyano, nitro, an acyl group, and an acyloxy group.

The amine compound having a phenoxy group and the ammonium salt compound having a phenoxy group are those having a phenoxy group at the terminal of the alkyl group of the amine compound or ammonium salt compound opposed to the nitrogen atom. The phenoxy group may have a substituent. Examples of the substituent of the phenoxy group include an alkyl group, an alkoxy group, a halogen atom, a cyano group, a nitro group, a carboxyl group, a carboxylic ester group, a sulfonic ester group, an aryl group, an aralkyl group, an acyloxy group, and an aryloxy group. The substitution position of the substituent may be any of 2- to 6-positions. The number of substituents is any value within the range of 1 to 5.

It is preferable that at least one oxyalkylene group exist between the phenoxy group and the nitrogen atom. The number of oxyalkylene groups within the molecule is 1 or more, preferably 3 to 9, and more preferably 4 to 6. Among the oxyalkylene groups, an oxyethylene group (—CH₂CH₂O—) or an oxypropylene group (—CH(CH₃)CH₂O— or —CH₂CH₂CH₂O—) is preferable, and an oxyethylene group is more preferable.

The amine compound having a phenoxy group can be obtained by heating a primary or secondary amine having a phenoxy group and a haloalkyl ether so as to effect a reaction therebetween, then adding an aqueous solution of a strong base such as sodium hydroxide, potassium hydroxide, and tetraalkylammonium, and thereafter carrying out an extraction with an organic solvent such as ethyl acetate and chloroform. Alternatively, the amine compound having a phenoxy group can be obtained by first heating a primary or secondary amine and a haloalkyl ether having a phenoxy group at its terminal so as to effect a reaction therebetween, subsequently adding an aqueous solution of a strong base such as sodium hydroxide, potassium hydroxide, and a tetraalkylammonium, and thereafter carrying out an extraction with an organic solvent such as ethyl acetate and chloroform.

(Compound (PA) that has Proton-Accepting Functional Group and Generates Compound of which Proton Acceptor Properties are Reduced or Lost, or which is Changed from Having Proton Acceptor Properties to being Acidic, by Decomposing Upon Irradiation with Actinic Rays or Radiation)

The composition according to the present invention may further contain, as a basic compound, a compound [hereinafter also referred to as a compound (PA)] that has a proton-accepting functional group and generates a compound of which proton acceptor properties are reduced or lost, or which is changed from having proton acceptor properties to being acidic, by decomposing upon irradiation with actinic rays or radiation.

The proton-accepting functional group refers to a functional group having an electron or a group which is capable of electrostatically interacting with a proton, and for example, means a functional group with a macrocyclic structure, such as a cyclic polyether, or a functional group containing a nitrogen atom having an unshared electron pair not contributing to π-conjugation. The nitrogen atom having an unshared electron pair not contributing to π-conjugation is, for example, a nitrogen atom having a partial structure represented by the following general formulae.

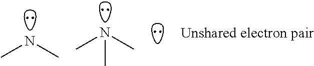

Preferred examples of the partial structure of the proton-accepting functional group include crown ether, azacrown ether, primary to tertiary amines, pyridine, imidazole, and pyrazine structures.

The compound (PA) decomposes upon irradiation with actinic rays or radiation to generate a compound of which proton acceptor properties are reduced or lost, or which is changed from having proton accepting properties to being acidic. Here, the expression, a compound of which proton acceptor properties are reduced or lost, or which is changed from having proton accepting properties to being acidic, means a compound having a change of proton acceptor properties due to the proton being added to the proton-accepting functional group, specifically a decrease in the equilibrium constant at chemical equilibrium in a case where a proton adduct is generated from the compound (PA) having the proton-accepting functional group and the proton.

Specific examples of the compound (PA) include the following compounds. Further, specific examples of the compound (PA) include those described in paragraphs 0421 to 0428 of JP2014-41328A, and paragraphs 0108 to 0116 of JP2014-134686A, the contents of which are incorporated herein.

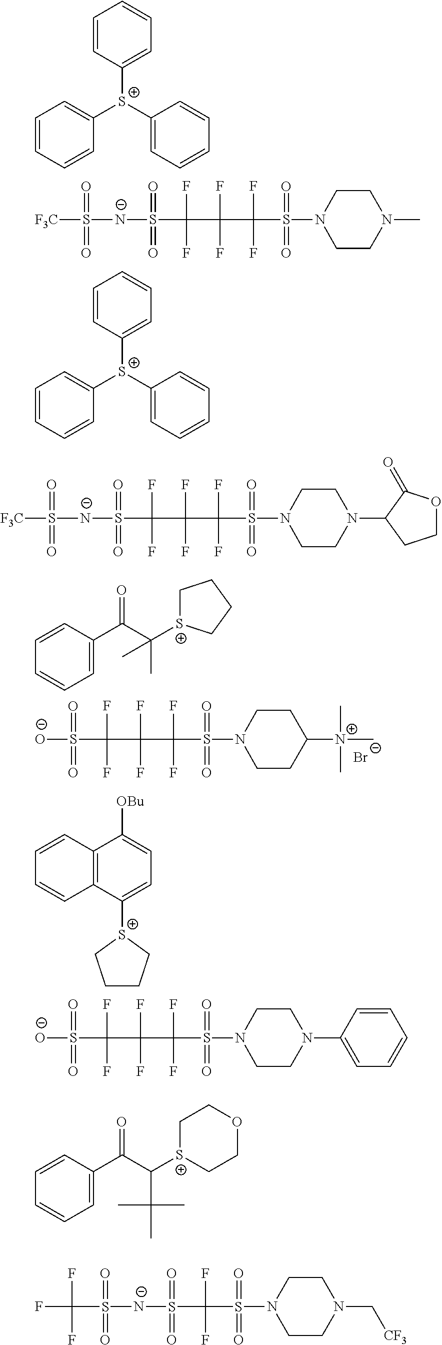

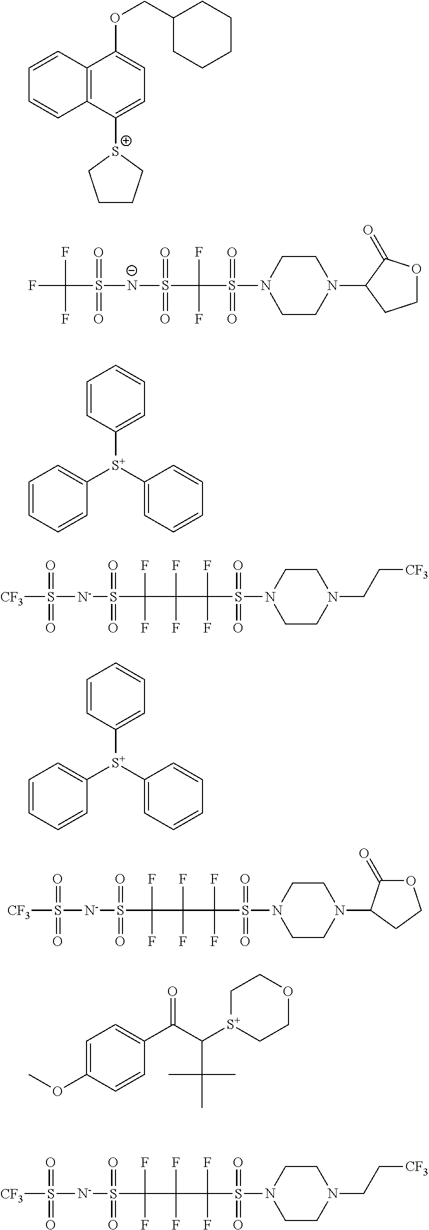

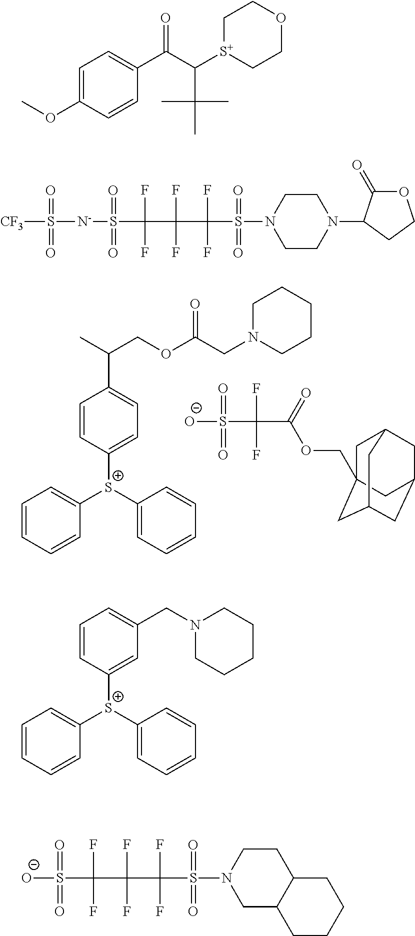 [SMILES: COc1ccc(C(=O)C([S+]2CCOCC2)C(C)(C)C)cc1 ; O=C1OCCC1N1CCN(S(=O)(=O)C(F)(F)C(F)(F)C(F)(F)S(=O)(=O)[N-]S(=O)(=O)C(F)(F)F)CC1 ; CC(COC(=O)CN1CCCCC1)c1ccc([S+](c2ccccc2)c2ccccc2)cc1 ; O=C(OCC12CC3CC(CC(C3)C1)C2)C(F)(F)S(=O)(=O)[O-] ; c1ccc([S+](c2ccccc2)c2cccc(CN3CCCCC3)c2)cc1 ; O=S(=O)([O-])C(F)(F)C(F)(F)C(F)(F)S(=O)(=O)N1CCC2CCCCC2C1]

These basic compounds may be used singly or in combination of two or more kinds thereof.

The amount of the basic compound to be used is usually 0.001% to 10% by mass, and preferably 0.01% to 5% by mass, based on the solid content of the actinic ray-sensitive or radiation-sensitive resin composition.

The ratio between the photoacid generator to the basic compound to be used in the composition is preferably the photoacid generator/basic compound (molar ratio)=2.5 to 300. That is, the molar ratio is preferably 2.5 or more in view of sensitivity and resolution, and is preferably 300 or less from the viewpoint of suppressing the reduction in resolution due to thickening of the resist pattern over time from exposure to the heat treatment. The photoacid generator/basic compound (molar ratio) is more preferably 5.0 to 200, and still more preferably 7.0 to 150.

As the basic compound, for example, the compounds (amine compounds, amido group-containing compounds, urea compounds, nitrogen-containing heterocyclic compounds, and the like) described in paragraphs 0140 to 0144 of JP2013-11833A can be used.

[(A′) Hydrophobic Resin]

The actinic ray-sensitive or radiation-sensitive resin composition may have a hydrophobic resin (A′) separately from the resin (A).

The hydrophobic resin is preferably designed to be unevenly distributed on the surface of the resist film. However, unlike the surfactant, it does not necessarily have a hydrophilic group in its molecule and may not contribute to homogeneous mixing of polar/nonpolar materials.

Examples of the effect of addition of the hydrophobic resin include control of the static/dynamic contact angle of the resist film surface with respect to water, and suppression of outgassing.

The hydrophobic resin preferably has at least one of a “fluorine atom”, a “silicon atom”, or a “CH₃ partial structure which is contained in a side chain moiety of a resin” from the viewpoint of uneven distribution on the film surface layer, and more preferably has two or more kinds thereof. Further, the hydrophobic resin preferably contains a hydrocarbon group having 5 or more carbon atoms. These groups may be present in the main chain of the resin or may be in the side chain by substitution.

In a case where hydrophobic resin includes a fluorine atom and/or a silicon atom, the fluorine atom and/or the silicon atom in the hydrophobic resin may be contained in the main chain or the side chain of the resin.

In a case where the hydrophobic resin includes a fluorine atom, it is preferably a resin having an alkyl group having a fluorine atom, a cycloalkyl group having a fluorine atom, or an aryl group having a fluorine atom, as a partial structure having a fluorine atom.

The alkyl group having a fluorine atom (preferably having 1 to 10 carbon atoms, and more preferably having 1 to 4 carbon atoms) is a linear or branched alkyl group in which at least one hydrogen atom is substituted with a fluorine atom, and may further have a substituent other than a fluorine atom.

The cycloalkyl group having a fluorine atom is a monocyclic or polycyclic cycloalkyl group in which at least one hydrogen atom is substituted with a fluorine atom, and may further have a substituent other than a fluorine atom.

The aryl group having a fluorine atom is one in which at least one hydrogen atom of the aryl group such as a phenyl group or a naphthyl group is substituted with a fluorine atom, and may further have a substituent other than a fluorine atom.

Examples of the repeating unit having a fluorine atom or a silicon atom include those exemplified in paragraph 0519 of US2012/0251948A1.

Moreover, it is also preferable that the hydrophobic resin contains a CH₃ partial structure in the side chain moiety as described above.

Here, the CH₃ partial structure contained in the side chain moiety in the hydrophobic resin includes a CH₃ partial structure contained in an ethyl group, a propyl group, and the like.

On the other hand, a methyl group bonded directly to the main chain of the hydrophobic resin (for example, an α-methyl group in the repeating unit having a methacrylic acid structure) makes a small contribution to uneven distribution on the surface of the hydrophobic resin due to the effect of the main chain, and it is therefore not included in the CH₃ partial structure in the present invention.

Regarding the hydrophobic resin, reference can be made to the description of [0348] to [0415] of JP2014-010245A, the contents of which are incorporated herein.

As the hydrophobic resin, those described in JP2011-248019A, JP2010-175859A, and JP2012-032544A can also be preferably used.

[(F) Surfactant]

The actinic ray-sensitive or radiation-sensitive resin composition may further include a surfactant (F). By the inclusion of the surfactant, it becomes possible to form a pattern which has less adhesiveness and development defects with good sensitivity and resolution at the time of using an exposure light source at a wavelength of 250 nm or less, and particularly 220 nm or less.

Fluorine-based and/or silicon-based surfactants are particularly preferably used as the surfactant.

Examples of the fluorine-based and/or silicon-based surfactants include the surfactants described in [0276] in US2008/0248425A. Further, EFTOP EF301 or EF303 (manufactured by Shin-Akita Kasei K. K.); FLORAD FC430, 431, or 4430 (manufactured by Sumitomo 3M Inc.); MEGAFACE F171, F173, F176, F189, F113, F110, F177, F120, or R08 (manufactured by DIC Corp.); SURFLON S-382, SC101, 102, 103, 104, 105, or 106 (manufactured by Asahi Glass Co., Ltd.); TROYSOL S-366 (manufactured by Troy Chemical Corp.); GF-300 or GF-150 (manufactured by Toagosei Chemical Industry Co., Ltd.); SURFLON S-393 (manufactured by Seimi Chemical Co., Ltd.); EFTOP EF121, EF122A, EF122B, RF122C, EF125M, EF135M, EF351, EF352, EF801, EF802, or EF601 (manufactured by JEMCO Inc.); PF636, PF656, PF6320, or PF6520 (manufactured by OMNOVA Solutions Inc.); or FTX-204G, 208G, 218G, 230G, 204D, 208D, 212D, 218D, or 222D (manufactured by NEOS COMPANY LIMITED) may be used. In addition, POLYSILOXANE POLYMER KP-341 (manufactured by Shin-Etsu Chemical Co., Ltd.) can also be used as the silicon-based surfactant.

Furthermore, in addition to those known surfactants as described above, a surfactant may be synthesized using a fluoroaliphatic compound which is produced by a telomerization method (also referred to as a telomer method) or an oligomerization method (also referred to as an oligomer method). Specifically, a polymer including a fluoroaliphatic group derived from the fluoroaliphatic compound may be used as the surfactant. The fluoroaliphatic compound can be synthesized in accordance with, for example, the method described in JP2002-90991A.

In addition, surfactants other than the fluorine-based and/or silicon-based surfactants described in [0280] of US2008/0248425A may be used.

These surfactants may be used singly or in combination of two or more kinds thereof.

In a case where the actinic ray-sensitive or radiation-sensitive resin composition includes a surfactant, the content of the surfactant is preferably 0% to 2% by mass, more preferably 0.0001% to 2% by mass, and still more preferably 0.0005% to 1% by mass, based on the total solid content of the composition.

[(G) Other Additives]

The actinic ray-sensitive or radiation-sensitive resin composition may further include a dissolution inhibiting compound, a dye, a plasticizer, a photosensitizer, a light absorber, and/or a compound (for example, a phenol compound having a molecular weight of 1,000 or less, or an alicyclic or aliphatic compound including a carboxy group) promoting a solubility in a developer.

The actinic ray-sensitive or radiation-sensitive resin composition may further include a dissolution inhibiting compound.

Here, the “dissolution inhibiting compound” is a compound having a molecular weight of 3,000 or less, which decomposes by the action of an acid to decrease its solubility in an organic developer.

Further, to the actinic ray-sensitive or radiation-sensitive resin composition, the organic carboxylic acid described in paragraphs [0040] to [0043] of WO2015/151759A may be added. The added organic carboxylic acid neutralizes the basic compound in the actinic ray-sensitive or radiation-sensitive resin composition to prevent alkali decomposition of the resin (A) and the hydrophobic resin (A′) over time, and to improve stability over time.

[Upper Layer Film (Top Coat Film)]

In the pattern forming method of the present invention, an upper layer film (top coat film) may be formed on the upper layer of the resist film.

It is preferable that the upper layer film is not mixed with the resist film and can be uniformly coated on the upper layer of the resist film.

The upper layer film is not particularly limited, and an upper layer film known in the related art can be formed by a method known in the related art. For example, the upper layer film can be formed based on the description of paragraphs 0072 to 0082 of JP2014-059543A. As a material for forming the upper layer film, in addition to the polymer described in paragraph 0072 of JP2014-059543A, a hydrophobic resin or the like can also be used. As the hydrophobic resin, for example, the above-mentioned hydrophobic resin (A′) can be used.

In a case of using a developer containing an organic solvent in the development step, it is preferable to form an upper layer film containing a basic compound, for example, as described in JP2013-61648A, on the resist film. Specific examples of the basic compound that can be contained in the upper layer film include a basic compound (E).

Further, the upper layer film preferably contains a compound containing at least one group or bond selected from the group consisting of an ether bond, a thioether bond, a hydroxyl group, a thiol group, a carbonyl bond, and an ester bond.

Furthermore, the upper layer film may contain a photoacid generator. As the photoacid generator, the same photoacid generator as those (for example, the above-mentioned photoacid generator (B)) that can be contained in the actinic ray-sensitive or radiation-sensitive resin composition can be used.

Hereinafter, a resin that is preferably used for the upper layer film (top coat film) will be described.

[Resin]

An upper layer film-forming composition preferably contains a resin. The resin that can be contained in the upper layer film-forming composition is not particularly limited, and the same one as the hydrophobic resin (for example, hydrophobic resin (A′)) that can be contained in the actinic ray-sensitive or radiation-sensitive resin composition can be used.

Regarding the hydrophobic resin, reference can be made to the description of [0017] to [0023] of JP2013-61647A ([0017] to [0023] of the corresponding US2013/244438A) and [0016] to [0165] of JP2014-56194A, the contents of which are incorporated herein.

In the present invention, the upper layer film-forming composition preferably contains a resin containing a repeating unit having an aromatic ring. By containing a repeating unit having an aromatic ring, particularly upon exposure using electron beams or EUV, increased generation efficiency of secondary electrons, and increased acid generation efficiency due to the compound capable of generating an acid by actinic rays or radiation are achieved, and thus high sensitivity and high resolution can be anticipated at the time of forming a pattern.

The weight-average molecular weight of the resin is preferably 3,000 to 100,000, more preferably 3,000 to 30,000, and still more preferably 5,000 to 20,000. The blending amount of the resin in the upper layer film-forming composition is preferably 50% to 99.9% by mass, more preferably 60% to 99.0% by mass, still more preferably 70% to 99.7% by mass, and particularly preferably 80% to 99.5% by mass, with respect to the total solid content.

In a case where the upper layer film-forming composition (top coat composition) contains a plurality of resins, it preferably contains at least one resin (XA) having a fluorine atom and/or a silicon atom.

In a preferable range of the content of fluorine atom and silicon atom contained in the resin (XA), the repeating unit containing a fluorine atom and/or a silicon atom is preferably 10% to 100% by mass, more preferably 10% to 99% by mol, and still more preferably from 20% to 80% by mol, in the resin (XA).

Further, the upper layer film-forming composition more preferably contains at least one resin (XA) having a fluorine atom and/or a silicon atom and a resin (XB) having the content of a fluorine atom and/or a silicon atom smaller than that of the resin (XA). Thus, in a case where the upper layer film is formed, since the resin (XA) is unevenly distributed on the surface of the upper layer film, it is possible to improve performance such as development characteristics and/or immersion liquid tracking properties.

The content of the resin (XA) is preferably 0.01% to 30% by mass, more preferably 0.1% to 10% by mass, still more preferably 0.1% to 8% by mass, and particularly preferably 0.1% to 5% by mass, based on the total solid content contained in the upper layer film-forming composition. The content of the resin (XB) is preferably 50.0% to 99.9% by mass, more preferably 60% to 99.9% by mass, still more preferably 70% to 99.9% by mass, and particularly preferably 80% to 99.9% by mass, based on the total solid content contained in the upper layer film-forming composition.

As the resin (XB), a form substantially not containing a fluorine atom and a silicon atom is preferable. In this case, specifically, the total content of the repeating unit having a fluorine atom and the repeating unit having a silicon atom is preferably 0% to 20% by mol, more preferably from 0% to 10% by mol, still more preferably from 0% to 5% by mol, and particularly preferably from 0% to 3% by mol, and ideally 0% by mol, that is, no fluorine atom and silicon atom is contained, with respect to all the repeating units in the resin (XB).

[Method for Preparing Upper Layer Film-Forming Composition (Top Coat Composition)]

It is preferable that the upper layer film-forming composition is obtained by dissolving each of the components in a solvent and filtering the resulting solution using a filter. As the filter, for example, one made of polytetrafluoroethylene, polyethylene, or nylon having a pore size of 0.1 μm or less, preferably 0.05 μm or less, and more preferably 0.03 μm or less is preferable. Plural kinds of filters may be connected in series or in parallel, and used. In addition, the composition may be filtered plural times, and a step of filtering plural times may be a circulatory filtration step. Furthermore, a degassing treatment or the like may be performed with respect to the composition before and after filtration using a filter. It is preferable that the upper layer film-forming composition does not contain impurities such as a metal. The content of the metal component contained in these materials is preferably 10 ppm or less, more preferably 5 ppm or less, still more preferably 1 ppm or less, and particularly preferably the metal component is substantially not contained (not higher than a detection limit of a determination device).

In the above-mentioned exposure step, in a case where the exposure is a liquid immersion exposure, the upper layer film is disposed between an actinic ray-sensitive or radiation-sensitive film and an immersion liquid, and also functions as a layer which prevents the actinic ray-sensitive or radiation-sensitive film from being brought into direct contact with the immersion liquid. In this case, preferred properties caused by the upper layer film (upper layer film-forming composition) are suitability for coating on an actinic ray-sensitive or radiation-sensitive film, transparency to radiation, particularly 193 nm, and poor solubility in the immersion liquid (preferably water). Further, it is preferable that the upper layer film is not mixed with the actinic ray-sensitive or radiation-sensitive film and can be uniformly coated on the surface of the actinic ray-sensitive or radiation-sensitive film.

In order to uniformly coat the upper layer film-forming composition on the surface of the actinic ray-sensitive or radiation-sensitive film without dissolving the actinic ray-sensitive or radiation-sensitive film, the upper layer film-forming composition preferably contains a solvent which does not dissolve the actinic ray-sensitive or radiation-sensitive film. As the solvent which does not dissolve the actinic ray-sensitive or radiation-sensitive film, it is further preferable to use a solvent having a different component from a developer (organic developer) containing an organic solvent.

The coating method of the upper layer film-forming composition is not particularly limited, and spin coating method, spray method, roller coating method, dipping method, or the like known in the related art can be used.

The thickness of the upper layer film is not particularly limited, and is usually formed to have a thickness of 5 nm to 300 nm, preferably 10 nm to 300 nm, more preferably 20 nm to 200 nm, and still more preferably 30 nm to 100 nm, from the viewpoint of transparency to the exposure light source.

After forming the upper layer film, the substrate is heated (PB), as desired.

The refractive index of the upper layer film is preferably close to the refractive index of the actinic ray-sensitive or radiation-sensitive film, from the viewpoint of resolution.

The upper layer film is preferably insoluble in the immersion liquid, and more preferably insoluble in water.

Regarding the receding contact angle of the upper layer film, the receding contact angle (23° C.) of the immersion liquid with respect to the upper layer film is preferably from 50 to 100 degrees, and more preferably from 80 to 100 degrees, from the viewpoint of immersion liquid tracking properties.

In the liquid immersion exposure, since the immersion liquid needs to move on the wafer while tracking the movement of an exposure head scanning the wafer at a high speed to form an exposure pattern, the contact angle of the immersion liquid to the actinic ray-sensitive or radiation-sensitive film in a dynamic state becomes important. Thus, in order to obtain better resist performance, it is preferable to have the receding contact angle of the above-mentioned range.

At the time of peeling the upper layer film, an organic developer may be used, or a separate release agent may be used. As the release agent, a solvent having a small permeation into the actinic ray-sensitive or radiation-sensitive film is preferable. From the viewpoint that peeling of the upper layer film can be performed simultaneously with development of the actinic ray-sensitive or radiation-sensitive film, it is preferable that the upper layer film can be peeled off with the organic developer. The organic developer used for the peeling is not particularly limited as long as it can dissolve and remove a low exposed portion of the actinic ray-sensitive or radiation-sensitive film.

From the viewpoint of being peeled off with the organic developer, the dissolution rate of the upper layer film to the organic developer is preferably 1 to 300 nm/sec, and more preferably 10 to 100 nm/sec.

Here, the dissolution rate of the upper layer film to the organic developer is a reduction rate of film thickness in a case where the upper layer film is formed and then exposed to the developer, and in the present invention, it is a rate in a case of being immersed in butyl acetate at 23° C.

By setting the dissolution rate of the upper layer film to the organic developer to 1 nm/sec or more, preferably 10 nm/sec or more, an effect of reduced occurrence of development defects after development of the actinic ray-sensitive or radiation-sensitive film is exhibited. Further, by setting such dissolution rate to 300 nm/sec or less, preferably 100 nm/sec, presumably, due to influence of reduced exposure unevenness at the time of liquid immersion exposure, an effect of obtaining better pattern line edge roughness after developing the actinic ray-sensitive or radiation-sensitive film is exhibited.

The upper layer film may be removed using another known developer, for example, an alkaline aqueous solution. Specific examples of the alkaline aqueous solution that can be used include an aqueous solution of tetramethylammonium hydroxide.

[Allowable Content of Impurities]

It is preferable that various materials (for example, a developer, a rinsing liquid, a resist solvent, an antireflection film-forming composition, and an upper layer film-forming composition) used in the actinic ray-sensitive or radiation-sensitive resin composition and the pattern forming method of the present invention contain no impurities such as metals, metal salts including halogen, acids, alkalis, sulfur-containing compounds, and phosphorus-containing compounds. The content of the impurities contained in these materials is preferably 1 ppm or less, more preferably 1 ppb or less, still more preferably 100 ppt or less, and particularly preferably 10 ppt or less, and most preferably, the impurities are substantially not contained (not higher than a detection limit of a determination device).

Examples of a method for removing impurities such as metals from the various materials include filtration using a filter. As for the filter pore diameter, the pore size is preferably 10 nm or less, more preferably 5 nm or less, and still more preferably 3 nm or less. As for the materials of a filter, a polytetrafluoroethylene-made filter, a polyethylene-made filter, and a nylon-made filter are preferable. The filter may be formed of a composite material formed by combining this material with an ion exchange medium. As the filter, a filter which had been washed with an organic solvent in advance may be used. In the step of filtration using a filter, plural kinds of filters may be connected in series or in parallel, and used. In a case of using plural kinds of filters, a combination of filters having different pore diameters and/or materials may be used. In addition, various materials may be filtered plural times, and a step of filtering plural times may be a circulatory filtration step.

Examples of a method for removing impurities such as metals from the above-mentioned various materials include a purification step by distillation (in particular, thin film distillation, molecular distillation, or the like). Examples of the distillation purification step include those described in, for example, “<Factory Operation Series> Enlarged/Distillation, published on Jul. 31, 1992, Chemical Industry Co., Ltd.” and “Chemical Engineering Handbook, published on Sep. 30, 2004, Asakura Shoten, p.p. 95 to 102”.

Moreover, examples of the method for reducing the impurities such as metals contained in the various materials include a method involving selecting raw materials having a small content of metals as raw materials constituting various materials, a method involving subjecting raw materials constituting various materials to filtration using a filter, and a method involving performing distillation under the condition with contamination being suppressed as much as possible by, for example, lining the inside of a device with TEFLON (registered trademark). The preferred conditions for filtration using a filter, which is carried out for raw materials constituting various materials, are the same as described above.

In addition to filtration using a filter, removal of impurities by an adsorbing material may be carried out, or a combination of filtration using a filter and an adsorbing material may be used. As the adsorbing material, known adsorbing materials may be used, and for example, inorganic adsorbing materials such as silica gel and zeolite, and organic adsorbing materials such as activated carbon can be used.

[Content of Sulfur-Containing Compound]

In the developer and/or the rinsing liquid (hereinafter, for convenience, these are collectively referred to as “treatment liquid”), the content of the sulfur-containing compound is preferably 10 mmol/L or less.

Thus, it is possible to suppress occurrence of defects in a resist pattern. Although details for this reason has not been clarified yet, it is presumed as follows.

That is, since the content of the sulfur-containing compound is small in the treatment liquid used as the developer and/or the rinsing liquid, it is possible to suppress a reaction between the sulfur-containing compound contained in the treatment liquid and a polar group in a component, in particular, a polymer component, contained in the film (resist film) after exposure. As a result, it is presumed that foreign matter generated on the surface of the resist pattern due to a reaction between the sulfur-containing compound and the polar group or the like in the polymer component can be suppressed, and thus generation of defects in the resist pattern can be suppressed.

Further, in particular, it is preferable that the amount of the sulfur-containing compound is further reduced in the treatment liquid used in steps to be carried out later, that is, it is preferable that the amount of the sulfur-containing compound is further reduced in the rinsing liquid.

In the treatment liquid, the content (concentration) of the sulfur-containing compound is more preferably 2.5 mmol/L or less, still more preferably 1.0 mmol/L or less, and most preferably the sulfur-containing compound is substantially not contained.

In this manner, by setting the content of the sulfur-containing compound to 10.0 mmol/L or less, for example, even in a case where the treatment liquid has been stored in a housing container (for example, the container described in JP2014-112176A), with a stopper thereof closed, at room temperature (23° C.) for 6 months, occurrence of defects in the resist pattern can be suppressed.

Here, “substantially not contained” means that in a case where the content (concentration) of the sulfur-containing compound is measured by a measurement method (for example, a measurement method as described later), it is not detected (present in an amount less than a detection limit value).

As described above, as the lower limit of the content (concentration) of the sulfur-containing compound, it is most preferable that the sulfur-containing compound is substantially not contained. However, as described later, in a case where a treatment such as distillation is excessively performed to reduce the content of the sulfur-containing compound, costs are increased. Considering the costs and the like at the time of being industrially used, the content of the sulfur-containing compound may be 0.01 mmol/L or more.

In the present invention, the sulfur-containing compound is mainly an organic substance containing a sulfur element originally contained as an impurity in the components constituting the treatment liquid. For example, in a naturally occurring hydrocarbon-based solvent such as decane and undecane, even after a fractional distillation process of petroleum, for example, a sulfur-containing compound having a near boiling point such as benzothiophene and 3-methylbenzothiophene tends to remain in a trace amount without being removed.

Examples of the sulfur-containing compound contained in the treatment liquid include thiols, sulfides, and thiophenes, and among these, sulfur compounds having a boiling point of 190° C. or higher (particularly 220° C. or higher and more particularly 280° C. or higher) are exemplified.

Specific examples of the thiols include methanethiol, ethanethiol (ethylmercaptan), 3-methyl-2-butene-1-thiol, 2-methyl-3-furanthiol, furfurylthiol (furfurylmercaptan), 3-mercapto-3-methylbutyl formate, phenyl mercaptan, methyl furfuryl mercaptan, ethyl 3-mercaptobutanoate, 3-mercapto-3-methyl butanol, and 4-mercapto-4-methyl-2-pentanone.

Examples of the sulfides include dimethylsulfide, dimethyltrisulfide, diisopropyltrisulfide, and bis(2-methyl-3-furyl) disulfide.

Examples of the thiophenes include alkylthiophenes, benzothiophenes, dibenzothiophenes, phenanthrothiophenes, benzonaphthothiophenes, and thiophene sulfides, each of which are variously substituted.

Among these, by setting the content of the thiophenes, particularly the benzothiophenes (for example, benzothiophene or 3-methylbenzothiophene) to 10.0 mmol/L or less, occurrence of defects in the resist pattern can be further suppressed.

The content of the sulfur-containing compound in the treatment liquid can be measured, for example, by the method defined in JIS K2541-6: 2013 “Test Method for Sulfur Content (Ultraviolet Fluorescence Method)”.

[Content of Phosphorus Compound]

The present inventors further found that a compound containing phosphorus (hereinafter referred to as “phosphorus-containing compound”) also interacts with a component contained in a resist pattern, similarly to the sulfur-containing compound as described above, and thus remains on the surface of the resist pattern without volatilization even after the rinsing step and then drying, thereby becoming a cause of foreign matter defects.

Therefore, in the treatment liquid (developer and/or rinsing liquid), the content of the compound containing phosphorus (hereinafter referred to as “phosphorus-containing compound”) is preferably 10 mmol/L or less, more preferably 2.5 mmol/L or less, still more preferably 1.0 mmol/L or less, and particularly preferably the compound containing phosphorus is substantially not contained.

Here, “substantially not contained” means that in a case where the content (concentration) of the phosphorus-containing compound is measured by a measurement method (for example, a measurement method as described later), it is not detected (present in an amount less than a detection limit value).

As described above, as the lower limit of the content (concentration) of the phosphorus-containing compound, it is most preferable that the phosphorus-containing compound is substantially not contained. However, as described later, in a case where a treatment such as distillation is excessively performed to reduce the content of the phosphorous-containing compound, costs are increased. Considering the costs and the like at the time of being industrially used, the content of the phosphorous-containing compound may be 0.01 mmol/L or more.

The phosphorus-containing compound is mainly an organic substance containing a phosphorus element originally contained as an impurity in the components constituting the treatment liquid and/or an organic substance containing a phosphorus element incorporated at the time of handling the treatment liquid. Examples thereof include phosphoric acid, and a phosphorus-based catalyst (organic phosphine, organic phosphine oxide, or the like) used for synthesizing an organic solvent.

The content of the compound containing phosphorus in the treatment liquid can be quantified as a total phosphorous using absorptiometry based on the method defined in JIS K0102: 2013. In a case of an organic substance containing phosphorus, the content thereof can be individually quantified, for example, using gas chromatography.

In the treatment liquid, the content of the sulfur-containing compound and/or the phosphorus-containing compound can be further reduced by performing distillation and/or filtration, and the like of the organic solvent to be used.

[Manufacturing Method of Electronic Device]

The present invention also relates to a method for manufacturing an electronic device including the above-mentioned pattern forming method of the present invention. An electronic device manufactured by the method for manufacturing an electronic device of the present invention is suitably mounted on electric or electronic equipment such as home electronics, office automation (OA)-related equipment, media-related equipment, optical equipment, and communication equipment.

### EXAMPLES

Hereinbelow, the present invention will be described in more detail with reference to Examples. However, the present invention is not intended to be limited to Examples shown below while not departing from the spirit of the present invention. Further, “parts” and “%” are given on the basis of mass unless otherwise specifically stated.

[Synthesis of Resin (A-2)]

First, monomer (a1) was synthesized and resin (A-2) was synthesized using the synthesized monomer (a1). Details thereof will be described in detail below.

<Synthesis of Monomer (a1)>

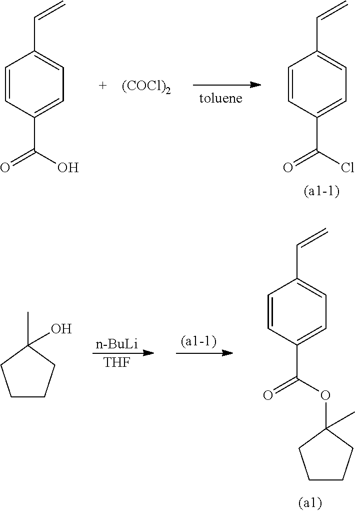

(Synthesis of Intermediate (a1-1))

30 g of 4-vinylbenzoic acid was suspended in 220 mL of toluene, 1 mL of N,N-dimethylformamide was added, and then 38.7 g of oxalyl dichloride was added dropwise under a nitrogen stream. After stirring at room temperature for 2 hours, the mixture was stirred at 50° C. for 2 hours. After allowing the mixture to cool to room temperature, 15 mg of 2,6-di-tert-butyl-p-cresol was added to the reaction solution, and the solvent and excess of oxalyl dichloride were distilled off by heating at 50° C. under reduced pressure to obtain 37 g of a pale yellow liquid. According to ¹H-NMR, the proportion of the intermediate (a1-1) was 90.7% and the remaining 9.3% was toluene. This intermediate (a1-1) was used for the next reaction without further purification.

¹H-NMR (Acetone-d6: ppm) δ: 8.11 (d, 2H), 7.73 (d, 2H), 6.90 (dd, 1H), 6.10 (d, 1H), 5.53 (d, 1H)

(Synthesis of Monomer (a1))

7.6 g of 1-methylcyclopentanol and 130 mL of tetrahydrofuran were mixed and cooled to −78° C. under a nitrogen gas atmosphere. 46 mL of n-butyllithium (1.6 M hexane solution) was added dropwise and the mixture was stirred at −78° C. for 1 hour and then stirred at −10° C. for further 1 hour. A solution prepared by mixing 13.8 g of the intermediate a1-1 (purity of 90.7%) and 30 mL of tetrahydrofuran was carefully added dropwise to the reaction solution cooled to −10° C. so as not to excessively generate heat. After stirring at room temperature for 2 hours, 300 mL of n-hexane and 300 mL of distilled water were added, and separation operation was performed. The organic layer was washed with a saturated aqueous solution of sodium hydrogencarbonate and distilled water, dehydrated with magnesium sulfate, filtered off, and the solvent of the organic layer was distilled off under reduced pressure. The residue was purified by silica gel column chromatography (eluent: ethyl acetate/n-hexane=3/97) to obtain 13 g of monomer (a1).

¹H-NMR (Acetone-d6: ppm) δ: 7.94 (d, 2H), 7.57 (d, 2H), 6.84 (dd, 1H), 5.95 (d, 1H), 5.38 (d, 1H), 2.28 (m, 2H), 1.85-1.68 (m, 6H), 1.67 (s, 3H)

Each monomer was synthesized in substantially the same manner as above except that 1-methylcyclopentanol was changed.

<Synthesis of Resin (A-2)>

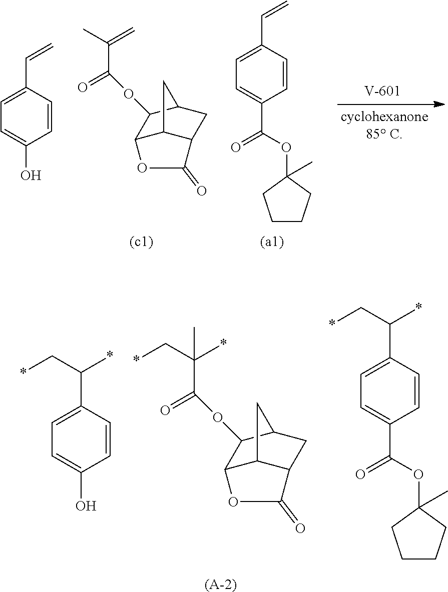

8.6 g of monomer (a1), 3.3 g of monomer (c1), 2.7 g of p-hydroxystyrene, 0.60 g of polymerization initiator V-601 (manufactured by Wako Pure Chemical Industries, Ltd.) were dissolved in 54.1 g of cyclohexanone. 29.1 g of cyclohexanone was put into a reaction container and added dropwise into a system at 85° C. for 4 hours in a nitrogen gas atmosphere. The reaction solution was heated and stirred for 2 hours, and then left to be cooled to room temperature. The reaction solution was added dropwise to 978 g of a mixed solution of n-heptane and ethyl acetate (n-heptane/ethyl acetate=9/1 (mass ratio)) to precipitate the polymer, followed by filtration. The filtered solid was washed using 293 g of a mixed solution of n-heptane and ethyl acetate (n-heptane/ethyl acetate=9/1 (mass ratio)). Thereafter, the washed solid was dried under reduced pressure to obtain 11.9 g of Resin (A-2). The weight-average molecular weight according to GPC was 13,000 and the molecular weight dispersity (Mw/Mn) was 1.49.

¹H-NMR (DMSO-d 6: ppm) δ: 9.38-8.84, 8.16-7.35, 7.33-6.04, 2.58-1.02 (all peaks are broad)

[Synthesis of Resins (A-1), (A-3) to (A-65), (R-1), and (R-2)]

Resins (A-1), (A-3) to (A-65), (R-1), and (R-2) having structures shown in Tables 3 to 11 were synthesized in substantially the same manner as above except that the monomer used was changed.

In Tables 3 to 11, a compositional ratio (molar ratio) of the resin was calculated by ¹H-NMR (nuclear magnetic resonance) or ¹³C-NMR measurement. The weight-average molecular weight (Mw: in terms of polystyrene) and the dispersity (Mw/Mn) of the resin were calculated by GPC (solvent: THF) measurement.

TABLE 3

| | | Compositional ratio | | |
|---|---|---|---|---|
| | | (molar ratio) | | |
| Resin | Structure | from the left | Mw | Mw/Mn |
| A-1 | 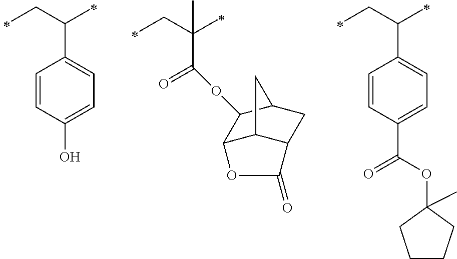 | 30/10/60 | 12,400 | 1.47 |
| A-2 | 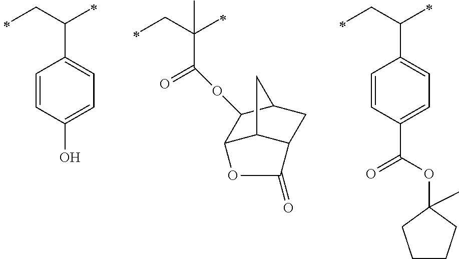 | 30/20/50 | 13,000 | 1.49 |
| A-3 | 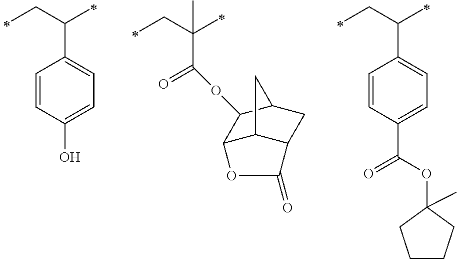 | 15/30/55 | 12,900 | 1.51 |
| A-4 | 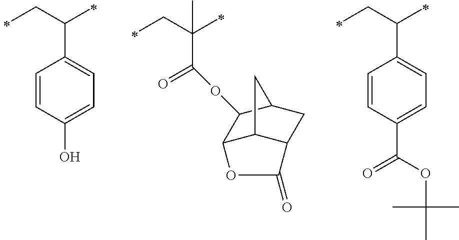 | 30/20/50 | 12,400 | 1.46 |
| A-5 | 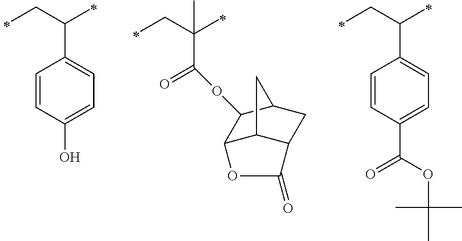 | 20/10/70 | 13,000 | 1.50 |
| A-6 | 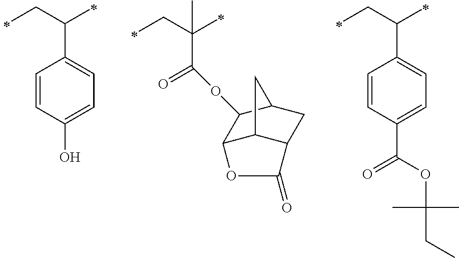 | 30/20/50 | 12,200 | 1.49 |
| A-7 | 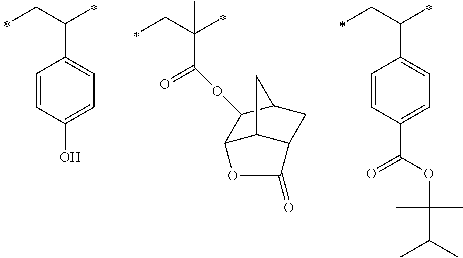 | 30/20/50 | 12,600 | 1.52 |
| A-8 | 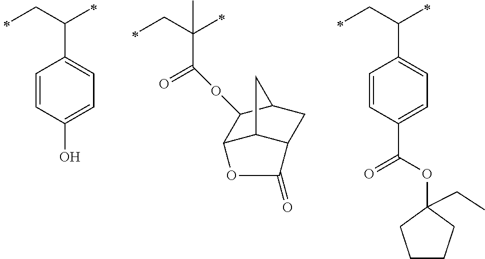 | 30/20/50 | 12,500 | 1.50 |

TABLE 4

| | | Compositional ratio | | |
|---|---|---|---|---|
| | | (molar ratio) | | |
| Resin | Structure | from the left | Mw | Mw/Mn |
| A-9 | 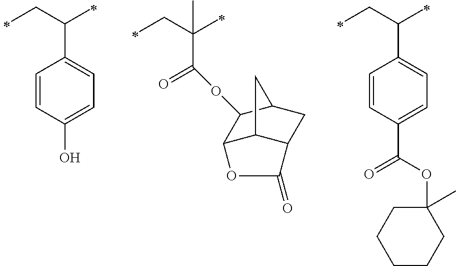 | 30/20/50 | 12,100 | 1.47 |
| A-10 | 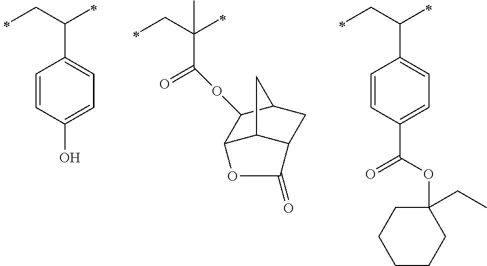 | 30/20/50 | 12,600 | 1.49 |
| A-11 | 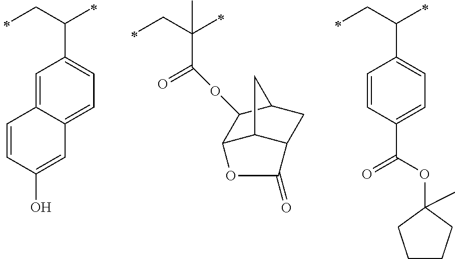 | 30/10/60 | 12,400 | 1.51 |
| A-12 | 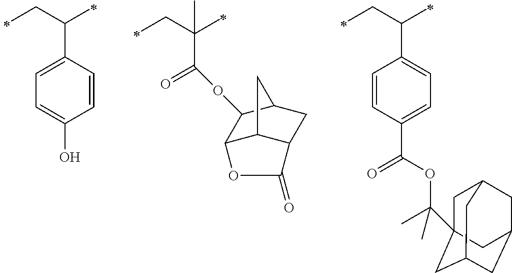 | 30/20/50 | 13,100 | 1.52 |
| A-13 | 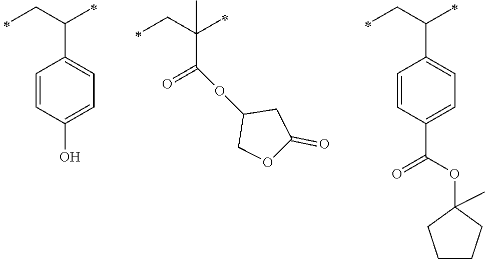 | 30/20/50 | 11,900 | 1.48 |
| A-14 | 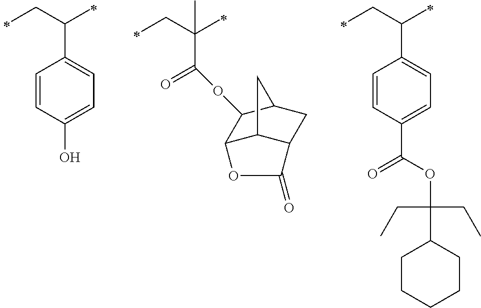 | 30/20/50 | 12,000 | 1.48 |
| A-15 | 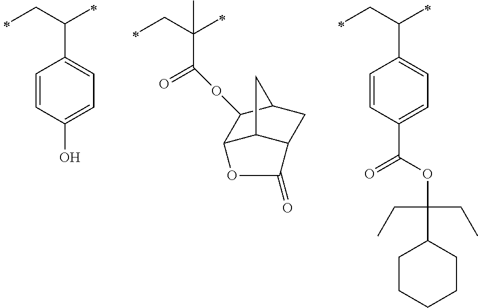 | 20/10/70 | 11,800 | 1.47 |
| A-16 | 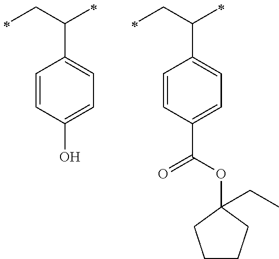 | 50/50 | 11,700 | 1.48 |

TABLE 5

| | | Compositional ratio | | |
|---|---|---|---|---|
| | | (molar ratio) | | |
| Resin | Structure | from the left | Mw | Mw/Mn |
| A-17 | 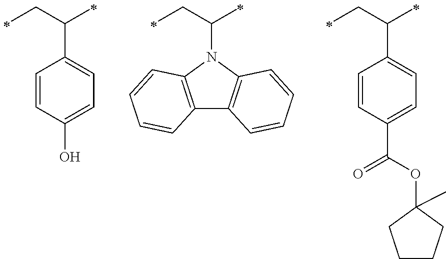 | 30/25/45 | 13,200 | 1.49 |
| A-18 | 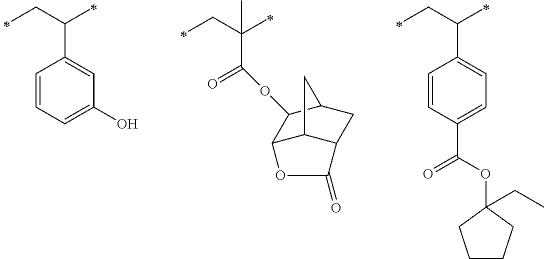 | 30/20/50 | 12,300 | 1.47 |
| A-19 | 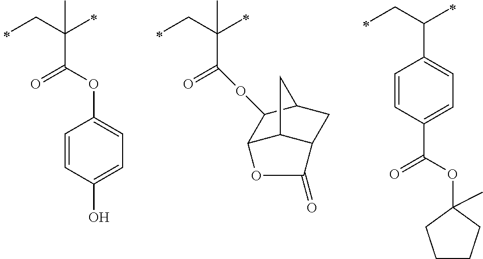 | 30/25/45 | 12,900 | 1.53 |
| A-20 | 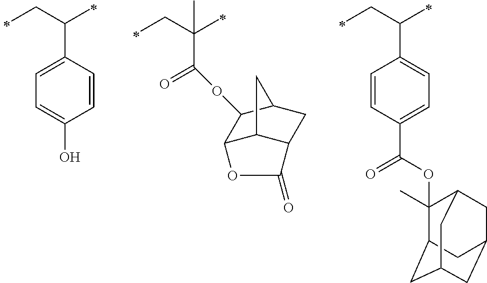 | 30/20/50 | 12,600 | 1.52 |
| A-21 | 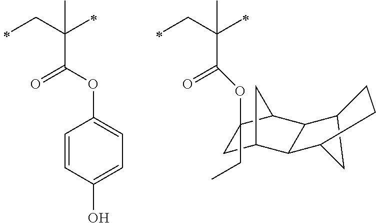 | 20/30/30/20 | 11,300 | 1.55 |
| | 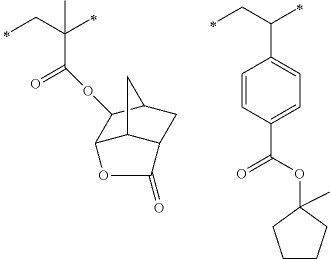 | | | |
| A-22 | 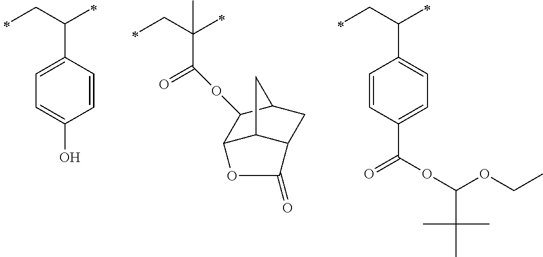 | 30/20/50 | 11,700 | 1.54 |
| A-23 | 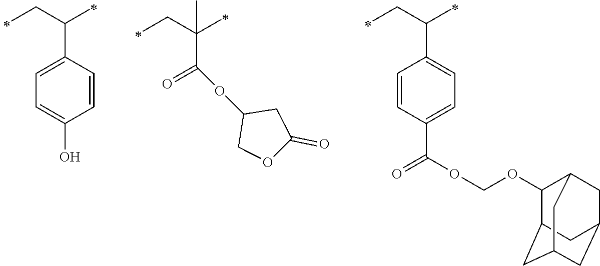 | 30/20/50 | 11,900 | 1.53 |
| A-24 | 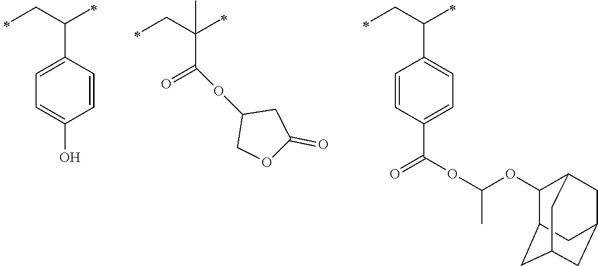 | 30/20/50 | 12,500 | 1.54 |

TABLE 6

| | | Compositional ratio | | |
|---|---|---|---|---|
| | | (molar ratio) | | |
| Resin | Structure | from the left | Mw | Mw/Mn |
| A-25 | 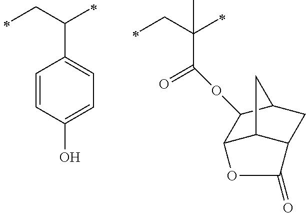 | 30/20/25/25 | 13,000 | 1.52 |
| | 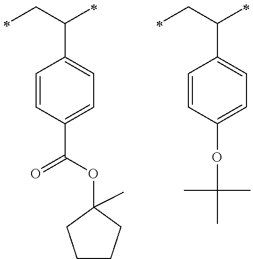 | | | |
| A-26 | 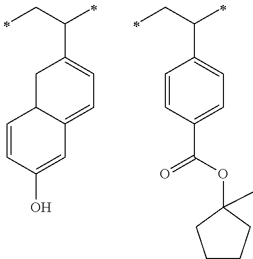 | 30/70 | 13,100 | 1.49 |
| A-27 | 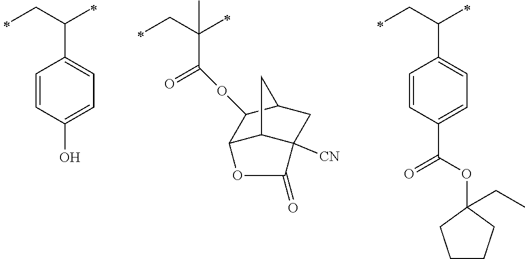 | 30/20/50 | 13,300 | 1.51 |
| A-28 | 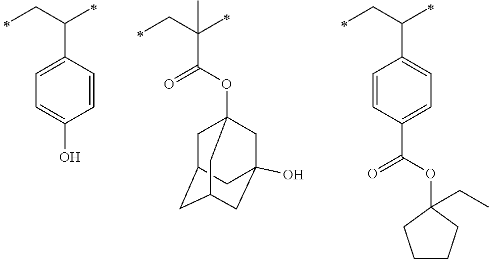 | 30/20/50 | 12,700 | 1.48 |
| A-29 | 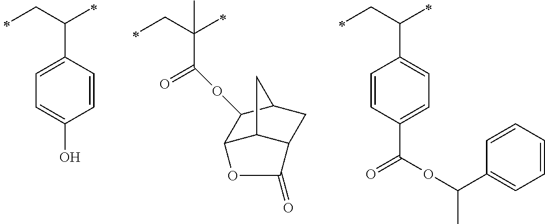 | 30/20/50 | 11,800 | 1.50 |
| A-30 | 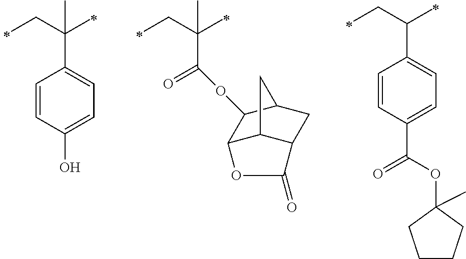 | 30/20/50 | 11,400 | 1.46 |
| A-31 | 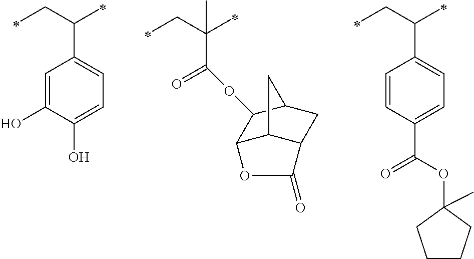 | 30/20/50 | 11,200 | 1.51 |
| A-32 | 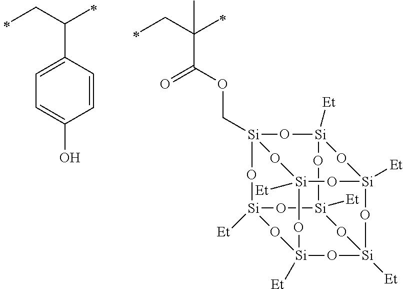 | 30/5/15/50 | 13,800 | 1.54 |
| | 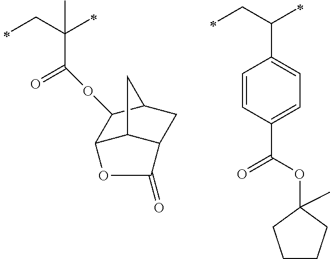 | | | |

TABLE 7

| | | Compositional ratio | | |
|---|---|---|---|---|
| | | (molar ratio) | | |
| Resin | Structure | from the left | Mw | Mw/Mn |
| A-33 | 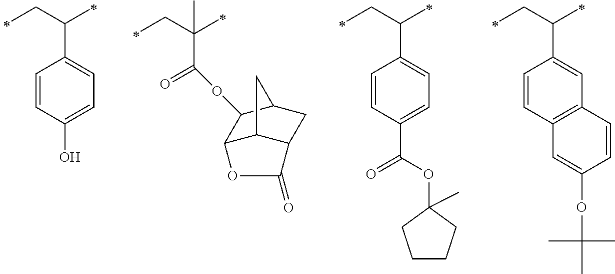 | 30/5/35/30 | 13,700 | 1.55 |
| A-34 | 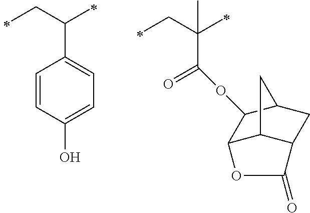 | 30/20/25/25 | 12,900 | 1.53 |
| | 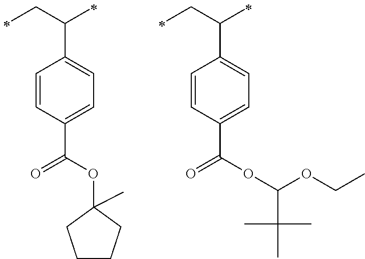 | | | |
| A-35 | 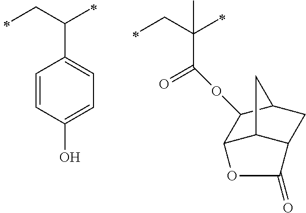 | 30/5/35/30 | 13,300 | 1.55 |
| | 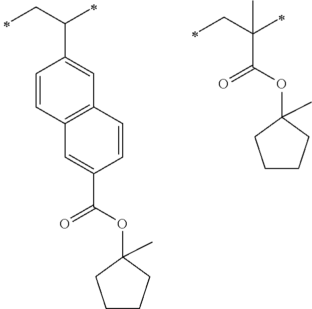 | | | |
| A-36 | 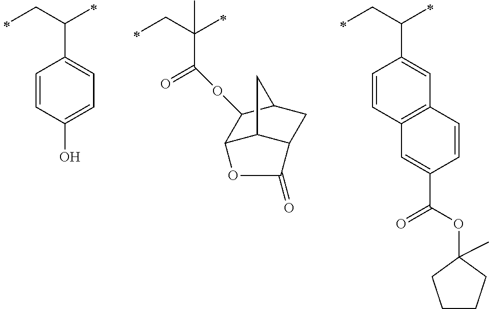 | 30/10/60 | 12,400 | 1.47 |
| A-37 | 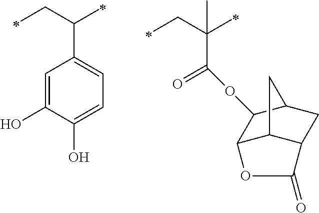 | 30/20/15/35 | 11,800 | 1.55 |
| | 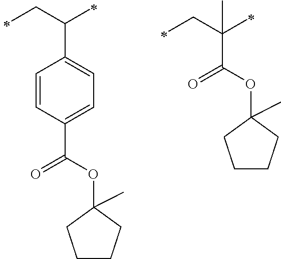 | | | |
| A-38 | 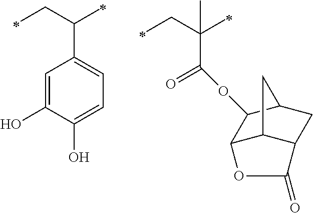 | 30/20/40/10 | 12,100 | 1.56 |
| | 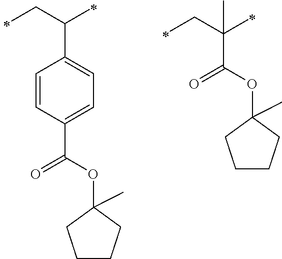 | | | |
| A-39 | 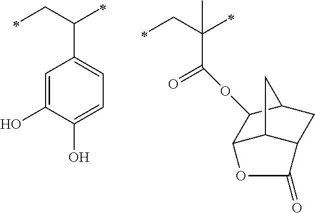 | 10/30/30/30 | 11,500 | 1.53 |
| | 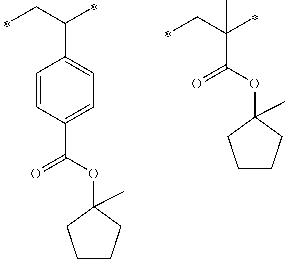 | | | |
| A-40 | 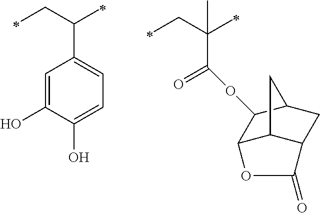 | 30/20/15/35 | 6,900 | 1.56 |
| | 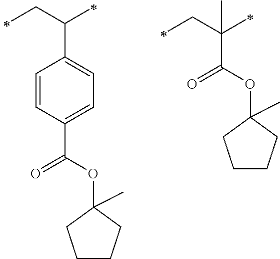 | | | |

TABLE 8

| | | Compositional ratio | | |
|---|---|---|---|---|
| | | (molar ratio) | | |
| Resin | Structure | from the left | Mw | Mw/Mn |
| A-41 | 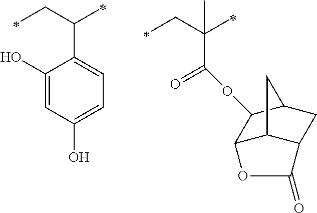 | 30/20/15/35 | 10,000 | 1.57 |
| | 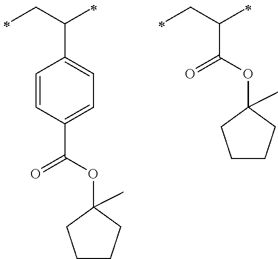 | | | |
| A-42 | 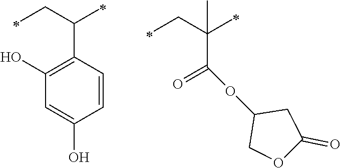 | 50/10/20/20 | 10,900 | 1.54 |
| | 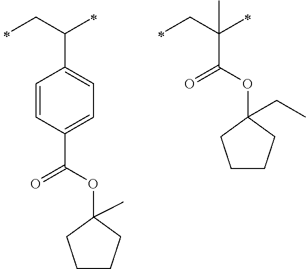 | | | |
| A-43 | 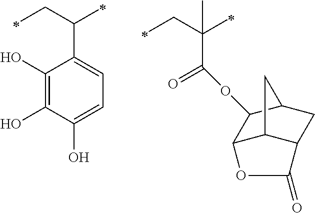 | 30/20/15/35 | 10,500 | 1.56 |
| | 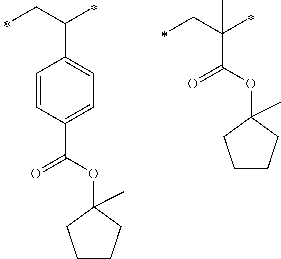 | | | |
| A-44 | 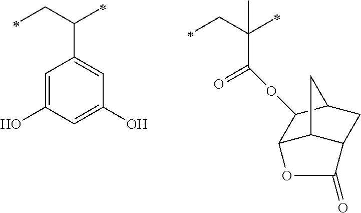 | 30/20/15/35 | 12,200 | 1.52 |
| | 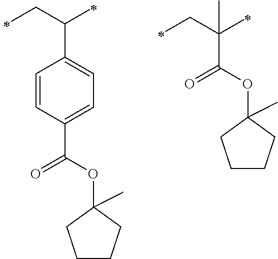 | | | |
| A-45 | 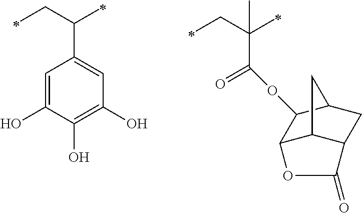 | 30/20/15/35 | 11,900 | 1.57 |
| | 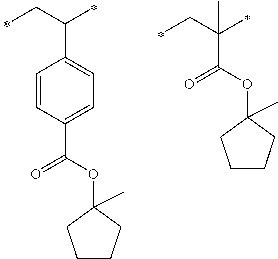 | | | |
| A-46 | 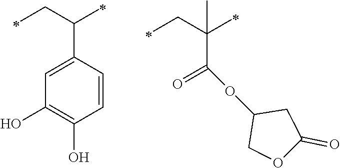 | 30/30/30/10 | 12,100 | 1.53 |
| | 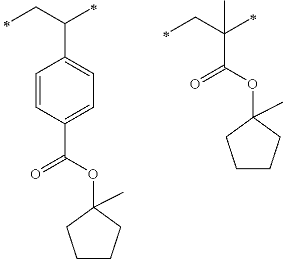 | | | |
| A-47 | 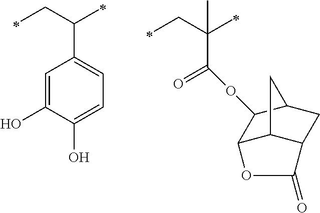 | 30/20/20/30 | 13,100 | 1.54 |
| | 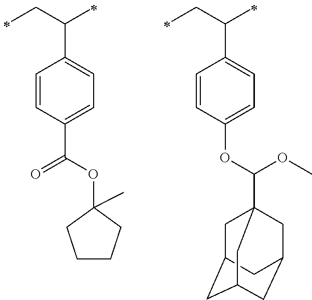 | | | |
| A-48 | 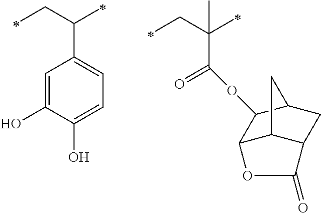 | 25/30/20/25 | 12,300 | 1.55 |
| | 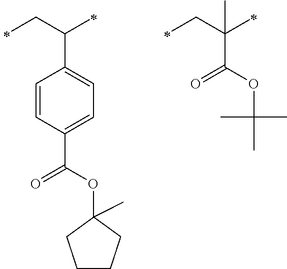 | | | |

TABLE 9

| | | Compositional ratio | | |
|---|---|---|---|---|
| | | (molar ratio) | | |
| Resin | Structure | from the left | Mw | Mw/Mn |
| A-49 | 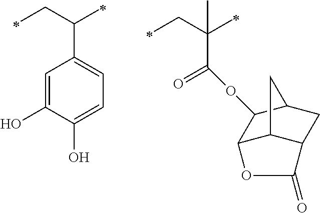 | 30/20/10/40 | 11,600 | 1.57 |
| | 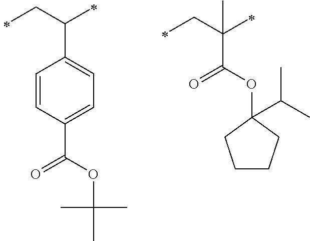 | | | |
| A-50 | 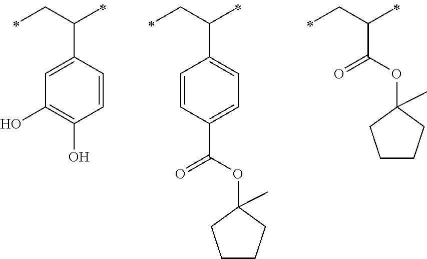 | 60/20/20 | 11,700 | 1.48 |
| A-51 | 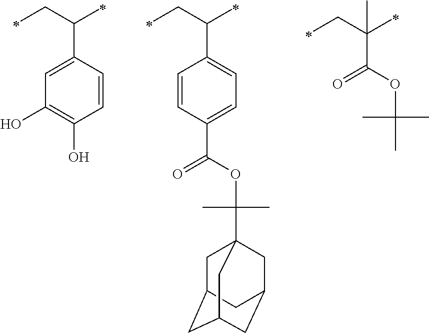 | 50/20/30 | 12,200 | 1.50 |
| A-52 | 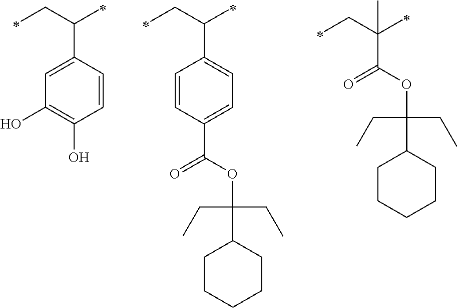 | 60/30/10 | 11,700 | 1.51 |
| A-53 | 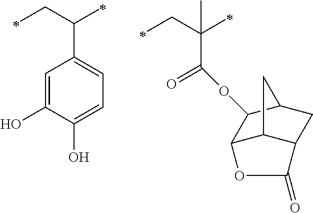 | 30/10/20/40 | 12,800 | 1.54 |
| | 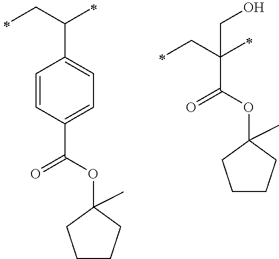 | | | |
| A-54 | 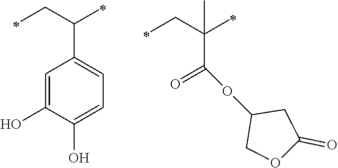 | 25/25/25/25 | 12,600 | 1.55 |
| | 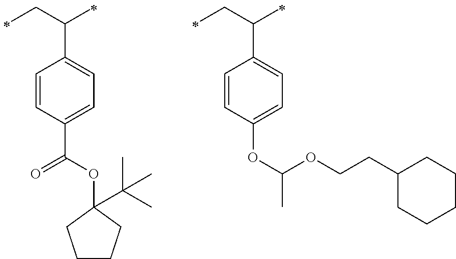 | | | |
| A-55 | 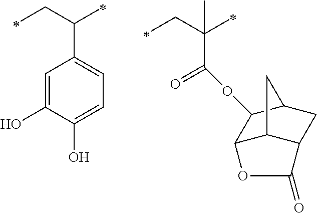 | 30/20/30/20 | 11,200 | 1.57 |
| | 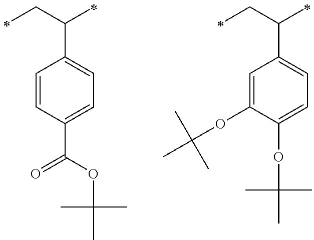 | | | |
| A-56 | 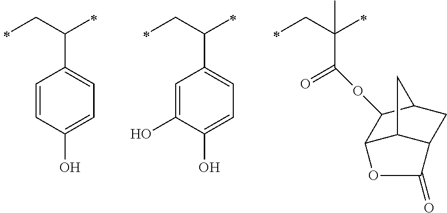 | 15/15/20/15/35 | 12,200 | 1.55 |
| | 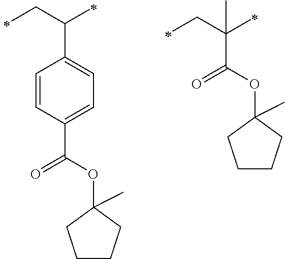 | | | |

TABLE 10

| | | Compositional ratio | | |
|---|---|---|---|---|
| | | (molar ratio) | | |
| Resin | Structure | from the left | Mw | Mw/Mn |
| A-57 | 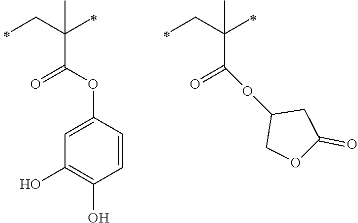 | 20/20/30/30 | 12,800 | 1.54 |
| | 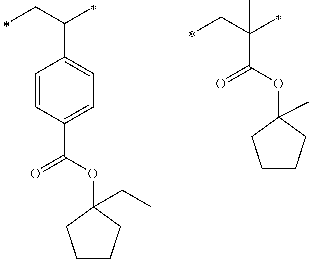 | | | |
| A-58 | 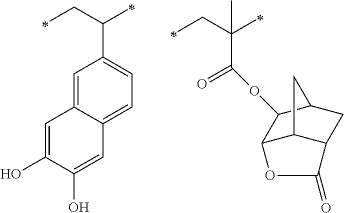 | 30/10/30/30 | 13,300 | 1.53 |
| | 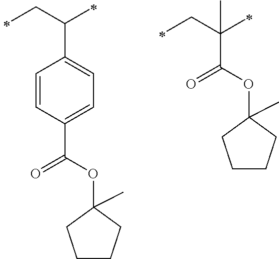 | | | |
| A-59 | 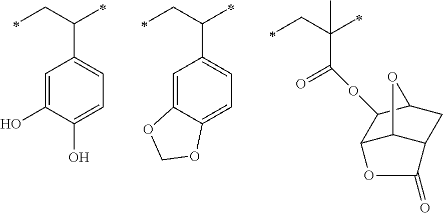 | 25/5/15/35/20 | 12,400 | 1.55 |
| | 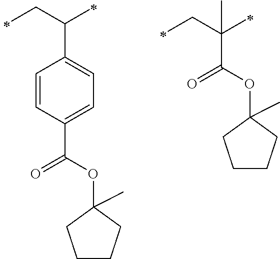 | | | |
| A-60 | 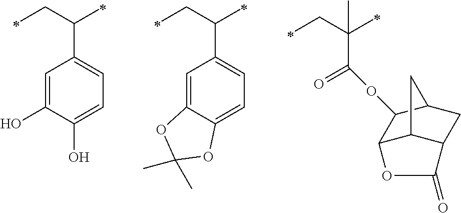 | 30/5/15/25/25 | 12,600 | 1.54 |
| | 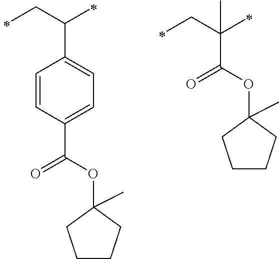 | | | |
| A-61 | 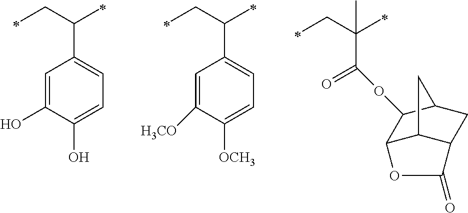 | 25/5/20/15/35 | 12,000 | 1.53 |
| | 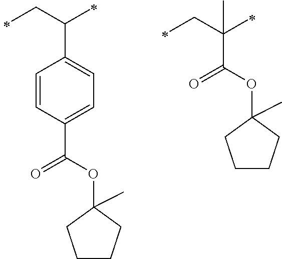 | | | |
| A-62 | 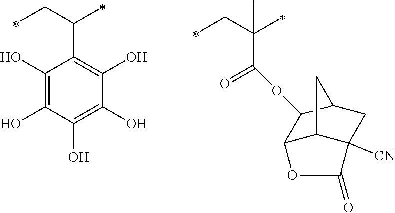 | 25/15/40/20 | 10,300 | 1.57 |
| | 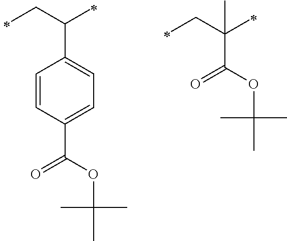 | | | |
| A-63 | 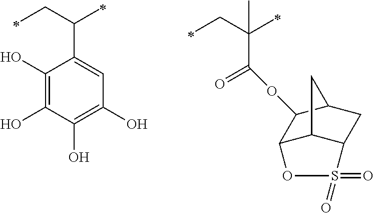 | 20/10/50/10 | 10,800 | 1.57 |
| | 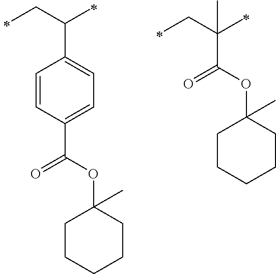 | | | |
| A-64 | 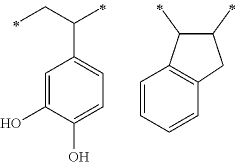 | 30/20/30/20 | 12,300 | 1.53 |
| | 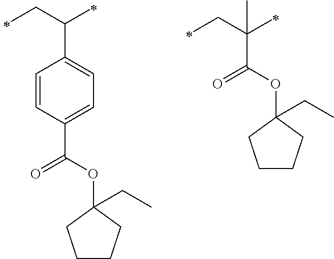 | | | |

TABLE 11

| | | Compositional ratio | | |
|---|---|---|---|---|
| | | (molar ratio) | | |
| Resin | Structure | from the left | Mw | Mw/Mn |
| A-65 | 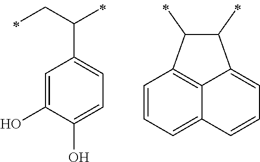 | 30/20/30/20 | 13,100 | 1.54 |
| | 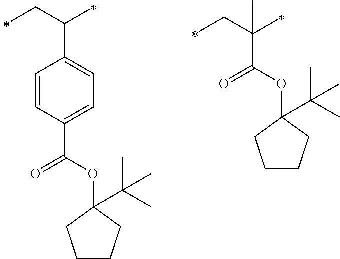 | | | |
| R-1 | 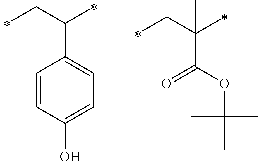 | 30/70 | 12,300 | 1.54 |
| R-2 | 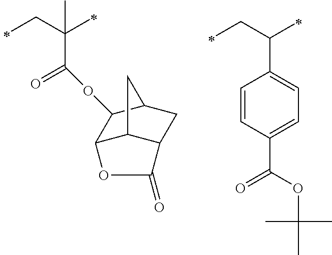 | 30/70 | 13,200 | 1.49 |

[Hydrophobic Resin (A′)]

As the hydrophobic resin, the following resins were used.

TABLE 12

| | Compositional ratio (molar ratio) | | | | Mw | Mw/Mn |
|---|---|---|---|---|---|---|
| Resin (1b) | 50 | 45 | 5 | — | 7,000 | 1.30 |
| Resin (2b) | 40 | 40 | 20 | — | 18,600 | 1.57 |
| Resin (3b) | 50 | 50 | — | — | 25,400 | 1.63 |
| Resin (4b) | 30 | 65 | 5 | — | 28,000 | 1.70 |
| Resin (5b) | 10 | 10 | 30 | 50 | 12,500 | 1.65 |

Specific structural formulae of the resins (1b) to (5b) described in Table 12 are shown below.

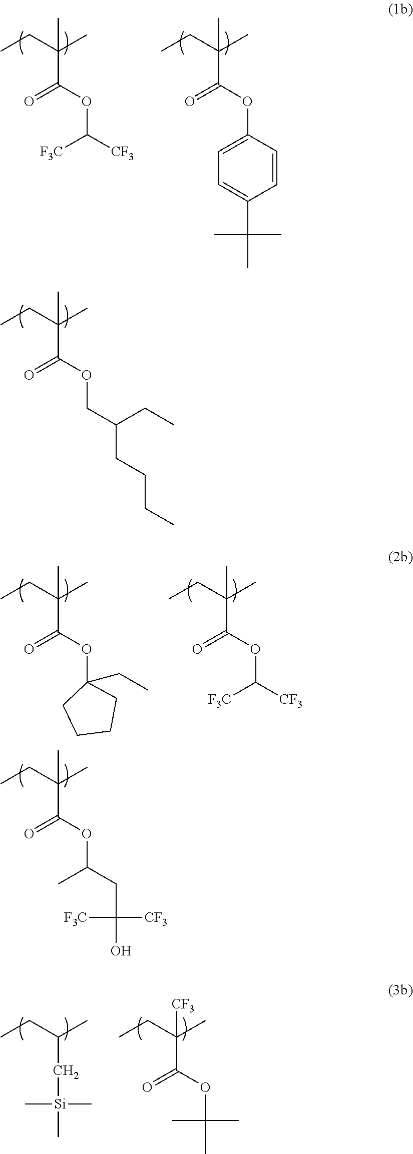

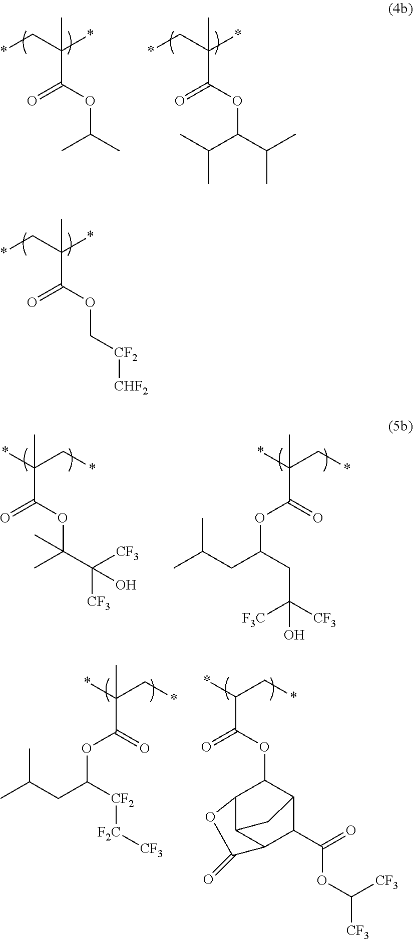

[Photoacid Generator (B)]

As the photoacid generator, the following compounds were used.

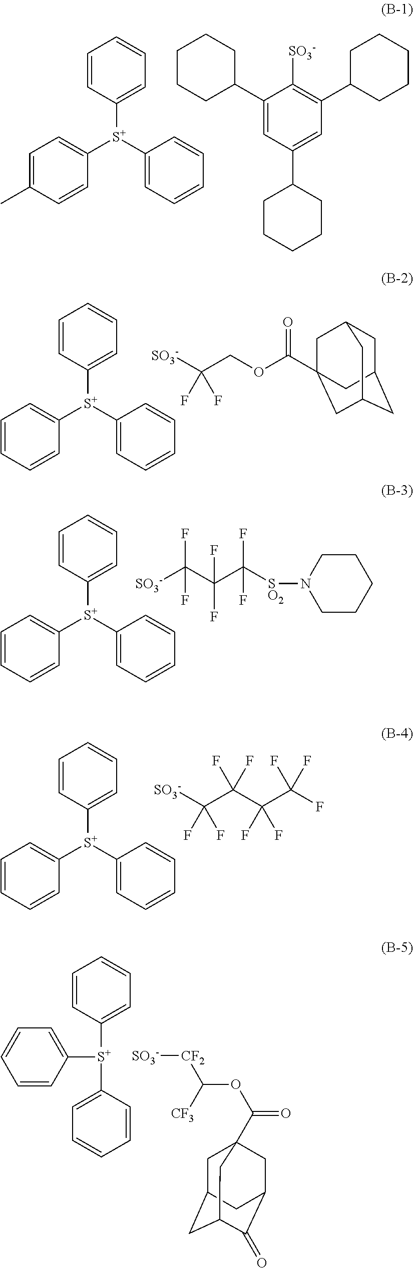

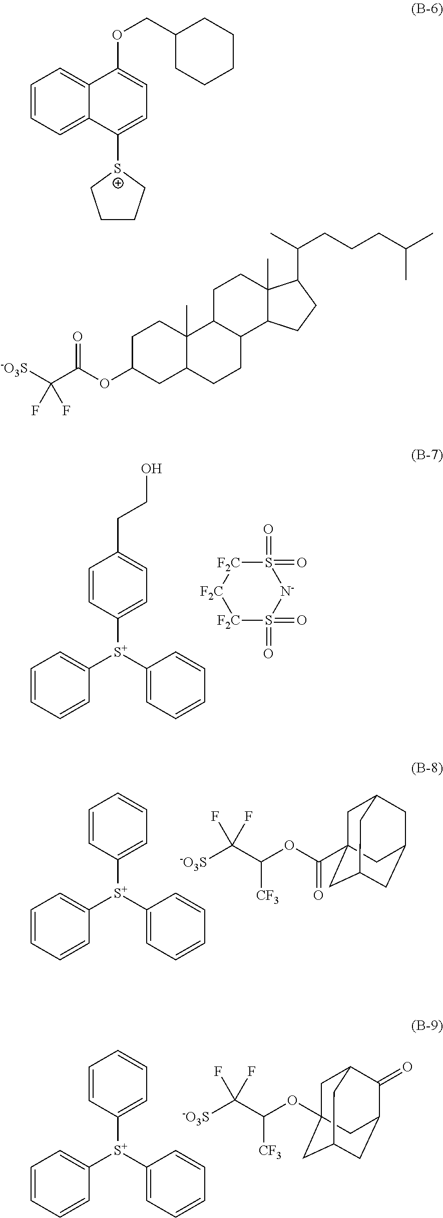

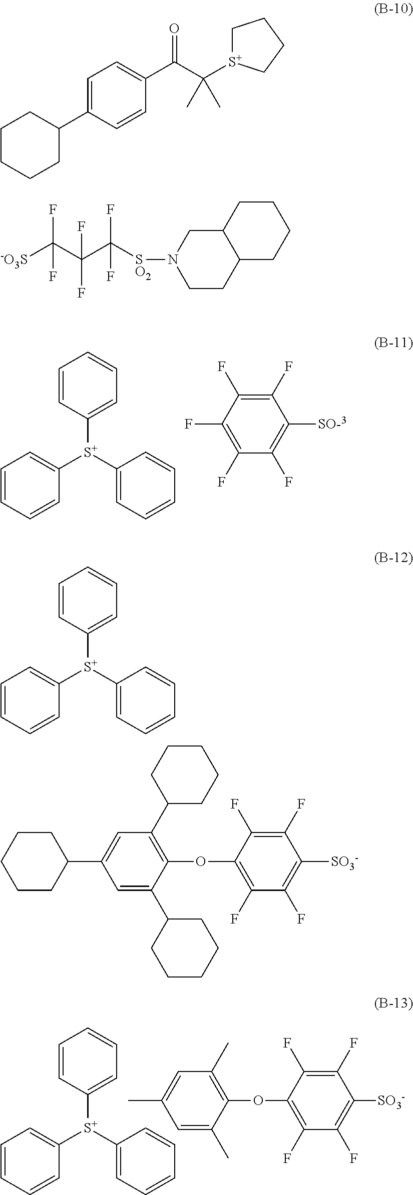

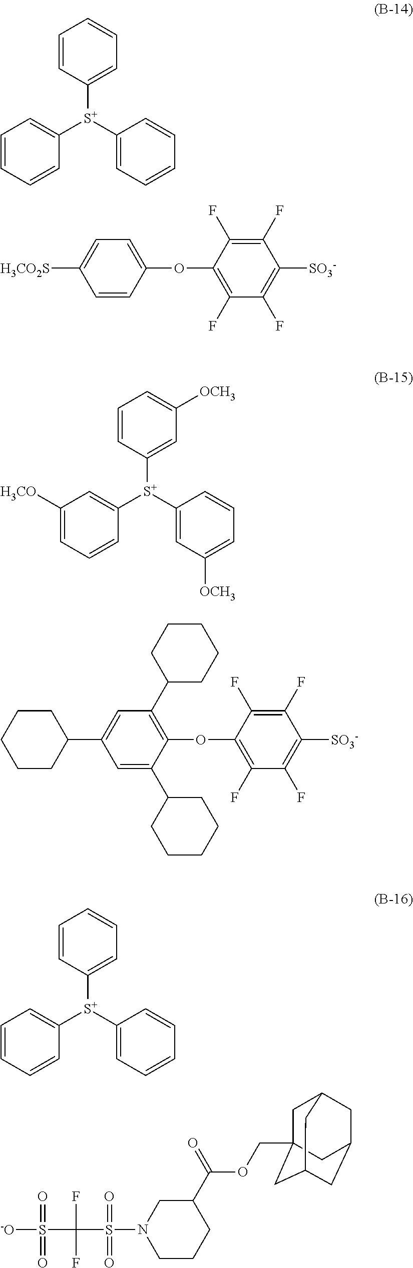

[Basic Compound (E)]

As the basic compound, the following compounds were used.

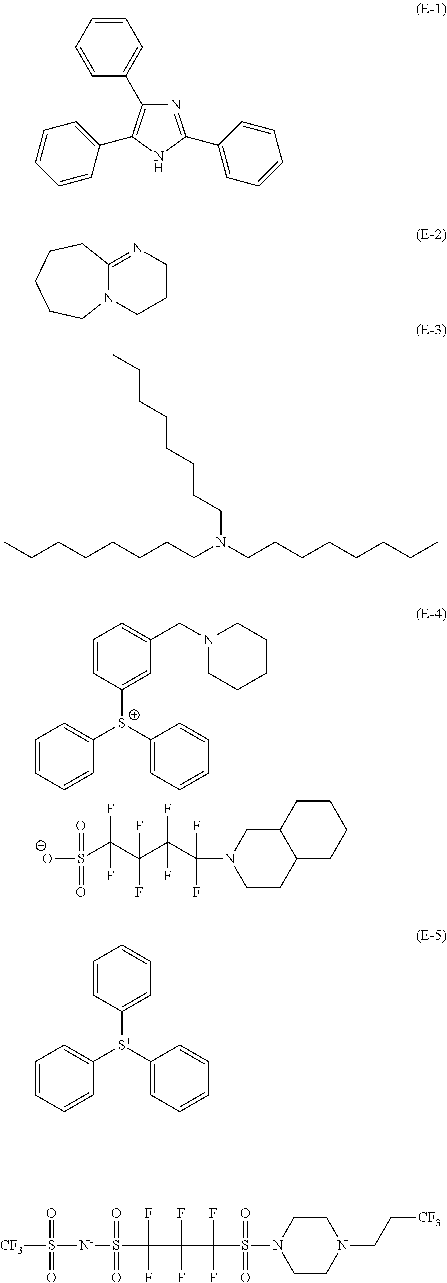

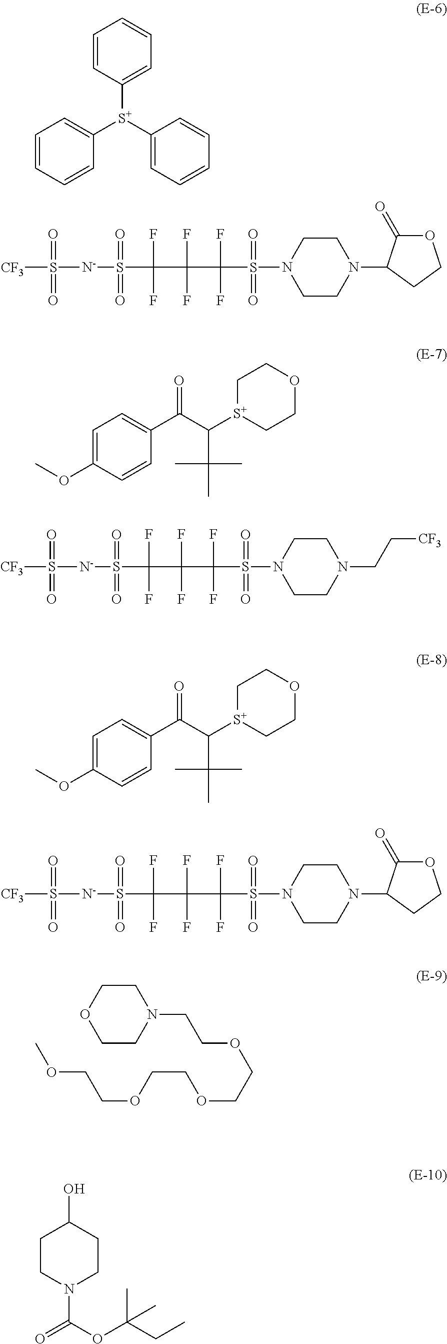

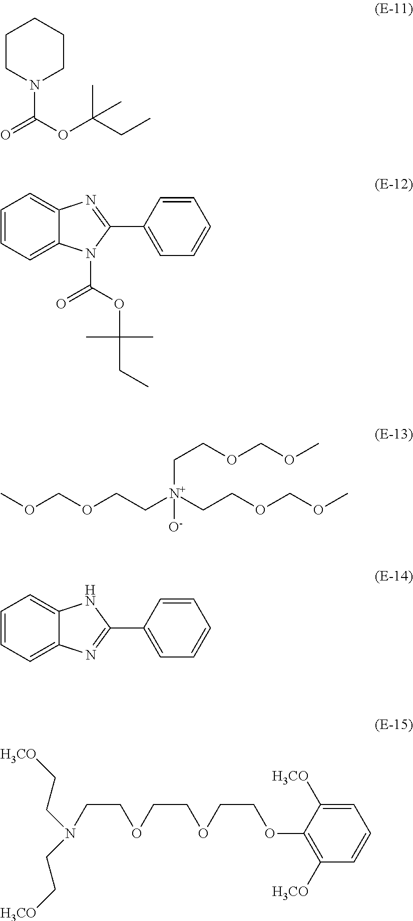

[Solvent (C)]

As the resist solvent, the following solvents were used.

C1: Propylene glycol monomethyl ether acetate

C2: Propylene glycol monomethyl ether

C3: Ethyl lactate

C4: Cyclohexanone

C5: Anisole

[Resist Composition]

The respective components shown in Tables 13 to 18 were dissolved in the solvents shown in the same tables. Each of these was filtered using a polyethylene filter having a pore size of 0.03 μm to obtain a resist composition.

TABLE 13

| Resist | | | | Hydro- | |
|---|---|---|---|---|---|
| compo- | | Photoacid | Basic | phobic | |
| sition | Resin | generator | compound | resin | Solvent |
| N1 | A-1 | B-2 | E-1 | Absent | C1/C3 |
| | 0.77 g | 0.2 g | 0.03 g | | 60 g/15 g |
| N2 | A-1 | B-2 | E-1 | 2b | C1/C3 |
| | 0.77 g | 0.2 g | 0.03 g | 0.01 g | 60 g/15 g |
| N3 | A-2 | B-2 | E-1 | Absent | C1/C3 |
| | 0.77 g | 0.2 g | 0.03 g | | 60 g/15 g |
| N4 | A-2 | B-1 | E-1 | Absent | C1/C3 |
| | 0.77 g | 0.2 g | 0.03 g | | 60 g/15 g |
| N5 | A-2 | B-1/B-2 | E-1 | Absent | C1/C3 |
| | 0.77 g | 0.1 g/0.1 g | 0.03 g | | 60 g/15 g |
| N6 | A-2 | B-8 | E-1 | Absent | C1/C3 |
| | 0.77 g | 0.2 g | 0.03 g | | 60 g/15 g |
| N7 | A-2 | B-2 | E-4 | Absent | C1/C3 |
| | 0.77 g | 0.2 g | 0.03 g | | 60 g/15 g |
| N8 | A-2 | B-2 | E-9 | Absent | C1/C3 |
| | 0.77 g | 0.2 g | 0.03 g | | 60 g/15 g |
| N9 | A-2 | B-5 | E-9 | Absent | C1/C3 |
| | 0.77 g | 0.2 g | 0.03 g | | 60 g/15 g |
| N10 | A-2/A-3 | B-2 | E-1 | Absent | C1/C3 |
| | 0.4 g/0.37 g | 0.2 g | 0.03 g | | 60 g/15 g |
| N11 | A-2 | B-2 | E-1 | 1b | C1/C2 |
| | 0.77 g | 0.2 g | 0.03 g | 0.01 g | 45 g/30 g |
| N12 | A-2 | B-2 | E-1/E-3 | Absent | C1/C2 |
| | 0.77 g | 0.2 g | 0.02 g/0.01 g | | 45 g/30 g |
| N13 | A-3 | B-2 | E-1 | Absent | C1/C3 |
| | 0.77 g | 0.2 g | 0.03 g | | 60 g/15 g |
| N14 | A-3 | B-2 | E-1 | Absent | C1/C4 |
| | 0.77 g | 0.2 g | 0.03 g | | 67.5 g/7.5 g |
| N15 | A-4 | B-2 | E-1 | Absent | C1/C3 |
| | 0.77 g | 0.2 g | 0.03 g | | 60 g/15 g |
| N16 | A-4 | B-4 | E-1 | Absent | C1/C3 |
| | 0.77 g | 0.2 g | 0.03 g | | 60 g/15 g |
| N17 | A-4 | B-8 | E-1 | Absent | C1/C3 |
| | 0.77 g | 0.2 g | 0.03 g | | 60 g/15 g |
| N18 | A-4 | B-8 | E-9 | Absent | C1/C2 |
| | 0.77 g | 0.2 g | 0.03 g | | 45 g/30 g |
| N19 | A-4 | B-8 | E-9 | Absent | C1/C3 |
| | 0.77 g | 0.2 g | 0.03 g | | 60 g/15 g |
| N20 | A-5 | B-2 | E-1 | Absent | C1/C3 |
| | 0.77 g | 0.2 g | 0.03 g | | 60 g/15 g |
| N21 | A-6 | B-2 | E-1 | Absent | C1/C3 |
| | 0.77 g | 0.2 g | 0.03 g | | 60 g/15 g |
| N22 | A-7 | B-2 | E-1 | Absent | C1/C3 |
| | 0.77 g | 0.2 g | 0.03 g | | 60 g/15 g |
| N23 | A-8 | B-2 | E-1 | Absent | C1/C3 |
| | 0.77 g | 0.2 g | 0.03 g | | 60 g/15 g |
| N24 | A-8 | B-5 | E-1 | Absent | C1/C3 |
| | 0.77 g | 0.2 g | 0.03 g | | 60 g/15 g |
| N25 | A-8 | B-9 | E-1 | Absent | C1/C3 |
| | 0.77 g | 0.2 g | 0.03 g | | 60 g/15 g |
| N26 | A-8 | B-9 | E-2 | Absent | C1/C3 |
| | 0.77 g | 0.2 g | 0.03 g | | 60 g/15 g |
| N27 | A-8 | B-9 | E-6 | Absent | C1/C3 |
| | 0.77 g | 0.2 g | 0.03 g | | 60 g/15 g |
| N28 | A-8 | B-2 | E-1 | 5b | C1/C3 |
| | 0.77 g | 0.2 g | 0.03 g | 0.03 g | 60 g/15 g |

TABLE 14

| Resist | | Photoacid | Basic | Hydrophobic | |
|---|---|---|---|---|---|
| composition | Resin | generator | compound | resin | Solvent |
| N29 | A-9 | B-2 | E-1 | Absent | C1/C3 |
| | 0.77 g | 0.2 g | 0.03 g | | 60 g/15 g |
| N30 | A-9 | B-2 | E-8 | Absent | C1/C4 |
| | 0.77 g | 0.2 g | 0.03 g | | 60 g/15 g |
| N31 | A-9 | B-2 | E-1 | 4b | C1/C3 |
| | 0.77 g | 0.2 g | 0.03 g | 0.003 g | 60 g/15 g |
| N32 | A-10 | B-2 | E-1 | Absent | C1/C3 |
| | 0.77 g | 0.2 g | 0.03 g | | 60 g/15 g |
| N33 | A-10 | B-7 | E-1 | Absent | C1/C3 |
| | 0.77 g | 0.2 g | 0.03 g | | 60 g/15 g |
| N34 | A-10 | B-2 | E-9 | Absent | C1/C3 |
| | 0.77 g | 0.2 g | 0.03 g | | 60 g/15 g |
| N35 | A-10 | B-5 | E-9 | Absent | C1/C3 |
| | 0.77 g | 0.2 g | 0.03 g | | 60 g/15 g |
| N36 | A-10 | B-2 | E-1 | 3b | C1/C3 |
| | 0.77 g | 0.2 g | 0.03 g | 0.005 g | 60 g/15 g |
| N37 | A-11 | B-2 | E-1 | Absent | C1/C3 |
| | 0.77 g | 0.2 g | 0.03 g | | 60 g/15 g |
| N38 | A-11 | B-2 | E-14 | Absent | C1/C3 |
| | 0.77 g | 0.2 g | 0.03 g | | 60 g/15 g |
| N39 | A-11 | B-2 | E-9 | Absent | C1/C3 |
| | 0.77 g | 0.2 g | 0.03 g | | 60 g/15 g |
| N40 | A-11 | B-5 | E-9 | Absent | C1/C3 |
| | 0.77 g | 0.2 g | 0.03 g | | 60 g/15 g |
| N41 | A-11 | B-1 | E-9 | Absent | C1/C3 |
| | 0.77 g | 0.2 g | 0.03 g | | 60 g/15 g |
| N42 | A-11 | B-1 | E-7 | Absent | C1/C3 |
| | 0.77 g | 0.2 g | 0.03 g | | 60 g/15 g |
| N43 | A-11 | B-2 | E-1 | 1b | C1/C3 |
| | 0.77 g | 0.2 g | 0.03 g | 0.01 g | 60 g/15 g |
| N44 | A-12 | B-2 | E-1 | Absent | C1/C3 |
| | 0.77 g | 0.2 g | 0.03 g | | 60 g/15 g |
| N45 | A-13 | B-2 | E-1 | Absent | C1/C3 |
| | 0.77 g | 0.2 g | 0.03 g | | 60 g/15 g |
| N46 | A-13 | B-10 | E-1 | Absent | C1/C3 |
| | 0.77 g | 0.2 g | 0.03 g | | 60 g/15 g |
| N47 | A-14 | B-2 | E-1 | Absent | C1/C3 |
| | 0.77 g | 0.2 g | 0.03 g | | 60 g/15 g |
| N48 | A-14 | B-2 | E-1 | Absent | C1/C2 |
| | 0.77 g | 0.2 g | 0.03 g | | 45 g/30 g |
| N49 | A-14 | B-2 | E-15 | Absent | C1/C2 |
| | 0.77 g | 0.2 g | 0.03 g | | 45 g/30 g |
| N50 | A-14 | B-11 | E-15 | Absent | C1/C2 |
| | 0.77 g | 0.2 g | 0.03 g | | 45 g/30 g |
| N51 | A-14 | B-2 | E-11 | Absent | C1/C2 |
| | 0.77 g | 0.2 g | 0.03 g | | 45 g/30 g |
| N52 | A-15 | B-2 | E-1 | Absent | C1/C3 |
| | 0.77 g | 0.2 g | 0.03 g | | 60 g/15 g |
| N53 | A-15 | B-11 | E-15 | Absent | C1/C2 |
| | 0.77 g | 0.2 g | 0.03 g | | 45 g/30 g |
| N54 | A-16 | B-2 | E-1 | Absent | C1/C3 |
| | 0.77 g | 0.2 g | 0.03 g | | 60 g/15 g |
| N55 | A-16 | B-2 | E-1 | Absent | C1/C2 |
| | 0.77 g | 0.2 g | 0.03 g | | 45 g/30 g |
| N56 | A-16 | B-3 | E-1 | Absent | C1/C2 |
| | 0.77 g | 0.2 g | 0.03 g | | 45 g/30 g |

TABLE 15

| Resist | | | | Hydro- | |
|---|---|---|---|---|---|
| compo- | | Photoacid | Basic | phobic | |
| sition | Resin | generator | compound | resin | Solvent |
| N57 | A-16 | B-3 | E-3 | Absent | C1/C2 |
| | 0.77 g | 0.2 g | 0.03 g | | 45 g/30 g |
| N58 | A-17 | B-2 | E-1 | Absent | C1/C3 |
| | 0.77 g | 0.2 g | 0.03 g | | 60 g/15 g |
| N59 | A-17 | B-2 | E-1 | Absent | C1/C4 |
| | 0.77 g | 0.2 g | 0.03 g | | 45 g/30 g |
| N60 | A-17 | B-2 | E-1 | Absent | C1/C2 |
| | 0.77 g | 0.2 g | 0.03 g | | 45 g/30 g |
| N61 | A-17 | B-2 | E-12 | Absent | C1/C4 |
| | 0.77 g | 0.2 g | 0.03 g | | 45 g/30 g |
| N62 | A-18 | B-2 | E-1 | Absent | C1/C3 |
| | 0.77 g | 0.2 g | 0.03 g | | 60 g/15 g |
| N63 | A-19 | B-2 | E-1 | Absent | C1/C3 |
| | 0.77 g | 0.2 g | 0.03 g | | 60 g/15 g |
| N64 | A-19 | B-6 | E-1 | Absent | C1/C2 |
| | 0.77 g | 0.2 g | 0.03 g | | 45 g/30 g |
| N65 | A-19 | B-2 | E-12 | Absent | C1/C2 |
| | 0.77 g | 0.2 g | 0.03 g | | 45 g/30 g |
| N66 | A-20 | B-2 | E-1 | Absent | C1/C3 |
| | 0.77 g | 0.2 g | 0.03 g | | 60 g/15 g |
| N67 | A-20 | B-4 | E-1 | Absent | C1/C3 |
| | 0.77 g | 0.2 g | 0.03 g | | 60 g/15 g |
| N68 | A-21 | B-2 | E-1 | Absent | C1/C3 |
| | 0.77 g | 0.2 g | 0.03 g | | 60 g/15 g |
| N69 | A-22 | B-2 | E-1 | Absent | C1/C3 |
| | 0.77 g | 0.2 g | 0.03 g | | 60 g/15 g |
| N70 | A-22 | B-1 | E-1 | Absent | C1/C3 |
| | 0.77 g | 0.2 g | 0.03 g | | 60 g/15 g |
| N71 | A-23 | B-2 | E-1 | Absent | C1/C3 |
| | 0.77 g | 0.2 g | 0.03 g | | 60 g/15 g |
| N72 | A-23 | B-1 | E-1 | Absent | C1/C3 |
| | 0.77 g | 0.2 g | 0.03 g | | 60 g/15 g |
| N73 | A-23 | B-1 | E-6 | Absent | C1/C3 |
| | 0.77 g | 0.2 g | 0.03 g | | 60 g/15 g |
| N74 | A-24 | B-2 | E-1 | Absent | C1/C3 |
| | 0.77 g | 0.2 g | 0.03 g | | 60 g/15 g |
| N75 | A-24 | B-1 | E-6 | Absent | C1/C3 |
| | 0.77 g | 0.2 g | 0.03 g | | 60 g/15 g |
| N76 | A-24 | B-1 | E-10 | Absent | C1/C3 |
| | 0.77 g | 0.2 g | 0.03 g | | 60 g/15 g |
| N77 | A-25 | B-2 | E-1 | Absent | C1/C3 |
| | 0.77 g | 0.2 g | 0.03 g | | 60 g/15 g |
| N78 | A-25 | B-2 | E-1 | 5b | C1/C3 |
| | 0.77 g | 0.2 g | 0.03 g | 0.03 g | 60 g/15 g |
| N79 | A-25 | B-2 | E-5 | Absent | C1/C3 |
| | 0.77 g | 0.2 g | 0.03 g | | 60 g/15 g |
| N80 | A-25 | B-3 | E-5 | Absent | C1/C3 |
| | 0.77 g | 0.2 g | 0.03 g | | 60 g/15 g |
| N81 | A-1/A-25 | B-2 | E-5 | Absent | C1/C3 |
| | 0.17 g/0.6 g | 0.2 g | 0.03 g | | 60 g/15 g |
| N82 | A-25 | B-2 | E-1/E-13 | Absent | C1/C3 |
| | 0.77 g | 0.2 g | 0.02 g/0.01 g | | 60 g/15 g |
| N83 | A-26 | B-2 | E-1 | Absent | C1/C3 |
| | 0.77 g | 0.2 g | 0.03 g | | 60 g/15 g |
| N84 | A-26 | B-6 | E-1 | Absent | C1/C2 |
| | 0.77 g | 0.2 g | 0.03 g | | 45 g/30 g |

TABLE 16

| Resist | | | | | |
|---|---|---|---|---|---|
| compo- | | Photoacid | Basic | Hydrophobic | |
| sition | Resin | generator | compound | resin | Solvent |
| N85 | A-26 | B-6 | E-3 | Absent | C1/C5 |
| | 0.77 g | 0.2 g | 0.03 g | | 60 g/15 g |
| N86 | A-27 | B-2 | E-1 | Absent | C1/C3 |
| | 0.77 g | 0.2 g | 0.03 g | | 60 g/15 g |
| N87 | A-27 | B-2 | E-14 | Absent | C1/C3 |
| | 0.77 g | 0.2 g | 0.03 g | | 60 g/15 g |
| N88 | A-27 | B-3 | E-14 | Absent | C1/C2 |
| | 0.77 g | 0.2 g | 0.03 g | | 45 g/30 g |
| N89 | A-28 | B-2 | E-1 | Absent | C1/C3 |
| | 0.77 g | 0.2 g | 0.03 g | | 60 g/15 g |
| N90 | A-29 | B-2 | E-1 | | C1/C3 |
| | 0.77 g | 0.2 g | 0.03 g | Absent | 60 g/15 g |
| N91 | A-29 | B-2 | E-6 | Absent | C1/C3 |
| | 0.77 g | 0.2 g | 0.03 g | | 60 g/15 g |
| N92 | A-30 | B-2 | E-1 | Absent | C1/C3 |
| | 0.77 g | 0.2 g | 0.03 g | | 60 g/15 g |
| N93 | A-31 | B-2 | E-1 | Absent | C1/C3 |
| | 0.77 g | 0.2 g | 0.03 g | | 60 g/15 g |
| N94 | A-31 | B-3 | E-1 | Absent | C1/C3 |
| | 0.77 g | 0.2 g | 0.03 g | | 60 g/15 g |
| N95 | A-32 | B-2 | E-1 | Absent | C1/C3 |
| | 0.77 g | 0.2 g | 0.03 g | | 60 g/15 g |
| N96 | A-32 | B-9 | E-1 | Absent | C1/C2 |
| | 0.77 g | 0.2 g | 0.03 g | | 45 g/30 g |
| N97 | A-33 | B-2 | E-1 | Absent | C1/C3 |
| | 0.77 g | 0.2 g | 0.03 g | | 60 g/15 g |
| N98 | A-33 | B-8 | E-1 | Absent | C1/C3 |
| | 0.77 g | 0.2 g | 0.03 g | | 60 g/15 g |
| N99 | A-34 | B-2 | E-1 | Absent | C1/C3 |
| | 0.77 g | 0.2 g | 0.03 g | | 60 g/15 g |
| N100 | A-35 | B-2 | E-1 | | C1/C3 |
| | 0.77 g | 0.2 g | 0.03 g | Absent | 60 g/15 g |
| N101 | A-36 | B-2 | E-1 | Absent | C1/C3 |
| | 0.77 g | 0.2 g | 0.03 g | | 60 g/15 g |
| N102 | A-37 | B-2 | E-1 | Absent | C1/C2 |
| | 0.77 g | 0.2 g | 0.03 g | | 60 g/15 g |
| N103 | A-37 | B-11 | E-1 | Absent | C1/C2 |
| | 0.77 g | 0.2 g | 0.03 g | | 60 g/15 g |
| N104 | A-37 | B-11 | E-1 | 1b | C1/C2 |
| | 0.77 g | 0.2 g | 0.03 g | 0.01 g | 60 g/15 g |
| N1041 | A-37 | B-12 | E-1 | Absent | C1/C2 |
| | 0.77 g | 0.2 g | 0.03 g | | 60 g/15 g |
| N1042 | A-37 | B-13 | E-1 | Absent | C1/C2 |
| | 0.77 g | 0.2 g | 0.03 g | | 60 g/15 g |
| N1043 | A-37 | B-14 | E-1 | Absent | C1/C2 |
| | 0.77 g | 0.2 g | 0.03 g | | 60 g/15 g |
| N1044 | A-37 | B-14 | E-4 | Absent | C1/C2 |
| | 0.77 g | 0.2 g | 0.03 g | | 60 g/15 g |
| N1045 | A-37 | B-15 | E-1 | Absent | C1/C2 |
| | 0.77 g | 0.2 g | 0.03 g | | 60 g/15 g |
| N1046 | A-37 | B-16 | E-1 | Absent | C1/C2 |
| | 0.77 g | 0.2 g | 0.03 g | | 60 g/15 g |
| N105 | A-37 | B-11 | E-4 | Absent | C1/C2 |
| | 0.77 g | 0.2 g | 0.03 g | | 60 g/15 g |
| N106 | A-1/A-37 | B-2 | E-1 | Absent | C1/C3 |
| | 0.17 g/0.6 g | 0.2 g | 0.03 g | | 60 g/15 g |

TABLE 17

| Resist | | Photoacid | Basic | Hydrophobic | |
|---|---|---|---|---|---|
| composition | Resin | generator | compound | resin | Solvent |
| N107 | A-38 | B-2 | E-1 | Absent | C1/C2 |
| | 0.77 g | 0.2 g | 0.03 g | | 60 g/15 g |
| N108 | A-38 | B-11 | E-1 | Absent | C1/C2 |
| | 0.77 g | 0.2 g | 0.03 g | | 60 g/15 g |
| N1081 | A-38 | B-12 | E-1 | Absent | C1/C2 |
| | 0.77 g | 0.2 g | 0.03 g | | 60 g/15 g |
| N109 | A-39 | B-2 | E-1 | Absent | C1/C2 |
| | 0.77 g | 0.2 g | 0.03 g | | 60 g/15 g |
| N1091 | A-38 | B-2 | E-1 | Absent | C1/C2 |
| | 0.84 g | 0.13 g | 0.03 g | | 60 g/15 g |
| N110 | A-40 | B-2 | E-1 | Absent | C1/C2 |
| | 0.77 g | 0.2 g | 0.03 g | | 60 g/15 g |
| N111 | A-41 | B-2 | E-1 | Absent | C1/C2 |
| | 0.77 g | 0.2 g | 0.03 g | | 60 g/15 g |
| N112 | A-41 | B-11 | E-1 | Absent | C1/C2 |
| | 0.77 g | 0.2 g | 0.03 g | | 60 g/15 g |
| N1121 | A-41 | B-13 | E-1 | Absent | C1/C2 |
| | 0.77 g | 0.2 g | 0.03 g | | 60 g/15 g |
| N113 | A-42 | B-2 | E-1 | Absent | C1/C2 |
| | 0.77 g | 0.2 g | 0.03 g | | 60 g/15 g |
| N114 | A-43 | B-2 | E-1 | Absent | C1/C2 |
| | 0.77 g | 0.2 g | 0.03 g | | 60 g/15 g |
| N115 | A-44 | B-2 | E-1 | Absent | C1/C2 |
| | 0.77 g | 0.2 g | 0.03 g | | 60 g/15 g |
| N116 | A-45 | B-2 | E-1 | Absent | C1/C2 |
| | 0.77 g | 0.2 g | 0.03 g | | 60 g/15 g |
| N117 | A-45 | B-2 | E-3 | Absent | C1/C2 |
| | 0.77 g | 0.2 g | 0.03 g | | 60 g/15 g |
| N118 | A-46 | B-2 | E-1 | Absent | C1/C2 |
| | 0.77 g | 0.2 g | 0.03 g | | 60 g/15 g |
| N119 | A-47 | B-2 | E-1 | Absent | C1/C2 |
| | 0.77 g | 0.2 g | 0.03 g | | 60 g/15 g |
| N120 | A-47 | B-1 | E-1 | Absent | C1/C2 |
| | 0.77 g | 0.2 g | 0.03 g | | 60 g/15 g |
| N121 | A-47 | B-11 | E-1 | Absent | C1/C2 |
| | 0.77 g | 0.2 g | 0.03 g | | 60 g/15 g |
| N1211 | A-47 | B-14 | E-1 | Absent | C1/C2 |
| | 0.77 g | 0.2 g | 0.03 g | | 60 g/15 g |
| N1212 | A-47 | B-14 | E-6 | Absent | C1/C2 |
| | 0.77 g | 0.2 g | 0.03 g | | 60 g/15 g |
| N122 | A-48 | B-2 | E-1 | Absent | C1/C2 |
| | 0.77 g | 0.2 g | 0.03 g | | 60 g/15 g |
| N123 | A-48 | B-3 | E-1 | Absent | C1/C2 |
| | 0.77 g | 0.2 g | 0.03 g | | 60 g/15 g |
| N124 | A-49 | B-2 | E-1 | Absent | C1/C2 |
| | 0.77 g | 0.2 g | 0.03 g | | 60 g/15 g |
| N125 | A-50 | B-2 | E-1 | Absent | C1/C2 |
| | 0.77 g | 0.2 g | 0.03 g | | 60 g/15 g |
| N126 | A-50 | B-11 | E-1 | Absent | C1/C2 |
| | 0.77 g | 0.2 g | 0.03 g | | 60 g/15 g |
| N1261 | A-50 | B-15 | E-1 | Absent | C1/C2 |
| | 0.77 g | 0.2 g | 0.03 g | | 60 g/15 g |
| N127 | A-50 | B-2 | E-6 | Absent | C1/C2 |
| | 0.77 g | 0.2 g | 0.03 g | | 60 g/15 g |
| N128 | A-51 | B-2 | E-1 | Absent | C1/C2 |
| | 0.77 g | 0.2 g | 0.03 g | | 60 g/15 g |

TABLE 18

| | | | | Hydro- | |
|---|---|---|---|---|---|
| Resist | | Photoacid | Basic | phobic | |
| composition | Resin | generator | compound | resin | Solvent |
| N129 | A-51 | B-1 | E-1 | Absent | C1/C2 |
| | 0.77 g | 0.2 g | 0.03 g | | 60 g/15 g |
| N130 | A-52 | B-2 | E-1 | Absent | C1/C2 |
| | 0.77 g | 0.2 g | 0.03 g | | 60 g/15 g |
| N131 | A-53 | B-2 | E-1 | Absent | C1/C2 |
| | 0.77 g | 0.2 g | 0.03 g | | 60 g/15 g |
| N132 | A-54 | B-2 | E-1 | Absent | C1/C2 |
| | 0.77 g | 0.2 g | 0.03 g | | 60 g/15 g |
| N133 | A-54 | B-1/B-2 | E-1 | Absent | C1/C2 |
| | 0.77 g | 0.1 g/0.1 g | 0.03 g | | 60 g/15 g |
| N134 | A-55 | B-2 | E-1 | Absent | C1/C2 |
| | 0.77 g | 0.2 g | 0.03 g | | 60 g/15 g |
| N135 | A-56 | B-2 | E-1 | Absent | C1/C2 |
| | 0.77 g | 0.2 g | 0.03 g | | 60 g/15 g |
| N136 | A-56 | B-2 | E-5 | Absent | C1/C2 |
| | 0.77 g | 0.2 g | 0.03 g | | 60 g/15 g |
| N137 | A-56 | B-2 | E-9 | Absent | C1/C2 |
| | 0.77 g | 0.2 g | 0.03 g | | 60 g/15 g |
| N138 | A-57 | B-2 | E-1 | Absent | C1/C2 |
| | 0.77 g | 0.2 g | 0.03 g | | 60 g/15 g |
| N139 | A-58 | B-2 | E-1 | Absent | C1/C2 |
| | 0.77 g | 0.2 g | 0.03 g | | 60 g/15 g |
| N140 | A-59 | B-2 | E-1 | Absent | C1/C2 |
| | 0.77 g | 0.2 g | 0.03 g | | 60 g/15 g |
| N141 | A-60 | B-2 | E-1 | Absent | C1/C2 |
| | 0.77 g | 0.2 g | 0.03 g | | 60 g/15 g |
| N142 | A-60 | B-11 | E-1 | Absent | C1/C2 |
| | 0.77 g | 0.2 g | 0.03 g | | 60 g/15 g |
| N1421 | A-60 | B-16 | E-1 | Absent | C1/C2 |
| | 0.77 g | 0.2 g | 0.03 g | | 60 g/15 g |
| N1422 | A-60 | B-12/B-16 | E-1 | Absent | C1/C2 |
| | 0.77 g | 0.1 g/0.1 g | 0.03 g | | 60 g/15 g |
| N143 | A-60 | B-1 | E-1 | Absent | C1/C2 |
| | 0.77 g | 0.2 g | 0.03 g | | 60 g/15 g |
| N144 | A-61 | B-2 | E-1 | Absent | C1/C2 |
| | 0.77 g | 0.2 g | 0.03 g | | 60 g/15 g |
| N145 | A-62 | B-2 | E-1 | Absent | C1/C2 |
| | 0.77 g | 0.2 g | 0.03 g | | 60 g/15 g |
| N146 | A-63 | B-2 | E-1 | Absent | C1/C2 |
| | 0.77 g | 0.2 g | 0.03 g | | 60 g/15 g |
| N147 | A-64 | B-2 | E-1 | Absent | C1/C2 |
| | 0.77 g | 0.2 g | 0.03 g | | 60 g/15 g |
| N148 | A-65 | B-2 | E-1 | Absent | C1/C2 |
| | 0.77 g | 0.2 g | 0.03 g | | 60 g/15 g |
| N149 | A-65 | B-2 | E-1/E-9 | Absent | C1/C2 |
| | 0.77 g | 0.2 g | 0.02 g/0.01 g | | 60 g/15 g |
| NR1 | R-1 | B-2 | E-1 | Absent | C1/C3 |
| | 0.77 g | 0.2 g | 0.03 g | | 60 g/15 g |
| NR2 | R-2 | B-2 | E-1 | Absent | C1/C3 |
| | 0.77 g | 0.2 g | 0.03 g | | 60 g/15 g |

[Upper Layer Film-Forming Composition]

The respective components shown in the following Table 19 were dissolved in the solvents shown in the same table. Each of these was filtered using a polyethylene filter having a pore size of 0.03 μm to obtain an upper layer film-forming composition. In the following table, “MIBC” represents methyl isobutyl carbinol.

TABLE 19

| Upper layer | | | | Solvent |
|---|---|---|---|---|
| film-forming | | Photoacid | | (mixing ratio (mass |
| composition | Resin | generator | Additive | ratio)) |
| T-1 | V-1 | — | — | MIBC/Decane |
| | 1.0 g | — | — | 30/70 |
| T-2 | V-1 | B-2 | — | MIBC/Decane |
| | 1.0 g | 0.02 g | — | 50/50 |
| T-3 | V-1 | — | E-11 | MIBC/Decane |
| | 1.0 g | — | 0.02 g | 30/70 |
| T-4 | V-1 | — | X1 | MIBC/Decane |
| | 1.0 g | — | 0.02 g | 30/70 |
| T-5 | V-1 | B-2 | X1 | MIBC/Decane |
| | 1.0 g | 0.02 g | 0.02 g | 30/70 |
| T-6 | V-2 | — | — | MIBC/Decane |
| | 1.0 g | — | — | 30/70 |
| T-7 | V-3 | — | — | MIBC/Decane |
| | 1.0 g | — | — | 30/70 |
| T-8 | V-4 | — | — | MIBC/Decane |
| | 1.0 g | — | — | 30/70 |
| T-9 | V-1:1b | — | — | MIBC/Undecane |
| | 0.9 g:0.1 g | — | — | 20/80 |

Resins V-1 to V-4 and 1b, and additive X1, which were used to obtain the upper layer film-forming composition, are shown below. Additives other than these are the same as those described above.

The compositional ratio, weight-average molecular weight and dispersity of the resins V-1 to V-4 and 1b are shown in the following Table 20.

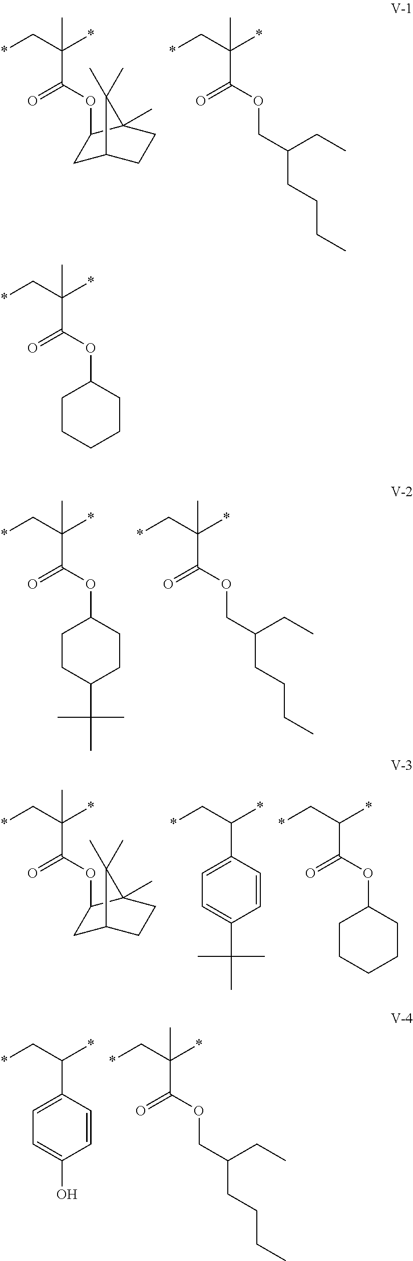

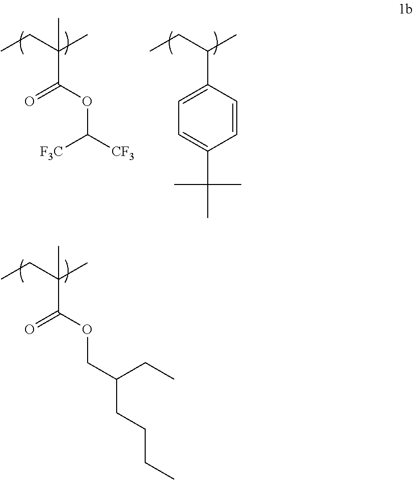

TABLE 20

| Upper layer | | | |
|---|---|---|---|
| film-forming | Compositional ratio | Weight-average | |
| composition | (molar ratio) | molecular weight | Dispersity |
| V-1 | 40/40/20 | 11,000 | 1.45 |
| V-2 | 60/40 | 9,500 | 1.59 |
| V-3 | 40/40/20 | 9,300 | 1.67 |
| V-4 | 30/70 | 12,000 | 1.33 |
| 1b | 40/50/10 | 11,000 | 1.45 |

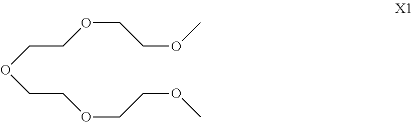

[Evaluation of EUV Exposure]

Using each of the resist compositions described in Tables 13 to 18, a resist pattern was formed by the following operation.

[Coating and Post Baking (PB) of Resist Composition]

DUV44 (manufactured by Brewer Science, Inc.) as an organic film-forming composition was coated on a 12-inch silicon wafer and baked at 200° C. for 60 seconds to form an organic film having a film thickness of 60 nm. Each resist composition was coated on the formed organic film and baked at a condition of 120° C. for 60 seconds to form a resist film having a film thickness of 40 nm.

[Coating and Post Coating Bake (PB) of Upper Layer Film-Forming Composition]

In Examples 13 to 21, each of the upper layer film-forming compositions (topcoat compositions) shown in Table 19 was coated on the resist film after baking, and then baked at a PB temperature (unit: ° C.), which is described in Tables 23 to 27, for 60 seconds to form an upper layer film (top coat) having a film thickness of 40 nm.

[Exposure]

<L/S Pattern Evaluation>

EUV exposure was carried out on the wafer prepared above with Numerical Aperture (NA) of 0.25 and dipole illumination (Dipole 60x, outer sigma 0.81, inner sigma 0.43). Specifically, EUV exposure was carried out by changing the exposure dose through a mask including a pattern for forming a line-and-space pattern (L/S pattern) with a pitch of 40 nm and a width of 20 nm on the wafer.

[Post Exposure Bake (PEB)]

After irradiation, once removed from the EUV exposure device, the wafer was immediately baked (PEB) at a temperature described in Tables 23 to 27 for 60 seconds.

[Development]

Thereafter, using a shower type developing device (ADE 3000S, manufactured by ACTES Co., Ltd.), development was carried out by spray-ejecting the developer (23° C.) at a flow rate of 200 mL/min for 30 seconds while rotating the wafer at 50 revolutions (rpm). As the developer, a developer shown in Table 21 was used. Tables 23 to 27 show the developers used in the respective examples altogether.

TABLE 21

| | | Compositional ratio |
|---|---|---|
| Developer | Solvent name | [% by mass] |
| SG1 | Butyl acetate | 100 |
| SG2 | Isoamyl acetate | 100 |
| SG3 | Isobutyl isobutanoate | 100 |
| SG4 | Diisobutyl ketone | 100 |
| SG5 | Diisobutyl ketone/Undecane | 90/10 |
| SG6 | Diisobutyl ketone/Decane | 90/10 |

[Rinsing]

Thereafter, a rinsing treatment was carried out by spray-ejecting a rinsing liquid (23° C.) at a flow rate of 200 mL/min for 15 seconds while rotating the wafer at 50 revolutions (rpm)

Finally, the wafer was dried by high-speed spinning at 2,500 revolutions (rpm) for 60 seconds. As the rinsing liquid, a rinsing liquid described in Table 22 was used. Tables 23 to 27 show the rinsing liquids used in the respective examples altogether.

TABLE 22

| Rinsing | | Compositional ratio |
|---|---|---|
| liquid | Solvent name | [% by mass] |
| SR1 | Undecane | 100 |
| SR2 | Decane | 100 |
| SR3 | Diisobutyl ketone | 100 |
| SR4 | Diisobutyl ketone/Undecane | 90/10 |
| SR5 | Diisobutyl ketone/Undecane | 80/20 |
| SR6 | Diisobutyl ketone/Undecane | 70/30 |
| SR7 | Diisobutyl ketone/Decane | 90/10 |
| SR8 | Diisobutyl ketone/Decane | 80/20 |
| SR9 | Diisobutyl ketone/Decane | 70/30 |
| SR10 | Diisoamyl ether | 100 |
| SR11 | Diisoamyl ether/Decane | 90/10 |
| SR12 | Diisoamyl ether/Diisobutyl ketone | 70/30 |
| SR13 | Diisobutyl ether/Decane | 90/10 |
| SR14 | Isoamyl acetate | 100 |

[Evaluation Test]

The following items were evaluated. Details of the results are shown in Tables 23 to 27 below.

<Resolution (Pattern Collapse Performance)>

Resolution states of the line-and-space patterns obtained by exposure with different exposure doses were observed with a scanning electron microscope (S-9380II, manufactured by Hitachi, Ltd.) at a magnification of 200 k, and the minimum line width (unit: nm) where a pattern collapse within an observed one field did not occur was calculated and used as an indicator of pattern collapse. As this numerical value is smaller, better pattern collapse performance is exhibited (that is, occurrence of pattern collapse is suppressed).

<Etching Resistance>

An initial film thickness (FT1 (unit: Å)) of the resist film prepared by substantially the same method as described above was measured. Next, etching was carried out for 20 seconds while supplying CF₄ gas using a dry etcher (U-621, manufactured by Hitachi High-Technologies Corporation). Thereafter, the film thickness (FT2 (unit: Å)) of the resist film obtained after etching was measured. Then, a dry etching rate (DE (unit: Å/sec)) defined by the following equation was calculated.

[DE(Å/sec)]=(FT1−FT2)/20

Superiority/inferiority of DE was evaluated according to the following criteria. As the value of DE is smaller, smaller film thickness change with etching (that is, excellent etching resistance) is exhibited. For practical use, “A” or “B” is preferable.

“A” . . . dry etching rate of less than 20 Å/sec

“B” . . . dry etching rate of equal to or more than 20 Å/sec and less than 25 Å/sec

“C” . . . dry etching rate of 25 Å/sec or more

<Outgassing Performance>

The amount of volatile outgas under vacuum exposure was quantified as a film thickness reduction rate.

More specifically, the film was exposed at 2.0 times the irradiation dose used at the time of forming the pattern, and a film thickness after exposure and before PEB was measured with an optical interference film thickness measurement meter (VM-8200, manufactured by Dainippon Screen Co., Ltd.). Then, a variation rate was obtained using the following equation from the film thickness at the time of not being exposed. As a value of the variation rate is smaller, a smaller amount of outgas is exhibited, which means good performance. For practical use, “A”, “B”, or “C” is preferable, and “A” or “B” is more preferable.

Film thickness variation rate (%)=[(film thickness at the time of non-exposure−film thickness after exposure)/film thickness at the time of non-exposure]×100

“A” . . . film thickness variation rate of less than 5%

“B” . . . film thickness variation rate of equal to or more than 5% and less than 10%

“C” . . . film thickness variation rate of equal to or more than 10% and less than 15%

“D” . . . film thickness variation rate of 15% or more

TABLE 23
(Evaluation of EUV Exposure)

| | | | | | Upper layer | | | | |
|---|---|---|---|---|---|---|---|---|---|
| | | | Rinsing | Upper | film PB | PEB | Resolution | Etching | Outgassing |
| | Composition | Developer | liquid | layer film | [° C.] | [° C.] | [nm] | resistance | performance |
| Example 1 | N1 | SG2 | SR1 | — | — | 90 | 14.4 | A | A |
| Example 2 | N1 | SG3 | SR1 | — | — | 90 | 14.0 | A | A |
| Example 3 | N1 | SG5 | SR1 | — | — | 90 | 13.9 | A | A |
| Example 4 | N2 | SG5 | SR1 | — | — | 90 | 13.6 | A | A |
| Example 5 | N3 | SG4 | SR1 | — | — | 90 | 13.3 | A | A |
| Example 6 | N3 | SG4 | SR2 | — | — | 90 | 13.5 | A | A |
| Example 7 | N3 | SG4 | SR5 | — | — | 90 | 13.7 | A | A |
| Example 8 | N3 | SG4 | SR6 | — | — | 90 | 13.9 | A | A |
| Example 9 | N3 | SG5 | SR2 | — | — | 90 | 13.7 | A | A |
| Example 10 | N3 | SG4 | SR8 | — | — | 90 | 13.9 | A | A |
| Example 11 | N3 | SG4 | SR11 | — | — | 90 | 13.8 | A | A |
| Example 12 | N3 | SG2 | SR1 | — | — | 90 | 14.6 | A | A |
| Example 13 | N3 | SG4 | SR6 | T-1 | 90 | 90 | 14.4 | A | A |
| Example 14 | N3 | SG4 | SR6 | T-2 | 120 | 90 | 13.2 | A | A |
| Example 15 | N3 | SG4 | SR6 | T-3 | 90 | 90 | 14.3 | A | A |
| Example 16 | N3 | SG4 | SR6 | T-4 | 120 | 90 | 13.3 | A | A |
| Example 17 | N3 | SG4 | SR6 | T-5 | 120 | 90 | 14.0 | A | A |
| Example 18 | N3 | SG4 | SR6 | T-6 | 90 | 90 | 13.8 | A | A |
| Example 19 | N3 | SG4 | SR6 | T-7 | 120 | 90 | 14.3 | A | A |
| Example 20 | N3 | SG4 | SR6 | T-8 | 90 | 90 | 13.9 | A | A |
| Example 21 | N3 | SG4 | SR6 | T-9 | 90 | 90 | 14.0 | A | A |
| Example 22 | N3 | SG4 | Absent | — | — | 90 | 15.8 | A | A |
| Example 23 | N4 | SG4 | SR1 | — | — | 90 | 13.8 | A | A |
| Example 24 | N4 | SG4 | SR4 | — | — | 90 | 13.7 | A | A |
| Example 25 | N5 | SG4 | SR1 | — | — | 90 | 13.9 | A | A |
| Example 26 | N6 | SG4 | SR1 | — | — | 90 | 13.8 | A | A |
| Example 27 | N6 | SG3 | SR1 | — | — | 90 | 14.0 | A | A |
| Example 28 | N7 | SG4 | SR1 | — | — | 90 | 13.9 | A | A |
| Example 29 | N8 | SG4 | SR1 | — | — | 90 | 13.8 | A | A |
| Example 30 | N9 | SG4 | SR1 | — | — | 90 | 14.1 | A | A |
| Example 31 | N10 | SG4 | SR1 | — | — | 90 | 14.7 | B | A |
| Example 32 | N11 | SG4 | SR1 | — | — | 90 | 13.2 | A | A |
| Example 33 | N12 | SG4 | SR1 | — | — | 90 | 13.4 | A | A |
| Example 34 | N12 | SG4 | SR2 | — | — | 90 | 13.5 | A | A |
| Example 35 | N13 | SG1 | SR1 | — | — | 90 | 17.9 | B | A |
| Example 36 | N13 | SG2 | SR1 | — | — | 90 | 16.8 | B | A |
| Example 37 | N13 | SG2 | SR4 | — | — | 90 | 16.5 | B | A |
| Example 38 | N13 | SG4 | SR4 | — | — | 90 | 16.2 | B | A |
| Example 39 | N14 | SG2 | SR1 | — | — | 90 | 17.1 | B | A |
| Example 40 | N15 | SG2 | SR1 | — | — | 110 | 15.5 | A | A |
| Example 41 | N15 | SG4 | SR1 | — | — | 110 | 15.2 | A | A |
| Example 42 | N15 | SG4 | SR2 | — | — | 110 | 15.2 | A | A |
| Example 43 | N15 | SG4 | SR4 | — | — | 110 | 15.0 | A | A |
| Example 44 | N16 | SG4 | SR4 | — | — | 110 | 14.9 | A | A |
| Example 45 | N16 | SG4 | SR13 | — | — | 110 | 14.9 | A | A |
| Example 46 | N17 | SG4 | SR4 | — | — | 110 | 15.2 | A | A |
| Example 47 | N18 | SG4 | SR7 | — | — | 110 | 15.4 | A | A |
| Example 48 | N19 | SG4 | SR4 | — | — | 110 | 15.1 | A | A |
| Example 49 | N20 | SG4 | SR1 | — | — | 110 | 18.1 | A | A |
| Example 50 | N20 | SG4 | SR2 | — | — | 110 | 18.3 | A | A |
| Example 51 | N21 | SG4 | SR1 | — | — | 110 | 14.9 | A | A |
| Example 52 | N22 | SG4 | SR1 | — | — | 110 | 15.0 | A | A |
| Example 53 | N23 | SG4 | SR1 | — | — | 85 | 13.3 | A | A |
| Example 54 | N23 | SG4 | SR2 | — | — | 85 | 13.5 | A | A |
| Example 55 | N23 | SG4 | SR5 | — | — | 85 | 13.7 | A | A |

TABLE 24
(Evaluation of EUV Exposure)

| | | | | Upper | Upper layer | | | | |
|---|---|---|---|---|---|---|---|---|---|
| | | | Rinsing | layer | film PB | PEB | Resolution | Etching | Outgassing |
| | Composition | Developer | liquid | film | [° C.] | [° C.] | [nm] | resistance | performance |
| Example 56 | N24 | SG4 | SR1 | — | — | 85 | 13.6 | A | A |
| Example 57 | N25 | SG4 | SR1 | — | — | 85 | 13.9 | A | A |
| Example 58 | N26 | SG4 | SR1 | — | — | 85 | 13.5 | A | A |
| Example 59 | N27 | SG4 | SR1 | — | — | 85 | 13.8 | A | A |
| Example 60 | N28 | SG4 | SR1 | — | — | 85 | 13.2 | A | A |
| Example 61 | N29 | SG4 | SR1 | — | — | 90 | 13.7 | A | A |
| Example 62 | N30 | SG4 | SR1 | — | — | 90 | 13.8 | A | A |
| Example 63 | N31 | SG4 | SR1 | — | — | 90 | 13.5 | A | A |
| Example 64 | N32 | SG4 | SR1 | — | — | 90 | 13.5 | A | A |
| Example 65 | N33 | SG4 | SR1 | — | — | 90 | 13.8 | A | A |
| Example 66 | N34 | SG4 | SR1 | — | — | 90 | 13.7 | A | A |
| Example 67 | N35 | SG4 | SR1 | — | — | 90 | 14.0 | A | A |
| Example 68 | N36 | SG4 | SR1 | — | — | 90 | 13.3 | A | A |
| Example 69 | N37 | SG1 | SR1 | — | — | 90 | 14.2 | A | A |
| Example 70 | N37 | SG4 | SR1 | — | — | 90 | 13.6 | A | A |
| Example 71 | N37 | SG4 | SR4 | — | — | 90 | 13.6 | A | A |
| Example 72 | N37 | SG4 | SR6 | — | — | 90 | 14.0 | A | A |
| Example 73 | N38 | SG4 | SR1 | — | — | 90 | 13.9 | A | A |
| Example 74 | N39 | SG4 | SR1 | — | — | 90 | 13.8 | A | A |
| Example 75 | N40 | SG4 | SR1 | — | — | 90 | 14.0 | A | A |
| Example 76 | N41 | SG4 | SR1 | — | — | 90 | 14.1 | A | A |
| Example 77 | N42 | SG4 | SR1 | — | — | 90 | 14.0 | A | A |
| Example 78 | N43 | SG4 | SR1 | — | — | 90 | 13.2 | A | A |
| Example 79 | N44 | SG4 | SR1 | — | — | 85 | 15.1 | A | C |
| Example 80 | N45 | SG4 | SR1 | — | — | 90 | 13.5 | A | A |
| Example 81 | N46 | SG4 | SR1 | — | — | 90 | 13.9 | A | A |
| Example 82 | N47 | SG4 | SR1 | — | — | 85 | 15.1 | A | C |
| Example 83 | N48 | SG4 | SR1 | — | — | 85 | 15.0 | A | C |
| Example 84 | N49 | SG4 | SR1 | — | — | 85 | 15.2 | A | C |
| Example 85 | N50 | SG4 | SR1 | — | — | 85 | 15.1 | A | C |
| Example 86 | N51 | SG4 | SR1 | — | — | 85 | 14.9 | A | C |
| Example 87 | N52 | SG4 | SR1 | — | — | 85 | 17.8 | A | C |
| Example 88 | N52 | SG3 | SR1 | — | — | 85 | 18.1 | A | C |
| Example 89 | N53 | SG3 | SR1 | — | — | 85 | 18.6 | A | C |
| Example 90 | N54 | SG4 | SR1 | — | — | 85 | 15.3 | A | A |
| Example 91 | N54 | SG2 | SR1 | — | — | 85 | 15.4 | A | A |
| Example 92 | N54 | SG5 | SR1 | — | — | 85 | 15.1 | A | A |
| Example 93 | N54 | SG6 | SR1 | — | — | 85 | 15.0 | A | A |
| Example 94 | N55 | SG4 | SR1 | — | — | 85 | 14.8 | A | A |
| Example 95 | N56 | SG4 | SR1 | — | — | 85 | 15.0 | A | A |
| Example 96 | N57 | SG4 | SR1 | — | — | 85 | 15.2 | A | A |
| Example 97 | N58 | SG4 | SR1 | — | — | 90 | 13.9 | A | A |
| Example 98 | N59 | SG4 | SR1 | — | — | 90 | 13.6 | A | A |
| Example 99 | N60 | SG4 | SR1 | — | — | 90 | 13.9 | A | A |
| Example 100 | N60 | SG5 | SR1 | — | — | 90 | 13.9 | A | A |
| Example 101 | N61 | SG4 | SR1 | — | — | 90 | 14.0 | A | A |
| Example 102 | N62 | SG4 | SR1 | — | — | 85 | 13.8 | A | A |
| Example 103 | N63 | SG4 | SR1 | — | — | 90 | 18.3 | B | A |
| Example 104 | N63 | SG3 | SR1 | — | — | 90 | 18.2 | B | A |
| Example 105 | N63 | SG3 | SR2 | — | — | 90 | 18.5 | B | A |
| Example 106 | N64 | SG3 | SR1 | — | — | 90 | 18.4 | B | A |
| Example 107 | N65 | SG3 | SR1 | — | — | 90 | 18.7 | B | A |
| Example 108 | N66 | SG4 | SR1 | — | — | 100 | 13.9 | A | C |
| Example 109 | N67 | SG4 | SR1 | — | — | 100 | 14.8 | A | C |
| Example 110 | N68 | SG4 | SR1 | — | — | 90 | 18.5 | B | A |

TABLE 25
(Evaluation of EUV Exposure)

| | | | | Upper | Upper layer | | | | |
|---|---|---|---|---|---|---|---|---|---|
| | | | Rinsing | layer | film PB | PEB | Resolution | Etching | Outgassing |
| | Composition | Developer | liquid | film | [° C.] | [° C.] | [nm] | resistance | performance |
| Example 111 | N68 | SG2 | SR1 | — | — | 90 | 18.5 | B | A |
| Example 112 | N68 | SG2 | SR6 | — | — | 90 | 18.1 | B | A |
| Example 113 | N68 | SG2 | SR12 | — | — | 90 | 18.2 | B | A |
| Example 114 | N69 | SG4 | SR1 | — | — | 85 | 16.9 | A | B |
| Example 115 | N70 | SG4 | SR1 | — | — | 85 | 16.3 | A | B |
| Example 116 | N71 | SG4 | SR1 | — | — | 80 | 18.5 | A | C |
| Example 117 | N72 | SG4 | SR1 | — | — | 80 | 17.5 | A | C |
| Example 118 | N73 | SG4 | SR1 | — | — | 80 | 17.6 | A | C |
| Example 119 | N74 | SG4 | SR1 | — | — | 85 | 17.8 | A | C |
| Example 120 | N75 | SG4 | SR1 | — | — | 85 | 17.0 | A | C |
| Example 121 | N76 | SG4 | SR1 | — | — | 85 | 17.1 | A | C |
| Example 122 | N77 | SG4 | SR1 | — | — | 100 | 13.3 | A | A |
| Example 123 | N77 | SG4 | SR5 | — | — | 100 | 13.7 | A | A |
| Example 124 | N77 | SG5 | SR1 | — | — | 100 | 13.8 | A | A |
| Example 125 | N78 | SG4 | SR1 | — | — | 100 | 13.2 | A | A |
| Example 126 | N79 | SG4 | SR1 | — | — | 100 | 13.6 | A | A |
| Example 127 | N80 | SG4 | SR1 | — | — | 100 | 13.5 | A | A |
| Example 128 | N81 | SG4 | SR1 | — | — | 100 | 13.2 | A | A |
| Example 129 | N82 | SG4 | SR1 | — | — | 100 | 13.3 | A | A |
| Example 130 | N83 | SG1 | SR1 | — | — | 90 | 15.8 | A | A |
| Example 131 | N83 | SG4 | SR1 | — | — | 90 | 15.0 | A | A |
| Example 132 | N83 | SG4 | SR5 | — | — | 90 | 14.7 | A | A |
| Example 133 | N83 | SG4 | SR6 | — | — | 90 | 15.0 | A | A |
| Example 134 | N84 | SG4 | SR5 | — | — | 90 | 15.2 | A | A |
| Example 135 | N85 | SG4 | SR5 | — | — | 90 | 15.1 | A | A |
| Example 136 | N86 | SG2 | SR1 | — | — | 85 | 14.2 | A | A |
| Example 137 | N86 | SG4 | SR1 | — | — | 85 | 13.3 | A | A |
| Example 138 | N87 | SG4 | SR1 | — | — | 85 | 13.7 | A | A |
| Example 139 | N88 | SG4 | SR1 | — | — | 85 | 13.7 | A | A |
| Example 140 | N88 | SG4 | Absent | — | — | 85 | 15.3 | A | A |
| Example 141 | N89 | SG4 | SR1 | — | — | 85 | 13.6 | A | A |
| Example 142 | N90 | SG4 | SR1 | — | — | 100 | 16.9 | A | B |
| Example 143 | N91 | SG4 | SR1 | — | — | 100 | 17.0 | A | B |
| Example 144 | N92 | SG4 | SR1 | — | — | 90 | 13.4 | A | A |
| Example 145 | N93 | SG1 | SR1 | — | — | 90 | 14.3 | A | A |
| Example 146 | N93 | SG4 | SR1 | — | — | 90 | 13.8 | A | A |
| Example 147 | N94 | SG4 | SR1 | — | — | 90 | 14.0 | A | A |
| Example 148 | N95 | SG4 | SR1 | — | — | 90 | 14.0 | A | A |
| Example 149 | N95 | SG3 | SR1 | — | — | 90 | 14.3 | A | A |
| Example 150 | N95 | SG4 | SR2 | — | — | 90 | 14.0 | A | A |
| Example 151 | N95 | SG4 | SR6 | — | — | 90 | 14.1 | A | A |
| Example 152 | N95 | SG4 | SR9 | — | — | 90 | 14.2 | A | A |
| Example 153 | N96 | SG4 | SR1 | — | — | 90 | 14.3 | A | A |
| Example 154 | N97 | SG4 | SR1 | — | — | 100 | 13.3 | A | A |
| Example 155 | N97 | SG5 | SR6 | — | — | 100 | 13.5 | A | A |
| Example 156 | N97 | SG2 | SR6 | — | — | 100 | 14.1 | A | A |
| Example 157 | N98 | SG4 | SR1 | — | — | 100 | 13.7 | A | A |
| Example 158 | N99 | SG4 | SR2 | — | — | 80 | 14.7 | A | A |
| Example 159 | N100 | SG4 | SR1 | — | — | 90 | 13.4 | A | A |
| Example 160 | N100 | SG4 | SR10 | — | — | 90 | 13.6 | A | A |
| Example 161 | N101 | SG4 | SR1 | — | — | 90 | 13.6 | A | A |
| Example 162 | N101 | SG2 | SR1 | — | — | 90 | 14.2 | A | A |
| Example 163 | N102 | SG1 | Absent | — | — | 90 | 13.8 | B | A |
| Example 164 | N102 | SG1 | SR9 | — | — | 90 | 13.5 | B | A |
| Example 165 | N102 | SG2 | Absent | — | — | 90 | 13.6 | B | A |

TABLE 26
(Evaluation of EUV Exposure)

| | | | | Upper | Upper layer | | | | |
|---|---|---|---|---|---|---|---|---|---|
| | | | Rinsing | layer | film PB | PEB | Resolution | Etching | Outgassing |
| | Composition | Developer | liquid | film | [° C.] | [° C.] | [nm] | resistance | performance |
| Example 166 | N102 | SG4 | SR1 | — | — | 90 | 13.4 | B | A |
| Example 167 | N103 | SG1 | Absent | — | — | 110 | 13.9 | B | A |
| Example 168 | N104 | SG1 | Absent | — | — | 110 | 13.6 | B | A |
| Example 169 | N1041 | SG1 | Absent | — | — | 110 | 13.7 | B | A |
| Example 170 | N1041 | SG2 | Absent | — | — | 110 | 13.5 | B | A |
| Example 171 | N1042 | SG1 | Absent | — | — | 110 | 13.5 | B | A |
| Example 172 | N1043 | SG1 | Absent | — | — | 110 | 13.4 | B | A |
| Example 173 | N1044 | SG1 | Absent | — | — | 110 | 13.4 | B | A |
| Example 174 | N1045 | SG1 | Absent | — | — | 110 | 13.6 | B | A |
| Example 175 | N1046 | SG1 | Absent | — | — | 90 | 13.4 | B | A |
| Example 176 | N105 | SG1 | Absent | — | — | 110 | 13.9 | B | A |
| Example 177 | N106 | SG1 | Absent | — | — | 90 | 13.8 | B | A |
| Example 178 | N106 | SG4 | Absent | — | — | 90 | 13.5 | B | A |
| Example 179 | N107 | SG1 | Absent | — | — | 90 | 13.8 | A | A |
| Example 180 | N107 | SG4 | SR6 | — | — | 90 | 13.5 | A | A |
| Example 181 | N108 | SG1 | Absent | — | — | 110 | 13.9 | A | A |
| Example 182 | N1081 | SG1 | Absent | — | — | 110 | 13.5 | A | A |
| Example 183 | N109 | SG1 | Absent | — | — | 90 | 17.8 | B | A |
| Example 184 | N109 | SG2 | Absent | — | — | 90 | 16.6 | B | A |
| Example 185 | N1091 | SG2 | Absent | — | — | 90 | 16.5 | B | A |
| Example 186 | N110 | SG1 | Absent | — | — | 90 | 13.7 | B | A |
| Example 187 | N111 | SG1 | Absent | — | — | 90 | 14.1 | B | A |
| Example 188 | N111 | SG2 | Absent | — | — | 90 | 13.8 | B | A |
| Example 189 | N112 | SG1 | Absent | — | — | 110 | 14.3 | B | A |
| Example 190 | N1121 | SG1 | Absent | — | — | 110 | 14.0 | B | A |
| Example 191 | N113 | SG1 | Absent | — | — | 90 | 14.0 | A | A |
| Example 192 | N114 | SG1 | Absent | — | — | 90 | 13.8 | B | A |
| Example 193 | N115 | SG1 | Absent | — | — | 90 | 13.9 | B | A |
| Example 194 | N115 | SG4 | SR1 | — | — | 90 | 13.6 | B | A |
| Example 195 | N116 | SG1 | Absent | — | — | 90 | 14.0 | B | A |
| Example 196 | N117 | SG1 | Absent | — | — | 90 | 14.2 | B | A |
| Example 197 | N118 | SG1 | Absent | — | — | 90 | 13.8 | B | A |
| Example 198 | N119 | SG1 | Absent | — | — | 85 | 15.1 | A | C |
| Example 199 | N120 | SG1 | Absent | — | — | 90 | 14.8 | A | C |
| Example 200 | N121 | SG1 | Absent | — | — | 90 | 15.2 | A | C |
| Example 201 | N1211 | SG1 | Absent | — | — | 90 | 15.0 | A | C |
| Example 202 | N1212 | SG1 | Absent | — | — | 90 | 15.1 | A | C |
| Example 203 | N122 | SG1 | Absent | — | — | 110 | 14.3 | B | A |
| Example 204 | N123 | SG1 | Absent | — | — | 110 | 14.4 | B | A |
| Example 205 | N124 | SG1 | Absent | — | — | 110 | 16.0 | B | A |
| Example 206 | N125 | SG1 | Absent | — | — | 90 | 15.7 | A | A |
| Example 207 | N125 | SG2 | Absent | — | — | 90 | 15.2 | A | A |
| Example 208 | N125 | SG2 | SR2 | — | — | 90 | 14.7 | A | A |
| Example 209 | N126 | SG1 | Absent | — | — | 110 | 15.3 | A | A |
| Example 210 | N1261 | SG1 | Absent | — | — | 110 | 15.0 | A | A |
| Example 211 | N127 | SG1 | Absent | — | — | 90 | 15.6 | A | A |
| Example 212 | N128 | SG1 | Absent | — | — | 110 | 16.6 | A | C |
| Example 213 | N129 | SG1 | Absent | — | — | 130 | 16.9 | A | C |
| Example 214 | N130 | SG1 | Absent | — | — | 90 | 17.6 | A | C |
| Example 215 | N131 | SG1 | Absent | — | — | 90 | 13.8 | B | A |
| Example 216 | N131 | SG1 | SR14 | — | — | 90 | 13.4 | B | A |
| Example 217 | N132 | SG1 | Absent | — | — | 80 | 15.8 | B | C |
| Example 218 | N133 | SG1 | Absent | — | — | 90 | 15.5 | B | C |
| Example 219 | N134 | SG1 | Absent | — | — | 110 | 14.8 | A | A |
| Example 220 | N135 | SG1 | Absent | — | — | 90 | 13.7 | B | A |

TABLE 27
(Evaluation of EUV Exposure)

| | | | | | Upper layer | | | | |
|---|---|---|---|---|---|---|---|---|---|
| | | | Rinsing | Upper | film PB | PEB | Resolution | Etching | Outgassing |
| | Composition | Developer | liquid | layer film | [° C.] | [° C.] | [nm] | resistance | performance |
| Example 221 | N135 | SG2 | Absent | — | — | 90 | 13.5 | B | A |
| Example 222 | N136 | SG1 | Absent | — | — | 90 | 13.8 | B | A |
| Example 223 | N137 | SG1 | Absent | — | — | 90 | 13.7 | B | A |
| Example 224 | N138 | SG1 | Absent | — | — | 85 | 18.1 | B | A |
| Example 225 | N139 | SG1 | Absent | — | — | 90 | 13.5 | B | A |
| Example 226 | N140 | SG1 | Absent | — | — | 90 | 14.0 | A | A |
| Example 227 | N141 | SG1 | Absent | — | — | 80 | 13.8 | A | A |
| Example 228 | N142 | SG1 | Absent | — | — | 90 | 13.7 | A | A |
| Example 229 | N142 | SG2 | Absent | — | — | 90 | 13.5 | A | A |
| Example 230 | N1421 | SG1 | Absent | — | — | 90 | 13.5 | A | A |
| Example 231 | N1422 | SG1 | Absent | — | — | 100 | 13.4 | A | A |
| Example 232 | N143 | SG1 | Absent | — | — | 100 | 13.6 | A | A |
| Example 233 | N144 | SG1 | Absent | — | — | 90 | 14.0 | B | A |
| Example 234 | N144 | SG2 | Absent | — | — | 90 | 13.7 | B | A |
| Example 235 | N145 | SG1 | Absent | — | — | 110 | 14.8 | B | A |
| Example 236 | N146 | SG1 | Absent | — | — | 90 | 15.4 | B | A |
| Example 237 | N147 | SG1 | Absent | — | — | 85 | 13.9 | A | A |
| Example 238 | N148 | SG1 | Absent | — | — | 80 | 14.3 | A | B |
| Example 239 | N149 | SG1 | Absent | — | — | 80 | 14.0 | A | B |
| Example 240 | N149 | SG2 | Absent | — | — | 80 | 13.7 | A | B |
| Comparative | NR1 | SG1 | SR1 | — | — | 110 | 27.1 | C | A |
| Example 1 | | | | | | | | | |
| Comparative | NR2 | SG1 | SR1 | — | — | 110 | 25.2 | C | A |
| Example 2 | | | | | | | | | |

As shown in Tables 23 to 27, Examples 1 to 240 exhibited good pattern collapse performance and etching resistance.

On the other hand, Comparative Example 1 using a composition NR1 that contains a resin (R-1) lacking the repeating unit represented by General Formula (BII) and Comparative Example 2 using a composition NR2 that contains a resin (R-2) lacking the repeating unit represented by General Formula (I) exhibited insufficient pattern collapse performance and etching resistance.

Referring to Examples 1 to 162, it was found that Examples having a large content of the repeating unit represented by General Formula (I) tended to exhibit good pattern collapse performance and excellent etching resistance, as compared with Examples having a small content thereof (for example, Examples 31 and 35 to 39 using a composition N10, N13, or N14, each containing a resin (A-3)).

This was the same also in Examples 163 to 240. That is, Examples having a large content of the repeating unit represented by General Formula (I) tended to exhibit good pattern collapse performance and excellent etching resistance, as compared with Examples having a small content thereof (for example, Examples 183 to 184 using a composition N109 containing a resin (A-39)).

Also, referring to Examples 1 to 162, in a case where the group Y₂ capable of leaving by the action of an acid in the repeating unit represented by General Formula (BII) is the above-mentioned Formula (Y1), it was found that Examples in which two of Rx₁ to Rx₃ were bonded to each other to form a ring tended to exhibit excellent pattern collapse performance, as compared with Examples in which they did not form a ring (for example, Examples 40 to 52 using compositions N15 to N22 containing resins (A-4) to (A-7)).

This was the same also in Examples 163 to 240. Also, in a case where the group Y₂ capable of leaving by the action of an acid in the repeating unit represented by General Formula (BII) is the above-mentioned Formula (Y1), it was found that Examples in which two of Rx₁ to Rx₃ were bonded to each other to form a ring tended to exhibit excellent pattern collapse performance, as compared with Examples in which they did not form a ring (for example, Example 219 using a composition N134 containing a resin (A-55) and Example 235 using a composition N145 containing a resin (A-62)).

Also, referring to Examples 1 to 162, in a case where the group Y₂ capable of leaving by the action of an acid in the repeating unit represented by General Formula (BII) is the above-mentioned Formula (Y1), it was found that Examples in which two of Rx₁ to Rx₃ were bonded to each other to form a ring tended to exhibit excellent outgassing performance, as compared with Examples in which any one of Rx₁ to Rx₃ is a cycloalkyl group (for example, Examples 79 and 82 to 89 using compositions N44 and N47 to N53 containing resins (A-12), (A-14), and (A-15)).

Also, referring to Examples 1 to 162, it was found that Examples, in which the group Y₂ capable of leaving by the action of an acid in the repeating unit represented by General Formula (BII) is the above-mentioned Formula (Y1), tended to exhibit good pattern collapse performance and excellent outgassing performance, as compared with Examples in which the above-mentioned Formula (Y3) is used (for example, Examples 114 to 121 using compositions N69 to N76 containing resins (A-22) to (A-24)), and Examples in which the above-mentioned Formula (Y4) is used (For example, Examples 142 to 143 using compositions N90 to N91 containing the resin (A-29)).

[Evaluation of EB Exposure]

Using the resist compositions described in Tables 13 to 18, a resist pattern was formed by the following operation.

[Coating and Post Baking (PB) of Resist Composition]

DUV44 (manufactured by Brewer Science, Inc.) as an organic film-forming composition was coated on a 6-inch silicon wafer and baked at 200° C. for 60 seconds to form an organic film having a film thickness of 60 nm. Each resist composition was coated on the formed organic film and baked at a condition of 120° C. for 60 seconds to form a resist film having a film thickness of 40 nm.

[Exposure]

<L/S Pattern Evaluation>

Using an electron beam irradiation device (JBX6000FS/E, manufactured by JEOL Ltd.; acceleration voltage of 50 KeV), a layout of EB drawing was designed on the wafer prepared above so that a line-and-space pattern with a pitch of 40 nm and a width of 20 nm was formed on the wafer, and EB exposure was carried out by changing the exposure dose.

[Post Exposure Bake (PEB)]

After irradiation, once removed from the electron beam irradiation device, the wafer was immediately heated on a hot plate at a condition of a temperature described in Tables 28 to 29 for 60 seconds.

[Development]

Using a shower type developing device (ADE 3000S, manufactured by ACTES Co., Ltd.), development was carried out by spray-ejecting the developer (23° C.) at a flow rate of 200 mL/min for 30 seconds while rotating the wafer at 50 revolutions (rpm).

[Rinsing]

Thereafter, a rinsing treatment was carried out by spray-ejecting a rinsing liquid (23° C.) at a flow rate of 200 mL/min for 15 seconds while rotating the wafer at 50 revolutions (rpm).

Finally, the wafer was dried by high-speed spinning at 2,500 revolutions (rpm) for 60 seconds.

[Evaluation Test]

Regarding the items similar to “Evaluation of EUV Exposure” mentioned above, the resist pattern was evaluated in the same manner as above except that “S-9220” (manufactured by Hitachi, Ltd.) was used as the scanning electron microscope. The etching resistance and the outgassing performance were also evaluated in substantially the same manner as “Evaluation of EUV Exposure” mentioned above. Details of the results are shown in Tables 28 to 29.

TABLE 28
(Evaluation of EB Exposure)

| | | | Rinsing | PEB | Resolution | Etching | Outgassing |
|---|---|---|---|---|---|---|---|
| | Composition | Developer | liquid | [° C.] | [nm] | resistance | performance |
| Example 1B | N3 | SG4 | SR1 | 90 | 13.2 | A | A |
| Example 2B | N3 | SG4 | SR2 | 90 | 13.8 | A | A |
| Example 3B | N3 | SG4 | SR5 | 90 | 13.9 | A | A |
| Example 4B | N3 | SG4 | SR6 | 90 | 14.1 | A | A |
| Example 5B | N3 | SG5 | SR2 | 90 | 13.8 | A | A |
| Example 6B | N3 | SG4 | SR8 | 90 | 14.0 | A | A |
| Example 7B | N3 | SG4 | SR11 | 90 | 14.2 | A | A |
| Example 8B | N3 | SG2 | SR1 | 90 | 14.9 | A | A |
| Example 9B | N4 | SG4 | SR1 | 90 | 14.0 | A | A |
| Example 10B | N5 | SG4 | SR1 | 90 | 14.3 | A | A |
| Example 11B | N6 | SG4 | SR1 | 90 | 13.9 | A | A |
| Example 12B | N6 | SG3 | SR1 | 90 | 14.3 | A | A |
| Example 13B | N7 | SG4 | SR1 | 90 | 14.0 | A | A |
| Example 14B | N8 | SG4 | SR1 | 90 | 14.0 | A | A |
| Example 15B | N10 | SG4 | SR1 | 90 | 15.4 | B | A |
| Example 16B | N11 | SG4 | SR1 | 90 | 13.1 | A | A |
| Example 17B | N12 | SG4 | SR1 | 90 | 13.6 | A | A |
| Example 18B | N13 | SG2 | SR1 | 90 | 17.1 | B | A |
| Example 19B | N13 | SG2 | SR4 | 90 | 16.7 | B | A |
| Example 20B | N13 | SG4 | SR4 | 90 | 16.3 | B | A |
| Example 21B | N15 | SG2 | SR1 | 110 | 15.9 | A | A |
| Example 22B | N15 | SG4 | SR1 | 110 | 15.4 | A | A |
| Example 23B | N15 | SG4 | SR2 | 110 | 15.5 | A | A |
| Example 24B | N16 | SG4 | SR13 | 110 | 15.4 | A | A |
| Example 25B | N17 | SG4 | SR4 | 110 | 15.6 | A | A |
| Example 26B | N18 | SG4 | SR7 | 110 | 15.7 | A | A |
| Example 27B | N23 | SG4 | SR1 | 85 | 13.5 | A | A |
| Example 28B | N25 | SG4 | SR1 | 85 | 13.8 | A | A |
| Example 29B | N28 | SG4 | SR1 | 85 | 13.3 | A | A |
| Example 30B | N37 | SG4 | SR1 | 90 | 13.8 | A | A |
| Example 31B | N39 | SG4 | SR1 | 90 | 14.0 | A | A |
| Example 32B | N41 | SG4 | SR1 | 90 | 14.4 | A | A |
| Example 33B | N42 | SG4 | SR1 | 90 | 14.4 | A | A |
| Example 34B | N43 | SG4 | SR1 | 90 | 13.5 | A | A |
| Example 35B | N45 | SG4 | SR1 | 90 | 13.6 | A | A |
| Example 36B | N47 | SG4 | SR1 | 85 | 15.5 | A | C |
| Example 37B | N49 | SG4 | SR1 | 85 | 15.5 | A | C |
| Example 38B | N50 | SG4 | SR1 | 85 | 15.7 | A | C |
| Example 39B | N52 | SG4 | SR1 | 85 | 18.1 | A | C |
| Example 40B | N53 | SG3 | SR1 | 85 | 19.0 | A | C |
| Example 41B | N54 | SG4 | SR1 | 85 | 15.8 | A | A |
| Example 42B | N54 | SG6 | SR1 | 85 | 15.6 | A | A |
| Example 43B | N58 | SG4 | SR1 | 90 | 13.8 | A | A |
| Example 44B | N59 | SG4 | SR1 | 90 | 13.8 | A | A |
| Example 45B | N68 | SG4 | SR1 | 90 | 18.7 | B | A |
| Example 46B | N69 | SG4 | SR1 | 85 | 17.1 | A | B |
| Example 47B | N70 | SG4 | SR1 | 85 | 16.6 | A | B |
| Example 48B | N77 | SG4 | SR1 | 100 | 13.5 | A | A |
| Example 49B | N77 | SG5 | SR1 | 100 | 14.0 | A | A |
| Example 50B | N79 | SG4 | SR1 | 100 | 13.9 | A | A |
| Example 51B | N81 | SG4 | SR1 | 100 | 13.5 | A | A |
| Example 52B | N82 | SG4 | SR1 | 100 | 13.5 | A | A |
| Example 53B | N95 | SG4 | SR1 | 90 | 14.2 | A | A |
| Example 54B | N97 | SG4 | SR1 | 100 | 13.6 | A | A |
| Example 55B | N100 | SG4 | SR1 | 90 | 13.8 | A | A |

TABLE 29
(Evaluation of EB Exposure)

| | | | Rinsing | PEB | Resolution | Etching | Outgassing |
|---|---|---|---|---|---|---|---|
| | Composition | Developer | liquid | [° C.] | [nm] | resistance | performance |
| Example 56B | N102 | SG1 | Absent | 90 | 14.4 | B | A |
| Example 57B | N102 | SG1 | SR9 | 90 | 14.0 | B | A |
| Example 58B | N102 | SG2 | Absent | 90 | 14.0 | B | A |
| Example 59B | N102 | SG4 | SR1 | 90 | 13.8 | B | A |
| Example 60B | N103 | SG1 | Absent | 110 | 14.3 | B | A |
| Example 61B | N1043 | SG1 | Absent | 110 | 13.9 | B | A |
| Example 62B | N1046 | SG1 | Absent | 90 | 13.8 | B | A |
| Example 63B | N105 | SG1 | Absent | 110 | 14.4 | B | A |
| Example 64B | N106 | SG1 | Absent | 90 | 14.4 | B | A |
| Example 65B | N107 | SG1 | Absent | 90 | 14.2 | A | A |
| Example 66B | N1081 | SG1 | Absent | 110 | 14.0 | A | A |
| Example 67B | N109 | SG1 | Absent | 90 | 18.3 | B | A |
| Example 68B | N111 | SG1 | Absent | 90 | 14.5 | B | A |
| Example 69B | N115 | SG1 | Absent | 90 | 14.3 | B | A |
| Example 70B | N119 | SG1 | Absent | 85 | 15.5 | A | C |
| Example 71B | N120 | SG1 | Absent | 90 | 15.2 | A | C |
| Example 72B | N121 | SG1 | Absent | 90 | 15.6 | A | C |
| Example 73B | N125 | SG1 | Absent | 90 | 16.2 | A | A |
| Example 74B | N125 | SG2 | Absent | 90 | 15.6 | A | A |
| Example 75B | N125 | SG2 | SR2 | 90 | 15.2 | A | A |
| Example 76B | N126 | SG1 | Absent | 110 | 15.6 | A | A |
| Example 77B | N1261 | SG1 | Absent | 110 | 15.4 | A | A |
| Example 78B | N132 | SG1 | Absent | 80 | 16.2 | B | C |
| Example 79B | N133 | SG1 | Absent | 90 | 15.9 | B | C |
| Example 80B | N135 | SG1 | Absent | 90 | 14.3 | B | A |
| Example 81B | N144 | SG1 | Absent | 90 | 14.4 | B | A |
| Example 82B | N148 | SG1 | Absent | 80 | 14.8 | A | B |
| Comparative | NR1 | SG1 | SR1 | 110 | 28.1 | C | A |
| Example 1B | | | | | | | |
| Comparative | NR2 | SG1 | SR1 | 110 | 26.0 | C | A |
| Example 2B | | | | | | | |

As shown in Tables 28 to 29, Examples 1B to 82B exhibited good pattern collapse performance and etching resistance.

On the other hand, Comparative Example 1B using the composition NR1 that contains the resin (R-1) lacking the repeating unit represented by General Formula (BII) and Comparative Example 2B using the composition NR2 that contains the resin (R-2) lacking the repeating unit represented by General Formula (I) exhibited insufficient pattern collapse performance and etching resistance.

Even in the evaluation of EB exposure shown in Tables 28 to 29, the same tendency as in the evaluation of EUV exposure (Tables 23 to 27) was observed.

Evaluation tests were carried out using compositions Ni to N149 containing resins (A-1) to (A-65) in the same manner as above, except that KrF excimer laser light was used. As a result, similar results are obtained.

What is claimed is:

1. A pattern forming method comprising:
a step of forming a film using an actinic ray-sensitive or radiation-sensitive resin composition that contains a resin A having a repeating unit represented by General Formula (I) and a repeating unit represented by General Formula (BII);
a step of exposing the film; and
a step of developing the exposed film using a developer containing an organic solvent, to form a pattern, 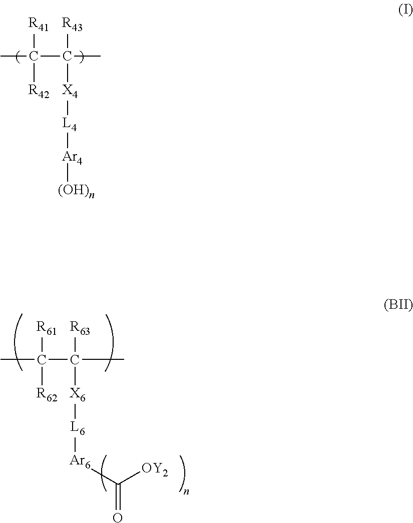
in General Formula (I),
R₄₁, R₄₂, and R₄₃ each independently represent a hydrogen atom, an alkyl group, a cycloalkyl group, a halogen atom, a cyano group, or an alkoxycarbonyl group, where R₄₂ may be bonded to AN to form a ring, and R₄₂ in such a case represents a single bond or an alkylene group,
X₄ represents a single bond, —COO—, or —CONR₆₄—, and R₆₄ represents a hydrogen atom or an alkyl group,
L₄ represents a single bond or an alkylene group,
Ar₄ represents an (n+1)-valent aromatic ring group, and in a case of being bonded to R₄₂ to form a ring, it represents an (n+2)-valent aromatic ring group, and
n represents an integer of 1 or more, and
in General Formula (BII),
R₆₁, R₆₂, and R₆₃ each independently represent a hydrogen atom, an alkyl group, a cycloalkyl group, a halogen atom, a cyano group, or an alkoxycarbonyl group, where R₆₂ may be bonded to Ar₆ to form a ring, and R₆₂ in such a case represents a single bond or an alkylene group,
X₆ represents a single bond, —COO—, or —CONR₆₄—, and R₆₄ represents a hydrogen atom or an alkyl group,
L₆ represents a single bond or an alkylene group,
Ar₆ represents an (n+1)-valent aromatic ring group, and in a case of being bonded to R₆₂ to form a ring, it represents an (n+2)-valent aromatic ring group,
Y₂, in a case where n=1, represents a group capable of leaving by the action of an acid, and in a case where n≥2, Y₂'s each independently represent a hydrogen atom or a group capable of leaving by the action of an acid, where at least one of Y₂'s represents a group capable of leaving by the action of an acid, and
n represents an integer of 1 or more.

2. The pattern forming method according to claim 1,
wherein Ar₄ in General Formula (I) and Ar₆ in General Formula (BII) are each independently a phenylene group or a naphthylene group.

3. The pattern forming method according to claim 1,
wherein X₄ in General Formula (I) and X₆ in General Formula (BII) are each independently a single bond.

4. The pattern forming method according to claim 1,
wherein a content of the repeating unit represented by General Formula (BII) is 10% by mol or more and 80% by mol or less, with respect to all the repeating units in the resin A.

5. The pattern forming method according to claim 1,
wherein a content of the repeating unit represented by General Formula (BII) is 25% by mol or more and 65% by mol or less, with respect to all the repeating units in the resin A.

6. The pattern forming method according to claim 1,
wherein a content of the repeating unit represented by General Formula (I) is 10% by mol or more and 80% by mol or less, with respect to all the repeating units in the resin A.

7. The pattern forming method according to claim 1,
Wherein Y₂ in General Formula (BII) is a group represented by Formula (Y1),
—C(Rx₁)(Rx₂)(Rx₃) (Y1):
in Formula (Y1), Rx₁ to Rx₃ each independently represent an alkyl group or a cycloalkyl group, and two of Rx₁ to Rx₃ may be bonded to each other to form a ring.

8. The pattern forming method according to claim 7,
wherein, in Formula (Y1), at least two of Rx₁, . . . , or Rx₃ are bonded to each other to form a ring.

9. The pattern forming method according to claim 1,
wherein the resin A further has a repeating unit having an aromatic ring group.

10. The pattern forming method according to claim 1,
wherein the resin A further has a repeating unit having a lactone group or a sultone group.

11. The pattern forming method according to claim 1,
wherein the actinic ray-sensitive or radiation-sensitive resin composition further contains a compound capable of generating an acid by actinic rays or radiation.

12. The pattern forming method according to claim 1,
wherein the developer contains at least one organic solvent selected from the group consisting of a ketone-based solvent and an ester-based solvent.

13. The pattern forming method according to claim 1, further comprising a step of washing the exposed film with a rinsing liquid after developing the exposed film using the developer,
wherein the rinsing liquid contains at least one organic solvent selected from the group consisting of a ketone-based solvent, an ether-based solvent, and a hydrocarbon-based solvent.

14. A method for manufacturing an electronic device, comprising the pattern forming method according to claim 1.
